(19) United States
(12) Patent Application Publication
(10) Pub. No.: US 2020/0392343 A1
(43) Pub. Date: Dec. 17, 2020

(54) COMPOSITION, CURED PRODUCT, COLOR FILTER, METHOD FOR PRODUCING COLOR FILTER, SOLID-STATE IMAGING ELEMENT, IMAGE DISPLAY DEVICE, AND COMPOUND

(71) Applicant: FUJIFILM Corporation, Tokyo (JP)

(72) Inventors: Akio Mizuno, Shizuoka (JP); Kazuya Ota, Shizuoka (JP); Hiromu Koizumi, Shizuoka (JP); Hiroaki Idei, Shizuoka (JP)

(73) Assignee: FUJIFILM Corporation, Tokyo (JP)

(21) Appl. No.: 17/004,618

(22) Filed: Aug. 27, 2020

Related U.S. Application Data
(63) Continuation of application No. PCT/JP2019/007341, filed on Feb. 26, 2019.

(30) Foreign Application Priority Data
Feb. 28, 2018 (JP) 2018-035196

(51) Int. Cl. C09B 47/30; C09B 67/22; C09B 67/20; C09B 67/02; G03F 7/00

(52) U.S. Cl. CPC C09B 47/30; C09B 67/0035; G03F 7/0007; C09B 67/0097; C09B 67/0067

(57) ABSTRACT

Provided are a composition including a compound represented by Formula 1 and having a maximum absorption wavelength in a range of 600 nm or more and less than 750 nm and a polymerizable compound; as well as a cured product of the composition, a color filter including the cured product, a method for producing the color filter, a solid-state imaging element including the color filter, an image display device including the color filter, and a compound.

In Formula 1, Z's each independently represent a specific group, n represents an integer of 4 to 16, and R's each independently represent a hydrogen atom or a monovalent substituent which is different from Z, m represents an integer of 0 to 12, and m+n is 16.

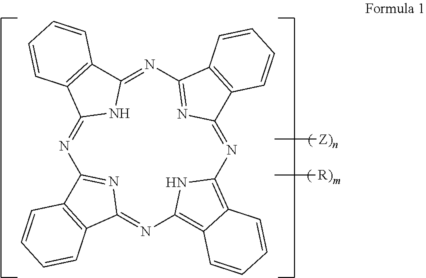

### CROSS-REFERENCE TO RELATED APPLICATIONS

This application is a continuation application of International Application No. PCT/JP2019/007341, filed Feb. 26, 2019, the disclosure of which is incorporated herein by reference in its entirety. Further, this application claims priority from Japanese Patent Application No. 2018-035196, filed Feb. 28, 2018, the disclosure of which is incorporated herein by reference in its entirety.

### BACKGROUND OF THE INVENTION

### 1. Field of the Invention

The present disclosure relates to a composition, a cured product, a color filter, a method for producing a color filter, a solid-state imaging element, an image display device, and a compound.

### 2. Description of the Related Art

A member such as a color filter is produced by a photolithographic method or the like, using a coloring photosensitive composition which is formed by adding a polyfunctional monomer, a photopolymerization initiator, an alkali-soluble resin, and other components to a pigment dispersion composition such as a composition in which an organic pigment or an inorganic pigment is dispersed.

It is known that a phthalocyanine compound is used as the pigment.

Examples of a conventional phthalocyanine compound or a composition using the phthalocyanine compound include those described in JP2009-079150A and JP2011-241349A.

For example, JP2009-079150A discloses a photopolymerization initiator having a mother nucleus structure of an organic pigment and a partial structure capable of decomposing by light to generate an initiating species in a molecule.

JP2011-241349A discloses a curable ink composition including an infrared absorbing coloring agent represented by General Formula (1) and a polymerizable compound.

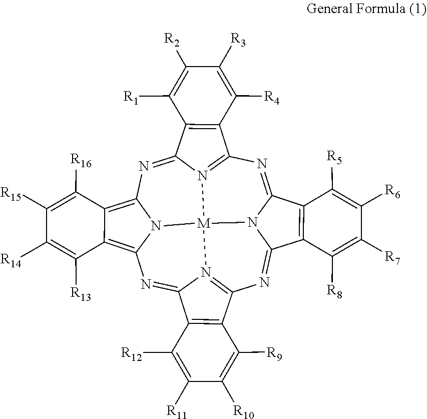

In General Formula (1), R₁, R₂, R₃, R₄, R₅, R₆, R₇, R₈, R₉, R₁₀, R₁₁, R₁₂, R₁₃, R₁₄, R₁₅, and R₁₆ each independently represent a hydrogen atom or a substituent, at least one of R₁, . . . , or R₁₆ represents an R₁₇—X— group, or includes at least one structure in which adjacent two of R₁ to R₁₆ are fused. X represents —S—, —NH—, —NR₁₈—, or —O—, and R₁₇ and R₁₈ each independently represent an aliphatic group or an aryl group. M represents two atoms selected from the group consisting of a hydrogen atom and a monovalent metal atom, a divalent metal atom, or a divalent substituted metal atom including a trivalent or tetravalent metal atom.]

### SUMMARY OF THE INVENTION

It has been studied to use a coloring agent having excellent spectral characteristics as a coloring agent used in forming a member such as a color filter. In the present disclosure, it is said that, with respect to the absorbance for light of specific wavelength A, the lower the absorbance for light of another wavelength B, the better the spectral characteristics, and the smaller the difference between the wavelength A and the wavelength B is, the better the spectral characteristics are. In general, the narrower the absorption wavelength peak width of the compound, the better the spectral characteristics.

Here, as a result of extensive studies, the present inventors have found that there is still room for improvement in spectral characteristics of the phthalocyanine coloring agents used in JP2009-079150A and JP2011-241349A.

An object to be achieved by an embodiment according to the present disclosure is to provide a composition having excellent spectral characteristics of a cured product to be obtained, a cured product of the composition, a color filter comprising the cured product, a method for producing the color filter, and a solid-state imaging element or an image display device, each of which comprising the color filter.

In addition, an object to be achieved by another embodiment according to the present disclosure is to provide a novel compound.

Means for achieving the foregoing objects include the following aspects.

<1> A composition comprising:

a compound represented by Formula 1 and having a maximum absorption wavelength in a range of 600 nm or more and less than 750 nm; and

a polymerizable compound.

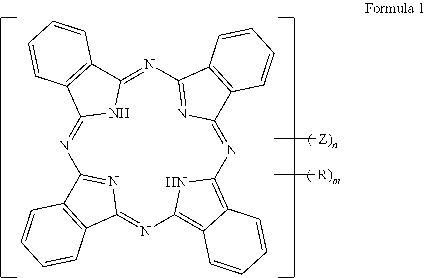

In Formula 1, Z's each independently represent a group represented by Formula 2, n represents an integer of 4 to 16, and R's each independently represent a hydrogen atom or a monovalent substituent which is different from Z, m represents an integer of 0 to 12, and m+n is 16.

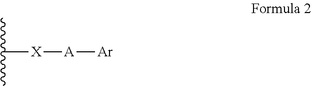

In Formula 2, X is —O—, —S—, —NR³—, —(C═O)—, or a group represented by a combination of at least two thereof, and R³'s each independently represent a hydrogen atom, an alkyl group which may have a substituent, or an aryl group which may have a substituent, A represents a divalent linking group, and Ar represents an aryl group or a heteroaryl group.

<2> The composition according to <1>, in which at least one of Z's is bonded to a β-position of the compound represented by Formula 1.

<3> The composition according to <1> or <2>, in which the compound represented by Formula 1 is a compound represented by Formula 3.

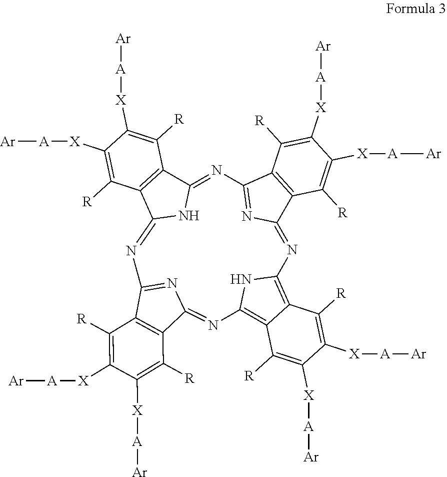

In Formula 3, R's each independently represent a hydrogen atom or a monovalent substituent which is different from Z, X's each independently represent —O—, —S—, —NR³—, —(C═O)—, or a group represented by a combination of at least two thereof, R³'s each independently represent a hydrogen atom, an alkyl group which may have a substituent, or an aryl group which may have a substituent, A's each independently represent a divalent linking group, and Ar's each independently represent an aryl group or a heteroaryl group.

<4> The composition according to any one of <1> to <3>, in which X's are each independently —O—, —S—, or —NR³—, A's are each independently an alkylene group having 1 to 4 carbon atoms, which may have a substituent, and may contain —O—, —S—, or —NR³— in a site other than a bonding site to X, R³'s each independently represent a hydrogen atom, an alkyl group which may have a substituent, or an aryl group which may have a substituent, and R's are each independently a hydrogen atom or a halogen atom.

<5> The composition according to any one of <1> to <4>, in which a content of the compound represented by Formula 1 is 40% by mass or more with respect to a total solid content of the composition.

<6> The composition according to any one of <1> to <5>, in which the compound represented by Formula 1 has a solubility of 0.1% by mass or less in the composition.

<7> The composition according to any one of <1> to <6>, further comprising: a yellow pigment.

<8> The composition according to any one of <1> to <7>, further comprising:

a polymerization initiator,

in which the polymerizable compound is an ethylenically unsaturated compound.

<9> A cured product obtained by curing the composition according to any one of <1> to <8>.

<10> A color filter comprising:

the cured product according to <9>.

<11> A method for producing a color filter, comprising:

a step of applying the composition according to any one of 1 to 8 onto a support to form a composition film;

a step of exposing the formed composition film to light in a pattern-wise manner; and

a step of developing the composition film after exposure to form a colored pattern.

<12> A method for producing a color filter, comprising:

a step of applying the composition according to any one of 1 to 8 onto a support and curing the applied composition to form a cured product;

a step of forming a photoresist layer on the cured product;

a step of exposing the photoresist layer to light in a pattern-wise manner and developing the exposed photoresist layer to form a resist pattern; and

a step of etching the cured product through the resist pattern.

<13> A solid-state imaging element comprising:

the color filter according to <10>.

<14> An image display device comprising:

the color filter according to <10>.

<15> A compound represented by Formula 4.

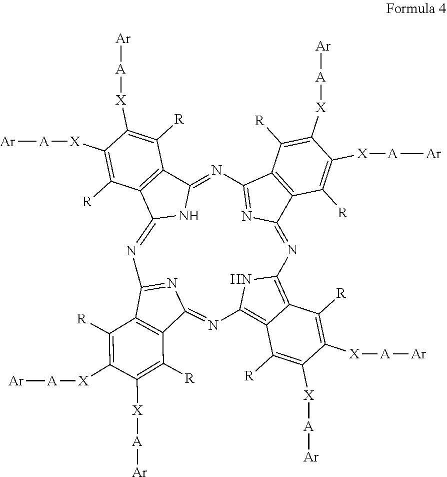

In Formula 4, X's each independently represent —O—, —S—, or —NR³—, A's each independently represent an alkylene group having 1 to 4 carbon atoms, which may have a substituent, and may contain —O—, —S—, or —NR³— in a site other than a bonding site to X, Ar's each independently represent an aryl group or a heteroaryl group, R³'s each independently represent a hydrogen atom, an alkyl group which may have a substituent, or an aryl group which may have a substituent, and R's each independently represent a hydrogen atom or a halogen atom.

According to the embodiment of the present disclosure, there are provided a composition having excellent spectral characteristics of a cured product to be obtained, a cured product of the composition, a color filter comprising the cured product, a method for producing the color filter, and a solid-state imaging element or an image display device, each of which comprising the color filter.

In addition, according to another embodiment of the present disclosure, there is provided a novel compound.

### BRIEF DESCRIPTION OF THE DRAWINGS

FIG. 1 is a schematic diagram of an absorption wavelength-absorbance curve for explaining sharp edge of absorption.

### DESCRIPTION OF THE PREFERRED EMBODIMENTS

Hereinafter, the contents of the present disclosure will be described in detail. The description of constituent elements described below may be based on representative embodiments of the present disclosure, but the present disclosure is not limited to such embodiments.

In the present disclosure, a term “to” indicating a numerical range is used as a meaning including numerical values described before and after the term as a lower limit value and an upper limit value, respectively.

In a numerical range described in a stepwise manner in the present disclosure, an upper limit value or a lower limit value described in a certain numerical range may be replaced with an upper limit value or a lower limit value of another numerical range described in a stepwise manner. In addition, in the numerical range described in the present disclosure, the upper limit value or the lower limit value of the numerical range may be replaced with the values shown in the Examples.

Further, in the present disclosure, in a case where a plurality of substances corresponding to components are present in the composition, the amount of each component in the composition means a total amount of the plurality of substances present in the composition, unless otherwise specified.

Regarding a term, group (atomic group) in the present disclosure, a term with no description of “substituted” and “unsubstituted” includes both a group not having a substituent and a group having a substituent. For example, an “alkyl group” includes not only an alkyl group having no substituent (unsubstituted alkyl group), but also an alkyl group having a substituent (substituted alkyl group).

In the present disclosure, unless otherwise specified, “Me” represents a methyl group, “Et” represents an ethyl group, “Pr” represents a propyl group, “Bu” represents a butyl group, and “Ph” represents a phenyl group.

In the present disclosure, “(meth)acrylic” is a term used as a concept including both acrylic and methacrylic, and “(meth)acryloyl” is a term used as a concept including both acryloyl and methacryloyl.

In the present disclosure, a term “step” not only includes an independent step, but also includes a step, even in a case where the step may not be clearly distinguished from the other step, as long as the expected object of the step is achieved.

In the present disclosure, the term “total solid content” refers to a total mass of components excluding a solvent from the total composition of the composition. In addition, the “solid content” is a component excluding a solvent, as described above, and may be a solid or a liquid at 25° C., for example.

In addition, in the present disclosure, “% by mass” is identical to “% by weight” and “parts by mass” is identical to “parts by weight”.

Further, in the present disclosure, a combination of two or more preferred aspects is a more preferred aspect.

In addition, unless otherwise noted, a weight-average molecular weight (Mw) and a number-average molecular weight (Mn) in the present disclosure are molecular weights in terms of polystyrene as a standard substance, following the detection by a gel permeation chromatography (GPC) analyzer using columns of TSKgel GMHxL, TSKgel G4000HxL, and TSKgel G2000HxL (all of which are trade names manufactured by Tosoh Corporation), using tetrahydrofuran (THF) as a solvent and a differential refractometer.

Hereinafter, the present disclosure will be described in detail.

(Composition)

The composition according to the present disclosure includes a compound represented by Formula 1 and having a maximum absorption wavelength in a range of 600 nm or more and less than 750 nm (hereinafter, also referred to as “specific compound”), and a polymerizable compound.

A cured product having excellent spectral characteristics can be obtained by using the composition according to the present disclosure.

The details of the mechanism by which the above effect is obtained are unknown, but are presumed as follows.

As the phthalocyanine compound, a compound which forms a complex with a metal such as copper or zinc in a central portion of the structure is known. For example, a commercially available Color Index (C.I.) Pigment Blue 15:6 is a compound having a structure represented by a formula shown below.

However, it is considered that the specific compound according to the present disclosure does not include the above metal in the central portion of the structure, so that the planarity of the compound in the crystal becomes large and an influence of a π interaction between the molecules of the specific compound is likely to increase.

In addition, it is considered that the specific compound according to the present disclosure has at least four groups represented by Formula 2 as Z, which further affects the π interaction due to an aryl group included in Formula 2, and thus the influence of the π interaction between the molecules of the specific compound is likely to increase.

It is considered that, as a result of an increase in the π interaction between the molecules of the specific compound as described above, the edge of absorption in the specific compound becomes sharper and thus the spectral characteristics are improved even in a cured product of a composition containing such a compound.

In addition, the “sharp edge of absorption” means that an absolute value of a slope is large in a region where the absorbance is small, in an absorption wavelength-absorbance curve.

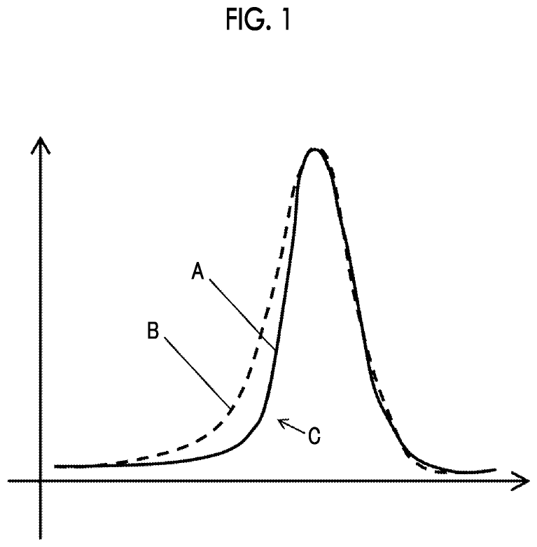

The sharp edge of absorption will be described with reference to FIG. 1.

FIG. 1 shows an absorption wavelength-absorbance curve of two compounds (compound A (solid line) and compound B (dashed line)), where a lateral axis indicates the absorption wavelength and a vertical axis indicates the absorbance.

Here, the absolute value of the slope of the compound A in the region where the absorbance is small (the region near the arrow C) is larger than that of the compound B. That is, it can be said that the compound A has a sharper edge of absorption than the compound B.

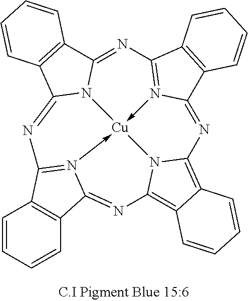

In addition, it is considered that the specific compound according to the present disclosure is more likely to have excellent light resistance than a phthalocyanine coloring agent containing a metal element such as zinc.

Further, it is considered that the specific compound according to the present disclosure contains four or more groups represented by Formula 2, which is more likely to result in excellent storage stability of the composition.

Hereinafter, details of each component included in the composition according to the present disclosure will be described.

<Specific Compound>

The specific compound used in the present disclosure is a compound represented by Formula 1 and having a maximum absorption wavelength in a range of 600 nm or more and less than 750 nm.

In addition, the specific compound is preferably a colorant and more preferably a pigment.

In the present disclosure, the pigment means a coloring agent compound that is insoluble in a solvent. In addition, the dye refers to a coloring agent compound that is soluble in a solvent.

For example, the pigment used in the present disclosure preferably has a solubility in 100 g of propylene glycol monomethyl ether acetate at 25° C. and a solubility in 100 g of water at 25° C. of both 0.1 g or less, more preferably 0.05 g or less, and still more preferably 0.01 g or less. In addition, the dye used in the present disclosure has at least one of a solubility in 100 g of propylene glycol monomethyl ether acetate at 25° C. or a solubility in 100 g of water at 25° C. of preferably more than 0.1 g, more preferably 1 g or more, and still more preferably 5 g or more.

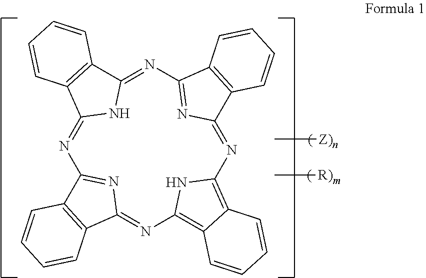

In Formula 1, Z's each independently represent a group represented by Formula 2, n represents an integer of 4 to 16, and R's each independently represent a hydrogen atom or a monovalent substituent which is different from Z, m represents an integer of 0 to 12, and m+n is 16.

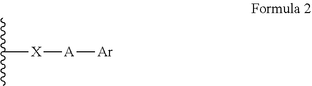

In Formula 2, X is —O—, —S—, —NR³—, —(C═O)—, or a group represented by a combination of at least two thereof, and R³'s each independently represent a hydrogen atom, an alkyl group which may have a substituent, or an aryl group which may have a substituent, A represents a divalent linking group, and Ar represents an aryl group or a heteroaryl group.

[Z]

In Formula 1, Z's each independently represent a group represented by Formula 2.

It is preferable that at least one of Z's is bonded to the β-position of the compound represented by Formula 1, it is more preferable that at least two of Z's are bonded to the β-position of the compound represented by Formula 1, and it is still more preferable that at least four of Z's are bonded to the β-position of the compound represented by Formula 1.

In the present disclosure, that at least one of Z's is bonded to the β-position of the compound represented by Formula 1 means that at least one of Z's is present at a position described by β in Formula 1-1.

Sixteen positions described by α and β in Formula 1-1 are positions where Z and R described later in the compound represented by Formula 1 are bonded.

As shown in Formula 1-1, the compound represented by Formula 1 has eight β positions, and it is preferable that Z is bonded to at least two of the eight β positions and it is more preferable that Z is bonded to at least four of the eight β positions.

In addition, from the viewpoint of spectral characteristics, it is preferable that Z is bonded to all β positions of the compound represented by Formula 1, and it is preferable that Z is bonded to all β-positions of the compound represented by Formula 1 and that Z is not bonded to all α-positions of the compound represented by Formula 1. Specifically, the compound represented by Formula 1 is preferably a compound represented by Formula 3 which will be described later.

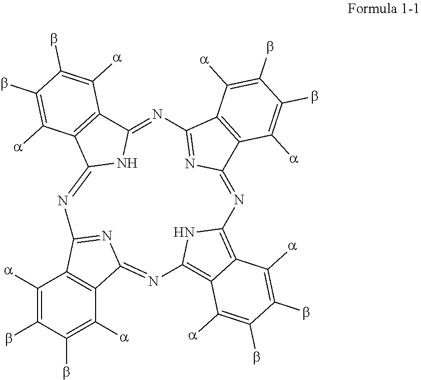

[Compound Represented by Formula 3]

The compound represented by Formula 1 is preferably a compound represented by Formula 3.

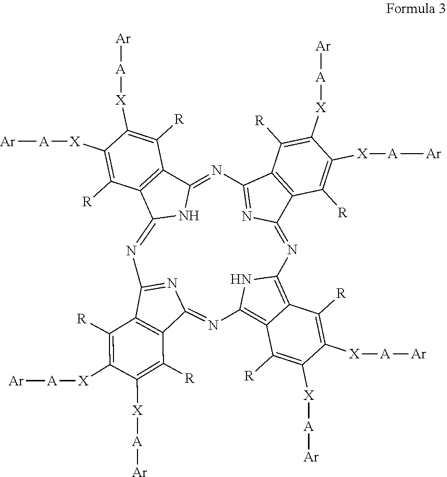

In Formula 3, R's each independently represent a hydrogen atom or a monovalent substituent which is different from Z, X's each independently represent —O—, —S—, —NR³—, —(C═O)—, or a group represented by a combination of at least two thereof, R³'s each independently represent a hydrogen atom, an alkyl group which may have a substituent, or an aryl group which may have a substituent, A's each independently represent a divalent linking group, and Ar's each independently represent an aryl group.

In Formula 3, a group represented by —X-A-Ar has the same meaning as the group represented by Z in Formula 1 (that is, the group represented by Formula 2), and a preferred aspect thereof is also the same.

In addition, R in Formula 3 has the same meaning as the group represented by R in Formula 1, and a preferred aspect thereof is also the same.

[Group Represented by Formula 2]

X's are each independently —O—, —S—, —NR³—, —(C═O)—, or a group represented by a combination of at least two thereof, and R³'s each independently represent a hydrogen atom, an alkyl group which may have a substituent, or an aryl group which may have a substituent.

X is preferably, for example, —O—, —S—, —NR³—, —C(═O)—, —OC(═O)—, —SC(═O)—, —NR³C(═O)—, —NR³C(═O)O—, —NR³C(═O)NR³—, —OC(═O)O—, —OC(═O)S—, or —OC(═O)NR³—. In the present disclosure, the direction of the bond of the divalent group is not particularly limited unless otherwise specified. Specifically, for example, in a case where X is described to be —OC(═O)—, the oxygen atom side may be bonded to A, or the carbon atom side (—C(═O)— side) may be bonded to A.

In addition, R³ is preferably a hydrogen atom, an alkyl group having 1 to 10 carbon atoms which may have a substituent, or an aryl group having 6 to 20 carbon atoms which may have a substituent, and more preferably a hydrogen atom, an alkyl group having 1 to 4 carbon atoms which may have a substituent, or a phenyl group which may have a substituent.

The substituent which the alkyl group may have is not particularly limited and examples thereof include an aryl group, a halogen atom, an alkoxy group, an aryloxy group, a dialkylamino group, an alkylarylamino group, a diarylamino group, an alkylthio group, and an arylthio group.

The substituent which the aryl group may have is not particularly limited and examples thereof include an alkyl group, an aryl group, a halogen atom, an alkoxy group, an aryloxy group, a dialkylamino group, an alkylarylamino group, a diarylamino group, an alkylthio group, and an arylthio group.

In addition, from the viewpoint that the maximum absorption wavelength is likely to be in a range of 600 nm or more and less than 750 nm, X's are each independently preferably —O—, —S—, or —NR³—.

—A—

A's each independently represent a divalent linking group. The number of linking atoms in the divalent linking group is preferably 1 to 12, more preferably 1 to 8, and still more preferably 1 to 6, from the viewpoint of light resistance and color value.

In the present disclosure, the divalent linking group does not include a single bond.

The number of linking atoms refers to the number of atoms in A that connect a bonding site to X and a bonding site to Ar in the shortest distance.

In the present disclosure, the color value is a value indicating a light absorption coefficient per unit mass.

In addition, A is preferably a hydrocarbon group which may contain —O—, —S—, —NR³—, —(C═O)—, or a group represented by a combination of at least two thereof at a position other than a bonding site to X.

Examples of the hydrocarbon group include an alkylene group, an arylene group, and a group represented by a bond thereof.

The —O—, —S—, —NR³—, —(C═O)—, and group represented by a combination of at least two thereof are the same as those groups in X.

In addition, A is preferably an alkylene group, an arylene group, an alkyleneoxy group, a polyalkyleneoxy group, —R^{A}—NR³—, —R^{A}—S—, or a group represented by a combination of at least two thereof. The alkylene group is preferably an alkylene group having 1 to 6 carbon atoms.

The arylene group is preferably a phenylene group.

The alkyleneoxy group is preferably an alkyleneoxy group having 1 to 6 carbon atoms.

The polyalkyleneoxy group is more preferably a polyethyleneoxy group or a polypropyleneoxy group.

R^{A} in —R^{A}—NR³— or —R^{A}—S— represents a hydrocarbon group, and is preferably an alkylene group having 1 to 6 carbon atoms or a phenylene group. R³ has the same meaning as R³ in X described above, and a preferred aspect thereof is also the same.

In addition, from the viewpoint of improving the sharpness of absorption-edge wavelength, A is more preferably an alkylene group which may have a substituent having 1 to 4 carbon atoms and may contain a group represented by —O—, —S—, or —NR³— at a position other than a bonding site to X.

R³ has the same meaning as R³ in X described above, and a preferred aspect thereof is also the same.

Examples of the substituent having 1 to 4 carbon atoms include alkyl groups having 1 to 4 carbon atoms, such as a methyl group, an ethyl group, a normal propyl group, an isopropyl group, and a butyl group, each of which has 1 to 4 carbon atoms.

—Ar—

Ar's each independently represent an aryl group or a heteroaryl group.

From the viewpoint of color value, the aryl group is preferably an aryl group having 4 to 10 carbon atoms and more preferably a phenyl group.

The hetero atom in the heteroaryl group is preferably an oxygen atom, a nitrogen atom, or a sulfur atom. In addition, the heteroaryl group is preferably a heteroaryl group having 3 to 9 carbon atoms and more preferably a pyridyl group, a quinolyl group, a furanyl ring, a thienyl group, or a pyrrolyl group.

Ar may have a substituent, and preferred examples of the substituent include a phenyl group, a naphthyl group, and a heteroaryl group, among which a phenyl group or a naphthyl group is preferable from the viewpoint of light resistance, and a phenyl group is more preferable from the viewpoint of color value.

The hetero atom in the heteroaryl group is preferably an oxygen atom, a nitrogen atom, or a sulfur atom. In addition, the heteroaryl group is preferably a heteroaryl group having 3 to 9 carbon atoms and more preferably a pyridyl group, a quinolyl group, or a thienyl group.

[n, m]

In Formula 1, n represents an integer of 4 to 16, preferably an integer of 4 to 12, and more preferably an integer of 6 to 10.

That is, m is preferably an integer of 0 to 12, more preferably an integer of 4 to 12, and still more preferably an integer of 6 to 10.

In a case where n is 6 or more, the sharpness of absorption-edge wavelength in the specific compound is improved, and thus the spectral characteristics of the resulting cured product are more likely to be excellent.

In addition, in a case where n is 12 or less (more preferably, 10 or less), the light resistance is likely to be excellent.

Furthermore, it is also possible to adjust the maximum absorption wavelength of the specific compound by the number of n. It is considered that the smaller the n is, the shorter the maximum absorption wavelength becomes, and the larger the n is, the longer the maximum absorption wavelength becomes.

[R]

R's each independently represent a hydrogen atom or a monovalent substituent which is different from Z, and is preferably a hydrogen atom, an alkyl group, an aryl group, a halogen atom, —OR¹, —NR¹R², or —SR¹.

In addition, R is preferably a hydrogen atom or a halogen atom from the viewpoint of color value.

The alkyl group is preferably an alkyl group having 1 to 10 carbon atoms and more preferably an alkyl group having 1 to 4 carbon atoms.

The aryl group is preferably an aryl group having 6 to 20 carbon atoms and more preferably a phenyl group.

The halogen atom is preferably a fluorine atom, a chlorine atom, a bromine atom, or an iodine atom and more preferably a fluorine atom, a chlorine atom, or a bromine atom.

R¹ is an alkyl group, an aryl group, or an aralkyl group and preferably an alkyl group having 1 to 10 carbon atoms, an aryl group having 6 to 20 carbon atoms, or an aralkyl group having 7 to 24 carbon atoms.

R² represents the same group as R¹, and in —NR¹R², R¹ and R² may be the same group or different groups.

From the viewpoint of the spectral characteristics, color value, and light resistance of a cured film to be obtained, it is preferable that X's are each independently —O—, —S—, or —NR³—, A's are each independently an alkylene group having 1 to 4 carbon atoms which may have a substituent and may contain —O—, —S—, or —NR³— in a site other than a bonding site to X, R³'s each independently represent a hydrogen atom, an alkyl group which may have a substituent, or an aryl group which may have a substituent, and R's are each independently a hydrogen atom or a halogen atom.

In addition, it is preferable that X's are each independently —O—, —S—, or —NR³—, A's are each independently an alkylene group having 1 to 4 carbon atoms which may have a substituent and may contain —O—, —S—, or —NR³— in a site other than a bonding site to X, R³'s each independently represent a hydrogen atom, an alkyl group which may have a substituent, or an aryl group which may have a substituent, Ar is a phenyl group, and R's are each independently a hydrogen atom or a halogen atom.

In addition, it is preferable that the specific compound has a point-symmetric structure or a line-symmetric structure in the structure described in a plane as in Formula 3.

(Maximum Absorption Wavelength)

The maximum absorption wavelength of the compound represented by Formula 1 is preferably in a wavelength range of 650 nm to 750 nm and more preferably in a wavelength range of 650 nm to 730 nm.

The maximum absorption wavelength is measured using a Cary 5000 UV-Vis-NIR spectrophotometer (manufactured by Agilent Technologies, Inc.).

In addition, the compound represented by Formula 1 preferably has a maximum absorption wavelength in a wavelength range of 400 nm to 1200 nm in a wavelength range of 600 nm to 750 nm, more preferably in a wavelength range of 650 nm to 750 nm, and still more preferably in a wavelength range of 650 nm to 730 nm.

[Average Particle Size]

In a case where the specific compound is a pigment, the average particle size thereof is preferably 0.01 μm to 0.2 μm and more preferably 0.01 μm to 0.1 μm.

In the present disclosure, unless otherwise specified, the average particle size of the pigment is measured on a volume basis using a MICROTRAC UPA 150 (manufactured by Nikkiso Co., Ltd).

[Content]

The content of the specific compound in the composition according to the present disclosure is preferably 20% by mass or more, more preferably 30% by mass or more, and still more preferably 40% by mass or more with respect to the total solid content of the composition.

In addition, the content is preferably 80% by mass or less, more preferably 70% by mass or less, and still more preferably 60% by mass or less.

In addition, in a case where the composition according to the present disclosure contains a chromatic colorant (preferably a yellow pigment) which will be described later, the content ratio (mass ratio) of the specific compound and the chromatic colorant is preferably specific compound:chromatic colorant=8:1 to 2:1, more preferably 6:1 to 2:1, and still more preferably 6:1 to 3:1, from the viewpoint of spectral characteristics, curing properties, and developability during pattern formation.

[Solubility]

The solubility of the specific compound in the composition according to the present disclosure is preferably 0.1% by mass or less, more preferably 0.08% by mass or less, and still more preferably 0.05% by mass or less.

Here, the solubility of 0.1% by mass or less means that the mass of the specific compound dissolved in 1 g of the composition is 0.001 g or less.

In addition, the solubility of the specific compound is preferably 0% by mass or more. Here, the solubility of 0% by mass means that the specific compound does not dissolve in the composition.

The solubility of the specific compound in the composition is measured by the following method.

The composition is filtered through a filter having a pore size of 0.5 μm and the filtrate is diluted with N-methyl-2-pyrrolidone (NMP). The diluted solution is measured for solution visible absorption spectrum and the concentration of the specific compound in the solution is calculated, whereby the solubility of the specific compound in the composition is measured. The temperature of the composition at the time of the filtration is 25° C.

Hereinafter, compounds Pc-1 to Pc-121, which are specific examples of the specific compound, are shown, but the present invention is not limited thereto.

Pc-1 to Pc-89 are compounds represented by Formula Pc1, which have the structures in which X, A, Ar, and R are as shown in tables which will be given later.

In Table 1 to Table 4, C₆H₄ represents a phenylene group, and Ar¹, Ar², and Ar³ represent the following structures, respectively. In the following structures, the wavy line portion indicates a bonding site to A.

In Table 1 to Table 4, for the structures described in the column of “A”, the left side of the structure indicates a bonding site to A, and the right side of the structure indicates a bonding site to Ar. For example, in a case where —(CH₂CH₂O)₂— is described in the column of “A”, it indicates that the bonding site which is a carbon atom is bonded to X, and the bonding site which is an oxygen atom is bonded to Ar.

Similarly, for the structures described in the column of “X”, the right side of the structure is a bonding site to A.

In Table 1 to Table 6 shown below, the description in the column of “λₘₐₓ” indicates the maximum absorption wavelength of each specific compound.

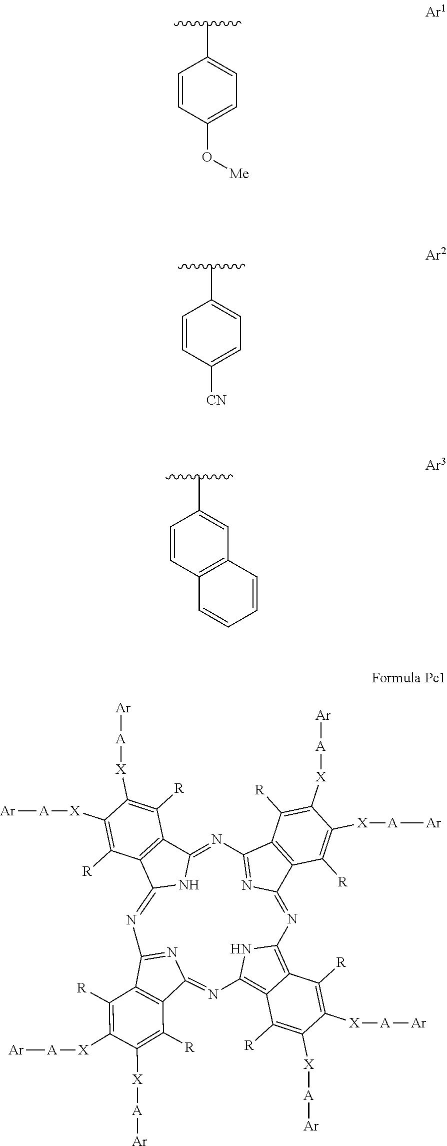

TABLE 1

| | X | A | Ar | R | λₘₐₓ |
|---|---|---|---|---|---|
| Pc-1 | —O— | —CH₂— | —Ph | —H | 683 |
| Pc-2 | —O— | —CH₂— | —Ph | —Cl | 701 |
| Pc-3 | —O— | —CH₂— | —Ph | —Me | 695 |
| Pc-4 | —O— | —CH₂— | —Ph | —Bu | 697 |
| Pc-5 | —O— | —CH₂— | —Ph | —SCH₂CH₃ | 705 |
| Pc-6 | —O— | —(CH₂)₂— | —Ph | —H | 683 |
| Pc-7 | —O— | —(CH₂)₂— | —Ph | —Ph | 698 |
| Pc-8 | —O— | —(CH₂)₂— | —Ph | —NMe₂ | 705 |
| Pc-9 | —O— | —(CH₂)₂— | —Ph | —Br | 701 |
| Pc-10 | —O— | —(CH₂)₂— | —Ph | —Cl | 701 |
| Pc-11 | —O— | —(CH₂)₂— | —Ar¹ | —F | 700 |
| Pc-12 | —O— | —(CH₂)₂— | —Ph | —OMe | 705 |
| Pc-13 | —O— | —(CH₂)₂— | —Ar¹ | —Cl | 701 |
| Pc-14 | —O— | —(CH₂)₃— | —Ar² | —Cl | 701 |
| Pc-15 | —O— | —(CH₂)₂— | —Ar³ | —Cl | 701 |
| Pc-16 | —O— | —(CH₂)₄— | —Ar² | —F | 700 |
| Pc-17 | —O— | —(CH₂)₆— | —Ph | —H | 683 |
| Pc-18 | —O— | —(CH₂CH₂O)₂— | —Ph | —H | 683 |
| Pc-19 | —O—C(═O)— | —CH₂CH₂— | —Ph | —Cl | 703 |
| Pc-20 | —O— | —CH₂CH₂S— | —Ph | —H | 683 |
| Pc-21 | —O— | —CH₂CH₂NH— | —Ph | —H | 683 |
| Pc-22 | —O—C(═O)— | —CH₂— | —Ph | —H | 685 |
| Pc-23 | —O—C(═O)O— | —CH₂— | —Ph | —H | 687 |
| Pc-24 | —O—C(═O)NH— | —CH₂— | —Ph | —H | 685 |
| Pc-25 | —O—C(═O)S— | —CH₂— | —Ph | —H | 685 |
| Pc-26 | —O— | —CH₂—C(═O)—CH₂CH₂— | —Ph | —H | 683 |
| Pc-27 | —O— | —CH₂—C₆H₄—CH₂CH₂— | —Ph | —H | 683 |
| Pc-28 | —NH— | —CH₂— | —Ph | —H | 712 |
| Pc-29 | —NH— | —CH₂— | —Ph | —Cl | 722 |
| Pc-30 | —NH— | —CH₂— | —Ph | —Me | 718 |
| Pc-31 | —NH— | —CH₂— | —Ph | —Bu | 718 |
| Pc-32 | —NH— | —CH₂— | —Ph | —SCH₂CH₃ | 732 |
| Pc-33 | —NH— | —(CH₂)₂— | —Ph | —H | 712 |
| Pc-34 | —NH— | —(CH₂)₂— | —Ph | —Ph | 720 |
| Pc-35 | —NH— | —(CH₂)₂— | —Ph | —NMe₂ | 735 |
| Pc-36 | —NH— | —(CH₂)₂— | —Ph | —Br | 722 |
| Pc-37 | —NH— | —(CH₂)₂— | —Ph | —Cl | 722 |

TABLE 2

| | X | A | Ar | R | λₘₐₓ |
|---|---|---|---|---|---|
| Pc-38 | —NH— | —(CH₂)₂— | —Ar¹ | —F | 722 |
| Pc-39 | —NH— | —(CH₂)₂— | —Ph | —OMe | 724 |
| Pc-40 | —NH— | —(CH₂)₂— | —Ar¹ | —Cl | 722 |
| Pc-41 | —NH— | —(CH₂)₂— | —Ar² | —Cl | 722 |
| Pc-42 | —NH— | —(CH₂)₂— | —Ar³ | —Cl | 722 |
| Pc-43 | —NH— | —(CH₂)₄— | —Ar² | —Cl | 722 |
| Pc-44 | —NH— | —(CH₂)₆— | —Ph | —H | 712 |
| Pc-45 | —NH— | —(CH₂CH₂O)₂— | —Ph | —H | 712 |
| Pc-46 | —NH—C(═O)— | —CH₂CH₂— | —Ph | —Cl | 722 |
| Pc-47 | —NH— | —CH₂CH₂S— | —Ph | —H | 712 |
| Pc-48 | —NH— | —CH₂CH₂NH— | —Ph | —H | 712 |
| Pc-49 | —NH—C(═O)— | —CH₂— | —Ph | —H | 721 |
| Pc-50 | —NH—C(═O)O— | —CH₂— | —Ph | —H | 722 |
| Pc-51 | —NH—C(═O)NH— | —CH₂— | —Ph | —H | 721 |
| Pc-52 | —NH—C(═O)H— | —CH₂— | —Ph | —H | 721 |
| Pc-53 | —NH— | —CH₂—C(═O)—CH₂CH₂— | —Ph | —H | 713 |
| Pc-54 | —NH— | —CH₂—C₆H₄—CH₂CH₂— | —Ph | —H | 713 |
| Pc-55 | —NMe— | —(CH₂)₂— | —Ph | —H | 715 |
| Pc-56 | —NMe— | —(CH₂)₂— | —Ph | —Br | 725 |
| Pc-57 | —NMe— | —(CH₂)₂— | —Ph | —Cl | 726 |
| Pc-58 | —NMe— | —(CH₂)₂— | —Ph | —F | 725 |
| Pc-59 | —NMe— | —(CH₂)₂— | —Ar¹ | —Cl | 726 |
| Pc-60 | —NMe— | —(CH₂)₂— | —Ar² | —Cl | 726 |
| Pc-61 | —NMe— | —(CH₂)₂— | —Ar³ | —Cl | 726 |
| Pc-62 | —NPh— | —(CH₂)₂— | —Ph | —H | 717 |
| Pc-63 | —NPh— | —(CH₂)₂— | —Ph | —Br | 727 |
| Pc-64 | —NPh— | —(CH₂)₂— | —Ph | —Cl | 728 |
| Pc-65 | —NPh— | —(CH₂)₂— | —Ph | —F | 727 |
| Pc-66 | —S— | —CH₂— | Ph | —H | 703 |
| Pc-67 | —S— | —CH₂— | —Ph | —Cl | 714 |
| Pc-68 | —S— | —CH₂— | —Ph | —Me | 713 |
| Pc-69 | —S— | —CH₂— | —Ph | —Bu | 713 |
| Pc-70 | —S— | —CH₂— | —Ph | —SCH₂CH₃ | 723 |
| Pc-71 | —S— | —(CH₂)₂— | —Ph | —H | 703 |
| Pc-72 | —S— | —(CH₂)₂— | —Ar¹ | —H | 703 |
| Pc-73 | —S— | —(CH₂)₂— | —Ar² | —H | 703 |
| Pc-74 | —S— | —(CH₂)₂— | —Ar³ | —Cl | 714 |

TABLE 3

| | X | A | Ar | R | λₘₐₓ |
|---|---|---|---|---|---|
| Pc-75 | —S— | —(CH₂)₂— | —Ph | —Cl | 714 |
| Pc-76 | —S— | —(CH₂)₂— | —Ph | —Br | 715 |
| Pc-77 | —S— | —(CH₂)₄— | —Ph | —H | 703 |
| Pc-78 | —S— | —(CH₂)₂— | —Ph | —Ph | 710 |
| Pc-79 | —S— | —(CH₂)₂— | —Ph | —NMe₂ | 733 |
| Pc-80 | —S— | —(CH₂CH₂O)₂— | —Ph | —H | 703 |
| Pc-81 | —S—C(═O)— | —CH₂CH₂— | —Ph | —H | 708 |
| Pc-82 | —S— | —CH₂CH₂S— | —Ph | —H | 703 |
| Pc-83 | —S— | —CH₂CH₂NH— | —Ph | —H | 703 |
| Pc-84 | —S—C(═O)— | —CH₂— | —Ph | —H | 708 |
| Pc-85 | —S—C(═O)O— | —CH₂— | —Ph | —H | 709 |
| Pc-86 | —S—C(═O)N— | —CH₂— | —Ph | —H | 708 |
| Pc-87 | —S—C(═O)S— | —CH₂— | —Ph | —H | 708 |
| Pc-88 | —S— | —CH₂—C(═O)—CH₂CH₂— | —Ph | —H | 703 |
| Pc-89 | —S— | —CH₂—C₆H₄—CH₂CH₂— | —Ph | —H | 703 |

Pc-90 to Pc-113 are compounds represented by Formula Pc2, which have the structures in which X, A, Ar, and R are as shown in tables which will be given later.

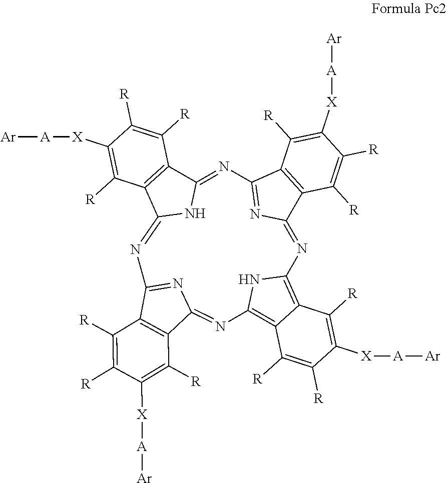

TABLE 4

| | X | A | Ar | R | λₘₐₓ |
|---|---|---|---|---|---|
| Pc-90 | —O— | —CH₂— | —Ph | —H | 658 |
| Pc-91 | —O— | —CH₂— | —Ph | —Me | 668 |
| Pc-92 | —O— | —(CH₂)₂— | —Ph | —Br | 677 |
| Pc-93 | —O— | —(CH₂)₂— | —Ph | —Ph | 680 |
| Pc-94 | —O— | —(CH₂)₂— | —Ph | —Cl | 680 |
| Pc-95 | —O— | —(CH₂)₄— | —Ph | —F | 680 |
| Pc-96 | —O— | —(CH₂)₄— | —Ph | —OMe | 703 |
| Pc-97 | —NH— | —CH₂— | —Ph | —H | 681 |
| Pc-98 | —NH— | —CH₂— | —Ph | —Me | 691 |
| Pc-99 | —NH— | —(CH₂)₂— | —Ph | —Br | 700 |
| Pc-100 | —NH— | —(CH₂)₂— | —Ph | —Ph | 701 |
| Pc-101 | —NH— | —(CH₂)₂— | —Ph | —Cl | 700 |
| Pc-102 | —NH— | —(CH₂)₄— | —Ph | —F | 700 |
| Pc-103 | —NH— | —(CH₂)₄— | —Ph | —OMe | 726 |
| Pc-104 | —NMe— | —(CH₂)₂— | —Ph | —Cl | 702 |
| Pc-105 | —NPh— | —(CH₂)₂— | —Ph | —Cl | 705 |
| Pc-106 | —S— | —CH₂— | —Ph | —H | 672 |
| Pc-107 | —S— | —CH₂— | —Ph | —Me | 682 |
| Pc-108 | —S— | —(CH₂)₂— | —Ph | —Br | 691 |
| Pc-109 | —S— | —(CH₂)₂— | —Ph | —Ph | 692 |
| Pc-110 | —S— | —(CH₂)₂— | —Ph | —Cl | 692 |
| Pc-111 | —S— | —(CH₂)₄— | —Ph | —F | 693 |
| Pc-112 | —S— | —(CH₂)₄— | —Ph | —OMe | 703 |

Pc-114 to Pc-121 are compounds having the structures described in the column of “S” in tables which will be given later. “Z” and “R” in chemical formulae described in the column of “S” represent the structures described in the columns of “Z” and “R”. In addition, * in the column of “Z” represents a bonding site to the structure described in the column of “S”.

The description of “↑” in each column of “Pc-115” to “Pc-117” indicates that the structure is the same as the structure of each column in “Pc-14”.

TABLE 5

| | S | Z | R | λₘₐₓ |
|---|---|---|---|---|
| Pc-113 | 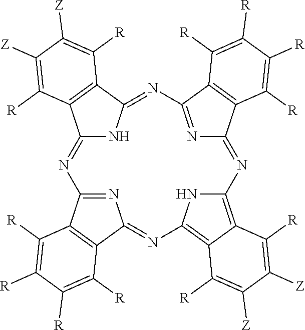 | 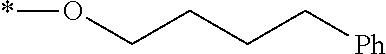 [SMILES: *OCCCCc1ccccc1] | —H | 660 |
| Pc-114 | 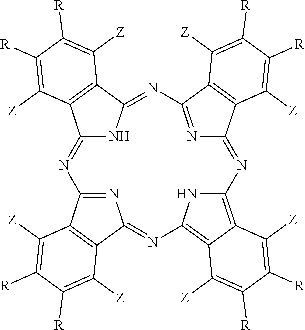 | 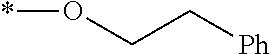 [SMILES: *OCCc1ccccc1] | —H | 684 |
| Pc-115 | ⬆ | ⬆ | —F | 695 |
| Pc-116 | ⬆ | 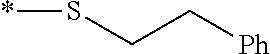 [SMILES: *SCCc1ccccc1] | —H | 694 |
| Pc-117 | ⬆ | 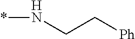 [SMILES: *NCCc1ccccc1] | —Cl | 702 |
| Pc-118 | 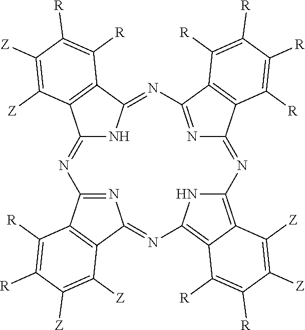 | 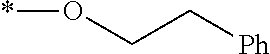 [SMILES: *OCCc1ccccc1] | —H | 688 |

TABLE 6

| No. | S | Z | R | λₘₐₓ |
|---|---|---|---|---|
| Pc-119 | 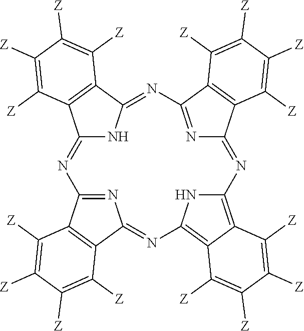 | 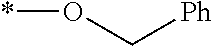 [SMILES: *OCc1ccccc1] | — | 722 |
| Pc-120 | 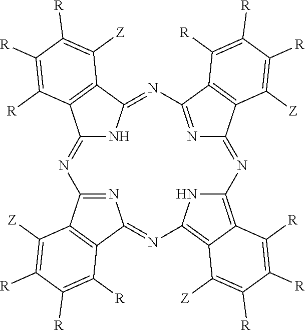 | 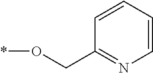 [SMILES: *OCc1ccccn1] | —Cl | 658 |
| Pc-121 | 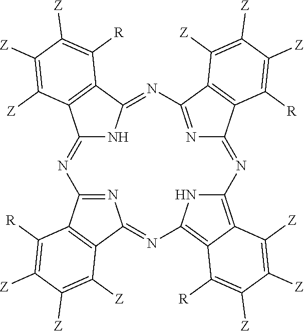 | 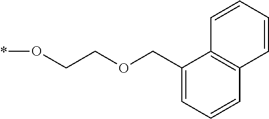 [SMILES: *OCCOCc1cccc2ccccc12] | —H | 703 |

(Method for Producing Specific Compound)

The production of the specific compound according to the present disclosure can be carried out as follows.

In a case where a corresponding phthalonitrile compound is reacted in 1-pentanol at 160° C. in the presence of diazabicycloundecene (DBU), a symmetric specific compound is precipitated and therefore can be easily isolated by filtration.

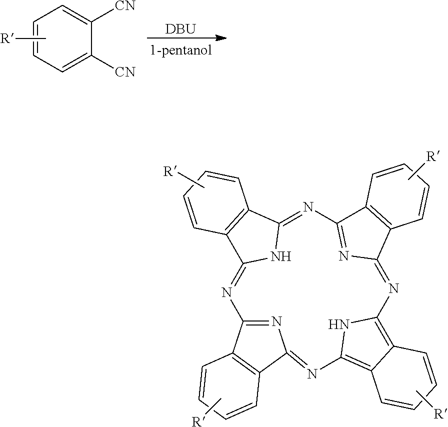

In addition, in a case of an asymmetric specific compound, a 3-to-1 form compound is obtained by preparing the compound according to the method described in J. Am. Chem. Soc., 1990, 112, 9640. A 2-to-2 form compound is obtained by preparing several mixtures of two types of phthalonitriles in the same manner as in the symmetric form and then separating and isolating a desired compound by purification.

The production of the corresponding phthalonitrile will be described below in stages.

—In case where R═H—

The corresponding phthalonitrile is obtained by reacting H—X-A-Ar and potassium carbonate with dichlorophthalonitrile in dimethylacetamide (DMAc).

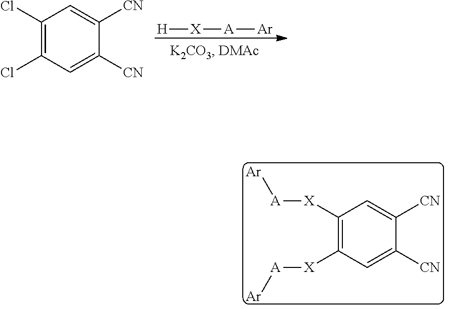

—In Case where R in Formula 1 is Halogen Atom—

The corresponding phthalonitrile is obtained by halogenating the phthalonitrile where R═H (by reacting with N-halogen succinimide or the like).

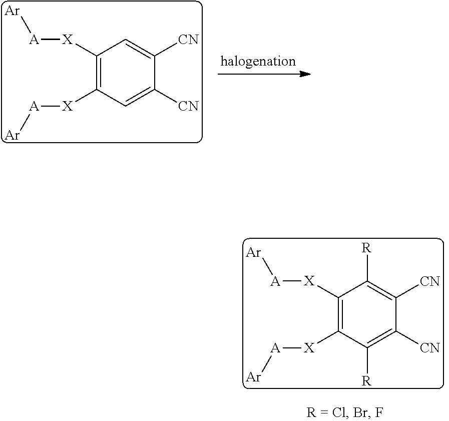

—In Case where R in Formula 1 is Hetero Atom-Linked Substituent—

The corresponding phthalonitrile is obtained by reacting the phthalonitrile where R═Cl obtained by halogenation with a corresponding hetero atom group in dimethylacetamide in the presence of a base such as potassium carbonate.

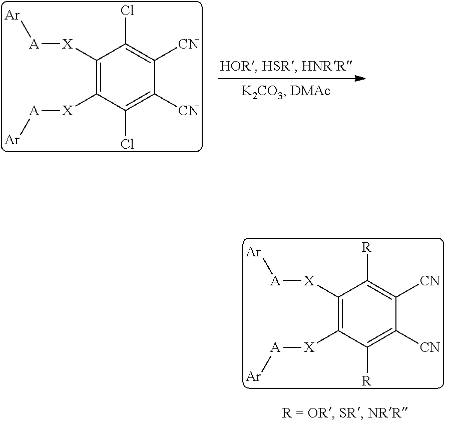

—In Case where R in Formula 1 is Alkyl Group which May have Substituent or Aryl Group which May have Substituent—

The corresponding phthalonitrile can be produced by subjecting the phthalonitrile where R═Br obtained by halogenation to Negishi coupling for an alkyl group or Suzuki coupling for an aryl group.

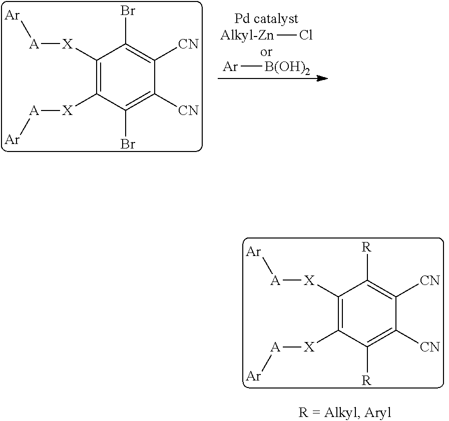

<Polymerizable Compound>

The composition according to the present disclosure contains a polymerizable compound. The polymerizable compound that can be used in the present disclosure is preferably an ethylenically unsaturated compound and more preferably a compound having a terminal ethylenically unsaturated group.

As a group of such a compound, known compounds can be used without any particular limitation.

These compounds have a chemical form such as a monomer, a prepolymer, that is, a dimer, a trimer or an oligomer, or a mixture thereof and a copolymer thereof. Examples of the monomer and the copolymer thereof include unsaturated carboxylic acids (for example, acrylic acid, methacrylic acid, itaconic acid, crotonic acid, isocrotonic acid, and maleic acid), and esters and amides thereof, among which an ester of an unsaturated carboxylic acid with an aliphatic polyhydric alcohol compound, or an amide of an unsaturated carboxylic acid with an aliphatic polyvalent amine compound is preferably used. In addition, a product of an addition reaction of an unsaturated carboxylic acid ester or amide having a nucleophilic substituent such as a hydroxyl group, an amino group, or a mercapto group with a monofunctional or polyfunctional isocyanate or epoxy, and a product of a dehydration condensation reaction of such an unsaturated carboxylic acid ester or amide with a monofunctional or polyfunctional carboxylic acid are also suitably used. In addition, a product of an addition reaction of an unsaturated carboxylic acid ester or amide having an electrophilic substituent such as an isocyanate group or an epoxy group with a monofunctional or polyfunctional alcohol, amine or thiol, and further a product of a substitution reaction of an unsaturated carboxylic acid ester or amide having a leaving substituent such as a halogen group or a tosyloxy group with a monofunctional or polyfunctional alcohol, amine or thiol are also suitable. In addition, as another example, it is also possible to use a group of compounds substituted with unsaturated phosphonic acid, styrene, vinyl ether, or the like in place of the foregoing unsaturated carboxylic acid.

Specific examples of the monomer of an ester of an aliphatic polyhydric alcohol compound with an unsaturated carboxylic acid include acrylic acid esters such as ethylene glycol diacrylate, triethylene glycol diacrylate, 1,3-butanediol diacrylate, tetramethylene glycol diacrylate, propylene glycol diacrylate, neopentyl glycol diacrylate, trimethylolpropane triacrylate, trimethylolpropane tri(acryloyloxypropyl)ether, trimethylolethane triacrylate, hexanediol diacrylate, 1,4-cyclohexanediol diacrylate, tetraethylene glycol diacrylate, pentaerythritol diacrylate, pentaerythritol triacrylate, pentaerythritol tetraacrylate, dipentaerythritol diacrylate, dipentaerythritol hexaacrylate, sorbitol triacrylate, sorbitol tetraacrylate, sorbitol pentaacrylate, sorbitol hexaacrylate, tri(acryloyloxyethyl) isocyanurate, polyester acrylate oligomer, and isocyanuric acid EO-modified triacrylate.

Examples of the methacrylic acid esters include tetramethylene glycol dimethacrylate, triethylene glycol dimethacrylate, neopentyl glycol dimethacrylate, trimethylolpropane trimethacrylate, trimethylolethane trimethacrylate, ethylene glycol dimethacrylate, 1,3-butanediol dimethacrylate, hexanediol dimethacrylate, pentaerythritol dimethacrylate, pentaerythritol trimethacrylate, pentaerythritol tetramethacrylate, dipentaerythritol dimethacrylate, dipentaerythritol hexamethacrylate, sorbitol trimethacrylate, sorbitol tetramethacrylate, bis[p-(3-methacryloxy-2-hydroxypropoxy)phenyl]dimethylmethane, and bis[p-(methacryloxyethoxy)phenyl]dimethylmethane.

In addition, a urethane-based addition polymerizable compound produced by using an addition reaction of an isocyanate group with a hydroxy group is also suitable, and specific examples thereof include a vinyl urethane compound containing two or more polymerizable vinyl groups in one molecule, which is obtained by addition of a vinyl monomer containing a hydroxy group represented by General Formula (I) to a polyisocyanate compound having two or more isocyanate groups in one molecule, which is described in JP1973-041708B (JP-S-48-041708B).

CH₂═C(R)COOCH₂CH(R′)OH (I)

where R and R′ each represent H or CH₃.

In addition, urethane acrylates described in JP1976-037193A (JP-S-51-037193A), JP1990-032293B (JP-H-02-032293B), and JP1990-016765B (JP-H-02-016765B), and urethane compounds having an ethylene oxide-based skeleton described in JP1983-049860B (JP-S-58-049860B), JP1981-017654B (JP-S-56-017654B), JP1987-039417B (JP-S-62-039417B), and JP1987-039418B (JP-S-62-039418B) are also suitable. Further, use of addition polymerizable compounds having an amino structure or a sulfide structure in the molecule, described in JP1989-277653A (JP-S-63-277653A), JP1989-260909A (JP-S-63-260909A), and JP1989-105238A (JP-H-01-105238A), makes it possible to obtain a composition having a very excellent photosensitizing speed.

Other examples of the polymerizable compound include compounds described in paragraphs [0178] to [0190] of JP2007-277514A.

The content of the polymerizable compound in the composition is preferably 1% to 90% by mass, more preferably 5% to 80% by mass, and still more preferably 10% to 70% by mass with respect to the total solid content of the composition. In a case where the content of the polymerizable compound is within the above range, the curing properties of the composition are excellent.

<Chromatic Colorant Different from Specific Compound>

The composition according to the present disclosure preferably contains a chromatic colorant different from the specific compound.

In the present disclosure, the chromatic colorant refers to a colorant other than a white colorant and a black colorant.

By appropriately selecting the chromatic colorant, it is possible to design the wavelength range of light which is absorbed by the composition according to the present disclosure and the cured product of the composition.

For example, by using the composition according to the present disclosure containing a specific compound and a chromatic colorant having a maximum absorption wavelength shorter than that of the specific compound, a cured film that absorbs light having a wavelength near the maximum absorption wavelength of the specific compound according to the present disclosure, and light having a wavelength near the maximum absorption wavelength of the chromatic colorant, which is a wavelength shorter than the wavelength near the maximum absorption wavelength of the specific compound, can be obtained.

That is, the cured film is a cured film that transmits light in a wavelength range other than the light having a wavelength near the maximum absorption wavelength of the specific compound according to the present disclosure, and the light having a wavelength near the maximum absorption wavelength of the chromatic colorant.

Since the specific compound in the present disclosure has excellent spectral characteristics, it can be said that the cured film has excellent spectral characteristics in the wavelength range on the maximum absorption wavelength side of the specific compound, which is included in the wavelength range of the transmitted light.

As an example, a pixel in a color filter that transmits green light having a wavelength of 530 nm to 580 nm can be produced by using a composition according to the present disclosure including a yellow colorant having a maximum absorption wavelength in a wavelength range of 400 nm to 500 nm and a specific compound having a maximum absorption wavelength in a wavelength range of 600 nm or more and less than 700 nm.

It is considered that the pixel has satisfactory sharpness of absorption-edge wavelength by including the specific compound in the composition according to the present disclosure. Therefore, it is considered that the overlap of the transmission wavelength with the pixel that transmits red light (for example, light having a wavelength of 630 nm to 700 nm) (G/R overlap) becomes small.

In addition, since the specific compound has a small absorption wavelength peak width, in a case of being used as a pixel in a color filter, the composition may further include a green colorant in order to broaden the wavelength range of absorption.

As an example, a pixel that transmits green light having a wavelength of 530 nm to 580 nm and absorbs light in a wide wavelength range on a long wavelength side such as 600 nm to 750 nm can be produced by using a composition according to the present disclosure including a specific compound having a maximum absorption wavelength in a wavelength range of 600 nm or more and less than 700 nm, and a green colorant having a maximum absorption wavelength in a wavelength range of 600 nm or more and less than 700 nm and having a maximum absorption wavelength larger than that of the specific compound.

It is considered that the above-mentioned pixel also has satisfactory sharpness of absorption-edge wavelength by including the specific compound in the composition according to the present disclosure. Therefore, it is considered that the overlap of the transmission wavelength with the color filter that transmits red light (for example, light having a wavelength of 630 nm to 700 nm) (G/R overlap) becomes small.

In addition, the composition according to the present disclosure may include all of the specific compound, the yellow colorant described above, and the green colorant described above.

In addition, in a case where the spectral characteristics of a colored pixel are adjusted by using the colorants of two or more colors in combination, two or more layers of films may be laminated to adjust to achieve the desired spectral characteristics. For example, in a case where the spectral characteristics of a green pixel are adjusted by using a specific compound, a yellow colorant, and optionally a green colorant in combination, a film containing a specific compound and a film containing a yellow colorant may be laminated to adjust to achieve the desired spectral characteristics. The green colorant may be included in any of the above films as needed. In addition, the lamination forms described in JP2017-167389A and JP2017-194560A can also be applied to the present disclosure.

Hereinafter, the chromatic colorant will be described with reference to specific examples.

[Yellow Colorant]

The chromatic colorant is preferably a yellow colorant from the viewpoint of forming the pixel that transmits green light.

In addition, the yellow colorant is preferably a yellow pigment from the viewpoint of light resistance and moisture resistance.

In addition, the average particle size of the yellow pigment is preferably 0.01 μm to 0.1 μm and more preferably 0.01 μm to 0.05 μm.

The yellow colorant is not particularly limited as long as it is a colorant exhibiting yellow, but preferably has a maximum absorption wavelength in a wavelength range of 400 nm to 500 nm, more preferably in a wavelength range of 450 nm to 480 nm, and still more preferably in a wavelength range of 450 nm to 460 nm.

The yellow colorant is preferably at least one selected from the group consisting of an azo compound and an isoindoline compound, more preferably an azo compound, and still more preferably an azo compound having a barbituric acid structure.

Specific examples of the yellow colorant include yellow pigments such as Color Index (C.I.) Pigment Yellow (also simply referred to as “PY-”) 1, 2, 3, 4, 5, 6, 10, 11, 12, 13, 14, 15, 16, 17, 18, 20, 24, 31, 32, 34, 35, 35:1, 36, 36:1, 37, 37:1, 40, 42, 43, 53, 55, 60, 61, 62, 63, 65, 73, 74, 77, 81, 83, 86, 93, 94, 95, 97, 98, 100, 101, 104, 106, 108, 109, 110, 113, 114, 115, 116, 117, 118, 119, 120, 123, 125, 126, 127, 128, 129, 137, 138, 139, 147, 148, 150, 151, 152, 153, 154, 155, 156, 161, 162, 164, 166, 167, 168, 169, 170, 171, 172, 173, 174, 175, 176, 177, 179, 180, 181, 182, 185, 187, 188, 193, 194, 199, 213, and 214; and yellow dyes such as C.I. Solvent Yellow 4, 82, 88, 14, 15, 24, 93, 94, 98, and 162.

From the viewpoint of storage stability, the yellow colorant preferably includes at least one selected from the group consisting of PY-139, PY-150 and PY-185, more preferably at least one selected from the group consisting of PY-150 and PY-185, and still more preferably PY-150.

In addition, compounds having structures represented by Formulae (Y1) to (Y4) can also be used as a colorant Y

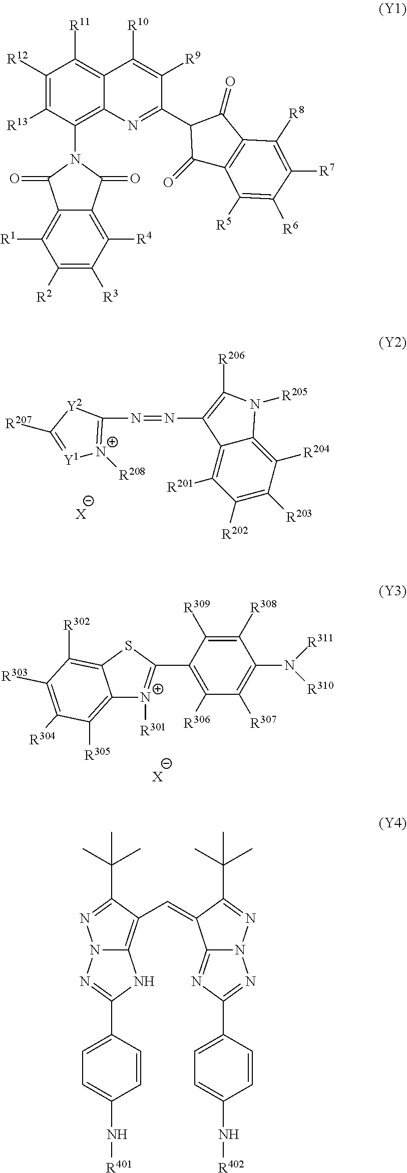

In Formula (Y1), R¹ to R¹³ each independently represent a hydrogen atom or a substituent, and adjacent groups among R¹ to R⁸ may be bonded to each other to form a ring. However, at least one set of two adjacent groups of R¹ to R⁸ is bonded to each other to form an aromatic ring.

In Formula (Y2), R²⁰⁵ and R²⁰⁸ each independently represent a hydrogen atom, an alkyl group, an aryl group, or a heteroaryl group, R²⁰¹ to R²⁰⁴, R²⁰⁶ and R²⁰⁷ each independently represent a hydrogen atom or a substituent, Y¹ represents a nitrogen atom or —CR^{Y1}—, Y2 represents a sulfur atom or —NR^{Y2}—, R^{Y1} and R^{Y2} each independently represent a hydrogen atom, an alkyl group, an aryl group, or a heteroaryl group, and X represents a bis(sulfonyl)imide anion, a tris(sulfonyl)methide anion, or an anion having a boron atom.

In Formula (Y3), R³⁰¹, R³¹¹, and R³¹⁰ each independently represent a hydrogen atom, an alkyl group, an aryl group, or a heteroaryl group, R³⁰² to R³⁰⁵ and R³⁰⁶ to R³⁰⁹ each independently represent a hydrogen atom or a substituent, and X represents a bis(sulfonyl)imide anion, a tris(sulfonyl)methide anion, or an anion having a boron atom.

In Formula (Y4), R⁴⁰¹ and R⁴⁰² each independently represent SO₂R⁴⁰³ or COR⁴⁰³; and R⁴⁰³ represents an alkyl group, an aryl group, or a heteroaryl group.

For details of Formulae (Y1) to (Y4), reference can be made to the description of paragraphs [0016] to [0046] of WO2017/082226A, the contents of which are incorporated in the present disclosure by reference.

In addition, quinophthalone compounds described in paragraphs [0011] to [0034] of JP2013-054339A, quinophthalone compounds described in paragraphs [0013] to [0058] of JP2014-026228A, and the like can also be used as the yellow colorant.

The composition may include only one type of yellow colorant or may include two or more types of yellow colorants.

The content of the yellow colorant is preferably 1% by mass to 30% by mass, more preferably 2% by mass to 25% by mass, and still more preferably 5% by mass to 20% by mass with respect to the total mass of the composition.

It is preferable that 50% by mass or more of the yellow colorant contained in the composition is at least one selected from an azo compound or an isoindoline compound (preferably an azo compound and more preferably an azo compound having a barbituric acid structure), more preferably 70% by mass or more, and still more preferably 90% by mass or more.

In addition, it is preferable for the composition that 50% by mass or more of the yellow colorant contained in the composition is at least one selected from the group consisting of PY-139, PY-150 and PY-185 (more preferably PY-150), more preferably 70% by mass or more, and still more preferably 90% by mass or more.

[Green Colorant]

It is preferable that the chromatic colorant includes a green colorant from the viewpoint of forming the pixel that transmits green light.

In addition, the green colorant is preferably a green pigment from the viewpoint of light resistance and moisture resistance.

In addition, the average particle size of the green pigment is preferably 0.01 μm to 0.1 μm and more preferably 0.01 μm to 0.05 μm.

The green colorant is not particularly limited as long as it is a colorant exhibiting a green color, but preferably has a maximum absorption wavelength in a range of 600 nm to 700 nm, more preferably in a range of 620 nm to 695 nm, and still more preferably in a range of 640 nm to 690 nm.

Examples of the green colorant include green pigments such as C.I. Pigment Green 7, 10, 36, 37, 58, and 59.

In addition, a halogenated zinc phthalocyanine pigment having an average number of halogen atoms of 10 to 14, an average number of bromine atoms of 8 to 12, and an average number of chlorine atoms of 2 to 5 in the molecule can also be used as the green colorant. Specific examples of the green colorant include compounds described in WO2015/118720A.

The composition may include only one type of green colorant or may include two or more types of green colorants.

The content of the green colorant is preferably 1% by mass to 30% by mass, more preferably 2% by mass to 20% by mass, and still more preferably 5% by mass to 15% by mass with respect to the total mass of the composition.

<Pigment Derivative>

The composition can contain a pigment derivative. Examples of the pigment derivative include a compound having a structure in which a part of a chromophore group is substituted with an acid group, a basic group, or a phthalimidomethyl group (for example, a derivative of the above-mentioned chromatic colorant). Examples of the chromophore group constituting the pigment derivative include a quinoline-based skeleton, a benzimidazolone-based skeleton, a diketopyrrolopyrrole-based skeleton, an azo-based skeleton, a phthalocyanine-based skeleton, an anthraquinone-based skeleton, a quinacridone-based skeleton, a dioxazine-based skeleton, a perinone-based skeleton, a perylene-based skeleton, a thioindigo-based skeleton, an isoindoline-based skeleton, an isoindolinone-based skeleton, a quinophthalone-based skeleton, a threne-based skeleton, and a metal complex-based skeleton, among which a quinoline-based skeleton, a benzimidazolone-based skeleton, a diketopyrrolopyrrole-based skeleton, an azo-based skeleton, a quinophthalone-based skeleton, an isoindoline-based skeleton, and a phthalocyanine-based skeleton are preferable, and an azo-based skeleton and a benzimidazolone-based skeleton are more preferable. The acid group contained in the pigment derivative is preferably a sulfo group or a carboxyl group and more preferably a sulfo group. The basic group contained in the pigment derivative is preferably an amino group and more preferably a tertiary amino group. With regard to specific examples of the pigment derivative, reference can be made to, for example, the description of paragraphs [0162] to [0183] of JP2011-252065A, the contents of which are incorporated herein by reference.

In a case where the composition contains a pigment derivative, the content of the pigment derivative is preferably 1 to 30 parts by mass and more preferably 3 to 20 parts by mass with respect to 100 parts by mass of the pigment. The pigment derivatives may be used alone or in combination of two or more thereof.

<Other Components>

The composition according to the present disclosure is a composition that can be finally cured to obtain a cured film.

In addition, the composition according to the present disclosure is preferably a composition that is capable forming a pattern of a cured film by pattern-wise exposure, for example, that is, a negative composition.

In a case where the composition according to the present disclosure is a negative composition, for example, an aspect including a polymerization initiator, a polymerizable compound, and an alkali-soluble resin is preferable.

Hereinafter, individual components included in the aspect in which the composition according to the present disclosure is a negative composition will be described.

The individual components included in the aspect in which the composition according to the present disclosure is a positive composition include the individual components described in WO2014/003111A, and preferred aspects thereof are also the same.

<Polymerization Initiator>

The composition according to the present disclosure preferably further includes a polymerization initiator, and more preferably further includes a photopolymerization initiator.

In addition, it is preferable that the composition according to the present disclosure further includes a polymerization initiator, and the polymerizable compound is an ethylenically unsaturated compound.

The photopolymerization initiator is not particularly limited as long as it has an ability to initiate polymerization of a polymerizable compound, and can be appropriately selected from known photopolymerization initiators. For example, a compound having photosensitivity to light in the ultraviolet region to the visible region is preferable. In addition, the photopolymerization initiator may be a compound that generates an active radical by causing some action with a photoexcited sensitizer. The photopolymerization initiator is preferably a photo-radical polymerization initiator.

Examples of the photopolymerization initiator include a halogenated hydrocarbon derivative (for example, a compound having a triazine skeleton or a compound having an oxadiazole skeleton), an acylphosphine compound, a hexaarylbiimidazole, an oxime compound, an organic peroxide, a thio compound, a ketone compound, an aromatic onium salt, an α-hydroxy ketone compound, and an α-amino ketone compound. From the viewpoint of exposure sensitivity, the photopolymerization initiator is preferably a trihalomethyltriazine compound, a benzyldimethylketal compound, an α-hydroxyketone compound, an α-aminoketone compound, an acylphosphine compound, a phosphine oxide compound, a metallocene compound, an oxime compound, a triarylimidazole dimer, an onium compound, a benzothiazole compound, a benzophenone compound, an acetophenone compound, a cyclopentadiene-benzene-iron complex, a halomethyloxadiazole compound, or a 3-aryl-substituted coumarin compound; more preferably a compound selected from an oxime compound, an α-hydroxyketone compound, an α-aminoketone compound, and an acylphosphine compound; and still more preferably an oxime compound. Regarding the photopolymerization initiator, reference can be made to the description of paragraphs [0065] to [0111] of JP2014-130173A and paragraphs [0274] to [0306] of JP2013-029760A, the contents of which are incorporated in the present disclosure by reference.

Examples of commercially available α-hydroxyketone compounds include IRGACURE-184, DAROCUR-1173, IRGACURE-500, IRGACURE-2959, and IRGACURE-127 (all of which are manufactured by BASF SE). Examples of commercially available α-aminoketone compounds include IRGACURE-907, IRGACURE-369, IRGACURE-379, and IRGACURE-379EG (all of which are manufactured by BASF SE). Examples of commercially available acylphosphine compounds include IRGACURE-819 and DAROCUR-TPO (both of which are manufactured by BASF SE).

Examples of the oxime compound include compounds described in JP2001-233842A, compounds described in JP2000-080068A, compounds described in JP2006-342166A, compounds described in J. C. S. Perkin II (1979, pp. 1653 to 1660), compounds described in J. C. S. Perkin II (1979, pp. 156 to 162), compounds described in Journal of Photopolymer Science and Technology (1995, pp. 202 to 232), compounds described in JP2000-066385A, compounds described in JP2000-080068A, compounds described in JP2004-534797A, compounds described in JP2006-342166A, compounds described in JP2017-019766A, compounds described in JP6065596B, compounds described in WO2015/152153A, and compounds described in WO2017/051680A. Specific examples of the oxime compound include 3-benzoyloxyiminobutan-2-one, 3-acetoxyiminobutan-2-one, 3-propionyloxyiminobutan-2-one, 2-acetoxyiminopentan-3-one, 2-acetoxyimino-1-phenylpropan-1-one, 2-benzoyloxyimino-1-phenylpropan-1-one, 3-(4-toluenesulfonyloxy)iminobutan-2-one, and 2-ethoxycarbonyloxyimino-1-phenylpropan-1-one. As commercially available oxime compounds, IRGACURE-OXE01, IRGACURE-OXE02, IRGACURE-OXE03, and IRGACURE-OXE04 (all of which are manufactured by BASF SE) are also suitably used. In addition, TRONLY TR-PBG-304, TRONLY TR-PBG-309, and TRONLY TR-PBG-305 (all of which are manufactured by CHANGZHOU TRONLY NEW ELECTRONIC MATERIALS CO., LTD), and ADEKA ARKLS NCI-930 and ADEKA OPTOMER N-1919 (photopolymerization initiator 2 of JP2012-014052A) (both of which are manufactured by ADEKA Corporation) can be mentioned as commercially available oxime compounds.

In addition, as the oxime compound other than the above-mentioned compounds, compounds described in JP2009-519904A in which an oxime is linked to an N-position of a carbazole ring; compounds described in U.S. Pat. No. 7,626,957B in which a hetero substituent is introduced into a benzophenone moiety; compounds described in JP2010-015025A and US2009-292039A in which a nitro group is introduced into a coloring agent moiety; ketoxime compounds described in WO2009/131189A; compounds described in U.S. Pat. No. 7,556,910B, which contain a triazine skeleton and an oxime skeleton in the same molecule; and compounds described in JP2009-221114A, which have a maximum absorption wavelength of 405 nm and satisfactory sensitivity to a g-ray light source, may be used.

In the present disclosure, an oxime compound having a fluorene ring can also be used as the photopolymerization initiator. Specific examples of the oxime compound having a fluorene ring include compounds described in JP2014-137466A, the contents of which are incorporated in the present disclosure by reference.

In the present disclosure, an oxime compound having a benzofuran skeleton can also be used as the photopolymerization initiator. Specific examples thereof include compounds OE-01 to OE-75 described in WO2015/036910A.

In the present disclosure, an oxime compound having a skeleton in which at least one benzene ring of a carbazole ring became a naphthalene ring can also be used as the photopolymerization initiator. Specific examples of such an oxime compound include compounds described in WO2013/083505A.

In the present disclosure, an oxime compound having a fluorine atom can also be used as the photopolymerization initiator. Specific examples of the oxime compound having a fluorine atom include compounds described in JP2010-262028A, Compounds 24 and 36 to 40 described in JP2014-500852A, and Compound (C-3) described in JP2013-164471A, the contents of which are incorporated in the present disclosure by reference.

In the present disclosure, an oxime compound having a nitro group can be used as the photopolymerization initiator. The oxime compound having a nitro group is also preferably a dimer. Specific examples of the oxime compound having a nitro group include compounds described in paragraphs [0031] to [0047] of JP2013-114249A, and paragraphs [0008] to [0012] and [0070] to [0079] of JP2014-137466A, compounds described in paragraphs [0007] to [0025] of JP4223071B, and ADEKA ARKLS NCI-831 (manufactured by ADEKA Corporation).

Specific examples of the oxime compound preferably used in the present disclosure are shown below, but the present disclosure is not limited thereto.

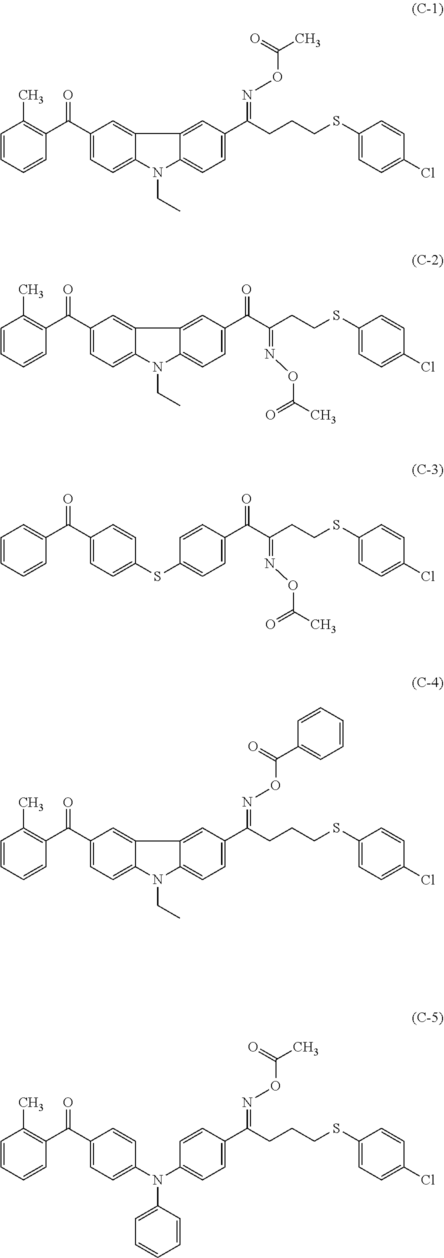 [SMILES: CCn1c2ccc(C(=O)c3ccccc3C)cc2c2cc(/C(CCCSc3ccc(Cl)cc3)=N/OC(C)=O)ccc21 ; CCn1c2ccc(C(=O)/C(CCSc3ccc(Cl)cc3)=N/OC(C)=O)cc2c2cc(C(=O)c3ccccc3C)ccc21 ; CC(=O)O/N=C(\CCSc1ccc(Cl)cc1)C(=O)c1ccc(Sc2ccc(C(=O)c3ccccc3)cc2)cc1 ; CCn1c2ccc(C(=O)c3ccccc3C)cc2c2cc(/C(CCCSc3ccc(Cl)cc3)=N/OC(=O)c3ccccc3)ccc21 ; CC(=O)O/N=C(\CCCSc1ccc(Cl)cc1)c1ccc(N(c2ccccc2)c2ccc(C(=O)c3ccccc3C)cc2)cc1]

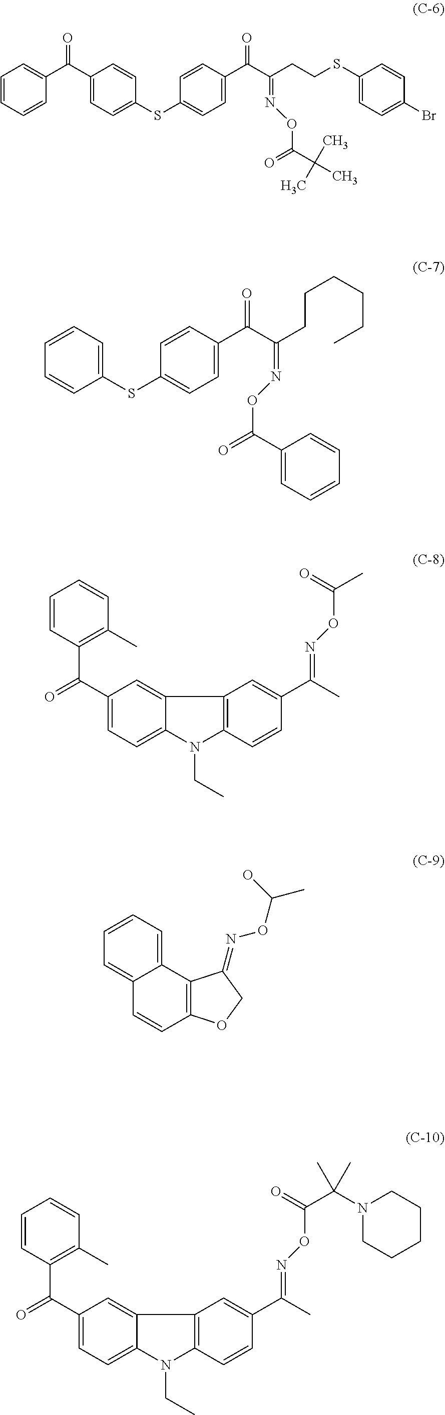 [SMILES: CC(C)(C)C(=O)O/N=C(\CCSc1ccc(Br)cc1)C(=O)c1ccc(Sc2ccc(C(=O)c3ccccc3)cc2)cc1 ; CCCCCC/C(=N/OC(=O)c1ccccc1)C(=O)c1ccc(Sc2ccccc2)cc1 ; CCn1c2ccc(C(=O)c3ccccc3C)cc2c2cc(/C(C)=N/OC(C)=O)ccc21 ; CC(O)O/N=C1\COc2ccc3ccccc3c21 ; CCn1c2ccc(C(=O)c3ccccc3C)cc2c2cc(/C(C)=N/OC(=O)C(C)(C)N3CCCCC3)ccc21]

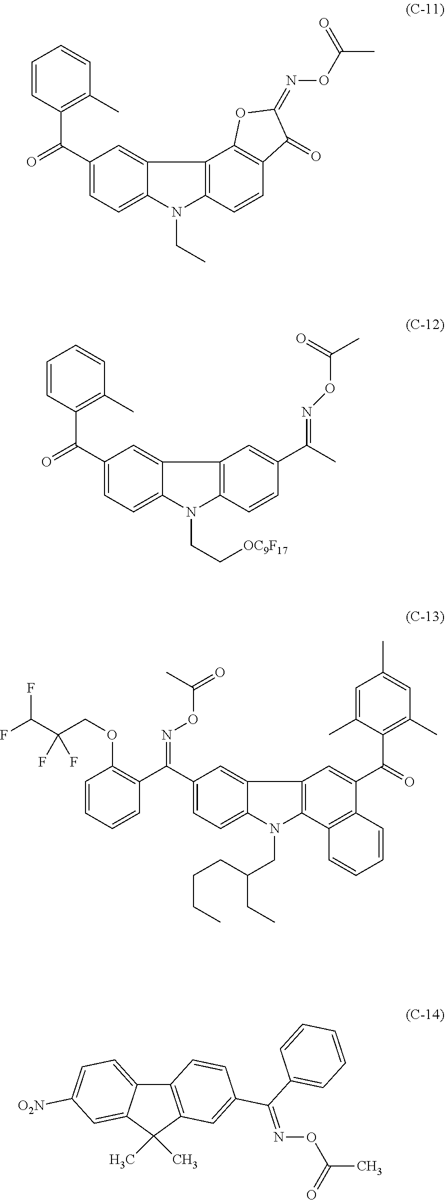

The oxime compound is preferably a compound having a maximum absorption wavelength in a wavelength range of 350 nm to 500 nm, and more preferably a compound having a maximum absorption wavelength in a wavelength range of 360 nm to 480 nm. In addition, the oxime compound is preferably a compound having high absorbance at wavelengths of 365 nm and 405 nm.

The molar light absorption coefficient at a wavelength of 365 nm or 405 nm of the oxime compound is preferably 1,000 to 300,000, more preferably 2,000 to 300,000, and particularly preferably 5,000 to 200,000 from the viewpoint of sensitivity. The molar light absorption coefficient of the compound can be measured using a known method. For example, it is preferable to measure the molar light absorption coefficient of the compound with an ultraviolet-visible spectrophotometer (Cary-5 spectrophotometer manufactured by Varian Medical Systems, Inc.) using an ethyl acetate solvent at a concentration of 0.01 g/L.

In the present disclosure, a difunctional or tri- or higher functional photopolymerization initiator may be used as the photopolymerization initiator. Specific examples of such a photopolymerization initiator include dimers of oxime compounds described in JP2010-527339A, JP2011-524436A, WO2015/004565A, paragraphs [0417] to [0412] of JP2016-532675A, and paragraphs [0039] to [0055] of WO2017/033680A, Compound (E) and Compound (G) described in JP2013-522445A, and Cmpd 1 to 7 described in WO2016/034963A.

The polymerization initiators may be used alone or in combination of two or more thereof.

The content of the polymerization initiator in the composition is preferably 0.1% to 50% by mass, more preferably 0.5% to 30% by mass, and particularly preferably 1% to 20% by mass, with respect to the total solid content of the composition. Within this range, satisfactory sensitivity and pattern formability can be obtained.

<Alkali-Soluble Resin>

The composition according to the present disclosure preferably contains at least one alkali-soluble resin.

The alkali-soluble resin is a high molecular weight polymer, and can be appropriately selected from alkali-soluble resins having at least one group (for example, a carboxy group, a phosphoric acid group, or a sulfonic acid group) that promotes alkali solubility in a molecule (preferably a molecule having an acrylic-based copolymer or a styrene-based copolymer as a main chain). Of these, more preferred is an alkali-soluble resin which is soluble in an organic solvent and can be developed with a weak alkaline aqueous solution.

For example, a known radical polymerization method can be applied to the production of the alkali-soluble resin. Polymerization conditions such as temperature, pressure, type and amount of radical initiator, and type of solvent in a case of producing an alkali-soluble resin by a radical polymerization method can be easily set by those skilled in the art, and the polymerization conditions can also be determined experimentally.

The high molecular weight polymer is preferably a polymer having a carboxylic acid in a side chain thereof. Examples of such a high molecular weight polymer include polymers having a carboxylic acid in a side chain thereof, such as methacrylic acid copolymers, acrylic acid copolymers, itaconic acid copolymers, crotonic acid copolymers, maleic acid copolymers, and partially esterified maleic acid copolymers, such as those described in, for example, JP1984-044615A (JP-S-59-044615A), JP1979-034327B (JP-S-54-034327B), JP1983-012577B (JP-S-58-012577B), JP1979-025957B (JP-S-54-025957B), JP1984-053836A (JP-59-053836A), and JP1984-071048A (JP-S-59-071048A); acidic cellulose derivatives having a carboxylic acid in a side chain thereof, and polymers obtained by adding an acid anhydride to a polymer having a hydroxyl group. Further, high molecular weight polymers having a (meth)acryloyl group in a side chain thereof are also preferred.

Specifically, a copolymer of (meth)acrylic acid and other monomers copolymerizable therewith is particularly suitable as the alkali-soluble resin.

Examples of other monomers copolymerizable with (meth)acrylic acid include (meth)acrylic acid esters, crotonic acid esters, vinyl esters, maleic acid diesters, fumaric acid diesters, itaconic acid diesters, (meth)acrylamides, styrenes, vinyl ethers, vinyl ketones, olefins, maleimides, and (meth)acrylonitriles.

Examples of (meth)acrylic acid esters include methyl (meth)acrylate, ethyl (meth)acrylate, n-propyl (meth)acrylate, isopropyl (meth)acrylate, n-butyl (meth)acrylate, isobutyl (meth)acrylate, t-butyl (meth)acrylate, amyl (meth)acrylate, n-hexyl (meth)acrylate, cyclohexyl (meth)acrylate, t-butyl cyclohexyl (meth)acrylate, 2-ethylhexyl (meth)acrylate, t-octyl (meth)acrylate, dodecy (meth)acrylate, octadecyl (meth)acrylate, acetoxyethyl (meth)acrylate, phenyl (meth)acrylate, 2-hydroxy ethyl (meth)acrylate, 2-hydroxypropyl (meth)acrylate, 3-hydroxypropyl (meth)acrylate, 4-hydroxybutyl (meth)acrylate, 2-methoxyethyl (meth)acrylate, 2-ethoxyethyl (meth)acrylate, 2-(2-methoxyethoxy)ethyl (meth)acrylate, 3-phenoxy-2-hydroxypropyl (meth)acrylate, 2-chloroethyl (meth)acrylate, glycidyl (meth)acrylate, 3,4-epoxycyclohexylmethyl (meth)acrylate, vinyl (meth)acrylate, 2-phenylvinyl (meth)acrylate, 1-propenyl (meth)acrylate, allyl (meth)acrylate, 2-aryloxyethyl (meth)acrylate, propargyl (meth)acrylate, benzyl (meth)acrylate, diethylene glycol monomethyl ether (meth)acrylate, diethylene glycol monoethyl ether (meth)acrylate, triethylene glycol monomethyl ether (meth)acrylate, triethylene glycol monoethyl ether (meth)acrylate, polyethylene glycol monomethyl ether (meth)acrylate, polyethylene glycol monoethyl ether (meth)acrylate, β-phenoxyethoxyethyl (meth)acrylate, nonylphenoxy polyethylene glycol (meth)acrylate, dicyclopentenyl (meth)acrylate, dicyclopentenyloxyethyl (meth)acrylate, trifluoroethyl (meth)acrylate, octafluoropentyl (meth)acrylate, perfluorooctylethyl (meth)acrylate, dicyclopentanyl (meth)acrylate, tribromophenyl (meth)acrylate, tribromophenyloxyethyl (meth)acrylate, and γ-butyrolactone (meth)acrylate.

The weight-average molecular weight of the alkali-soluble resin that can be used in the present disclosure is preferably 5,000 or more and more preferably 10,000 to 300,000, and the number-average molecular weight of the alkali-soluble resin that can be used in the present disclosure is preferably 1,000 or more and more preferably 2,000 to 250,000. The polydispersity (weight-average molecular weight/number-average molecular weight) is preferably in a range of 1.1 to 10 and more preferably in a range of 1.2 to 5.

The alkali-soluble resin may be any of a random polymer, a block polymer, a graft polymer, or the like.

Other examples of the alkali-soluble resin include compounds described in paragraphs [0162] to [0175] of JP2007-277514A.

In addition, at least one selected from the group consisting of the first polymer compound and the second polymer compound according to the present disclosure can also be used as the alkali-soluble resin.

The content of the alkali-soluble resin in the composition is preferably 1% by mass to 20% by mass, more preferably 2% by mass to 15% by mass, and particularly preferably 3% by mass to 12% by mass with respect to the total solid content of the composition.

<Dispersant>

The composition according to the present disclosure may contain a compound represented by Formula 1, and a dispersant for dispersing a pigment such as a yellow pigment or a green pigment, which is added as necessary.

The dispersant is not particularly limited, and a known dispersant can be used as the dispersant for a pigment.

Examples of the dispersant include a polymer dispersant [for example, a polyamidoamine and a salt thereof, a polycarboxylic acid and a salt thereof, a high-molecular weight unsaturated acid ester, a modified polyurethane, a modified polyester, a modified poly(meth)acrylate, a (meth)acrylic copolymer, and a naphthalene sulfonic acid/formalin condensate], a polyoxyethylene alkyl phosphoric acid ester, a polyoxyethylene alkylamine, and an alkanolamine.

The polymer dispersants can be further classified into a linear polymer, a terminal-modified polymer, a graft type polymer, and a block type polymer, depending on its structure. The polymer dispersant is adsorbed on a surface of a pigment and therefore acts to prevent re-aggregation of the pigment. For this reason, examples of a preferred structure thereof include a terminal-modified polymer, a graft type polymer, and a block type polymer, which have an anchoring site for the surface of a pigment. Incidentally, also preferably used are the dispersants described in paragraphs [0028] to [0124] of JP2011-070156A, the contents of which are incorporated herein by reference and the dispersants described in JP2007-277514A, the contents of which are incorporated herein by reference, the contents of which are incorporated in the present disclosure by reference.

The polymer dispersant preferably contains a repeating unit having an acid group. In a case where the resin used as the dispersant contains a repeating unit having an acid group, residues generated on the base of the pixel can be further reduced in a case where patterning is carried out by a photolithography method.

It is also preferable that the polymer dispersant is a graft copolymer. The graft copolymer has an affinity for a solvent due to a graft chain, which thus results in excellent pigment dispersibility and excellent storage stability over time. For details of the graft copolymer, reference can be made to the description in paragraphs [0025] to [0094] of JP2012-255128A, the contents of which are incorporated herein by reference. In addition, specific examples of the graft copolymer include, but are not limited to, P-2 in the Examples which will be described later. The following resins are also resins having an acid group (alkali-soluble resins). In addition, examples of the graft copolymer include the resins described in paragraphs [0072] to [0094] of JP2012-255128A, the contents of which are incorporated herein by reference.

In addition, a polymer dispersant having an ethylenically unsaturated group may be used as the polymer dispersant. Examples of the ethylenically unsaturated group include a vinyl group, a vinyloxy group, an allyl group, a methallyl group, a (meth)acryloyl group, a vinylphenyl group, a cinnamoyl group, and a maleimide group, among which a (meth)acryloyl group, a vinylphenyl group, or a maleimide group is preferable, a (meth)acryloyl group is more preferable, and an acryloyl group is particularly preferable, from the viewpoint of reactivity.

Examples of the polymer dispersant having an ethylenically unsaturated group include, but are not limited to, P-1, P-3, and P-4 in the Examples which will be described later.

A commercially available product can also be used as the dispersant. For example, a product described in paragraph [0129] of JP2012-137564A can be used as the dispersant. For example, Disperbyk-111 (manufactured by BYK-Chemie GmbH) can be mentioned as the commercially available dispersant product. In addition, the resin described as the dispersant can also be used for purposes other than the dispersant. For example, such a resin can also be used as a binder.

In the present disclosure, the dispersants may be used alone or in combination of two or more thereof.

The content of the dispersant may be appropriately adjusted according to the pigment used, but is preferably 1 part by mass to 200 parts by mass with respect to 100 parts by mass of the total content of the compound represented by Formula 1 and the pigment. The lower limit of the content of the dispersant is preferably 5 parts by mass or more and more preferably 10 parts by mass or more. The upper limit of the content of the dispersant is preferably 150 parts by mass or less and more preferably 100 parts by mass or less.

<Polymerization Inhibitor>

The composition according to the present disclosure preferably contains a polymerization inhibitor from the viewpoint of storage stability.

The polymerization inhibitor is not particularly limited, and a known polymerization inhibitor can be used.

Examples of the polymerization inhibitor include hydroquinone, p-methoxyphenol, di-t-butyl-p-cresol, pyrogallol, t-butylcatechol, benzoquinone, 4,4′-thiobis(3-methyl-6-t-butylphenol), 2,2′-methylenebis(4-methyl-6-t-butylphenol), an N-nitrosophenylhydroxyamine salt (an ammonium salt, a cerous salt, or the like), and 2,2,6,6-tetramethylpiperidine-1-oxyl.

Incidentally, the polymerization inhibitor may also function as an antioxidant.

The polymerization inhibitors may be used alone or in combination of two or more thereof.

The content of the polymerization inhibitor is preferably 0.1 ppm to 1,000 ppm, more preferably 1 ppm to 500 ppm, and particularly preferably 1 ppm to 100 ppm with respect to the total solid content of the composition, from the viewpoint of storage stability.

<Solvent>

The composition according to the present disclosure may contain a solvent.

Examples of the solvent include esters such as ethyl acetate, n-butyl acetate, isobutyl acetate, amyl formate, isoamyl acetate, isobutyl acetate, butyl propionate, isopropyl butyrate, ethyl butyrate, butyl butyrate, alkyl esters, methyl lactate, ethyl lactate, alkyl oxyacetates (such as methyl oxyacetates, ethyl oxyacetates, and butyl oxyacetates (for example, methyl methoxyacetate, ethyl methoxyacetate, butyl methoxyacetate, methyl ethoxyacetate, and ethyl ethoxyacetate), alkyl 3-oxypropionates (such as methyl 3-oxypropionates and ethyl 3-oxypropionates (for example, methyl 3-methoxypropionate, ethyl 3-methoxypropionate, methyl 3-ethoxypropionate, and ethyl 3-ethoxypropionate), alkyl 2-oxypropionates (such as methyl 2-oxypropionates, ethyl 2-oxypropionates, and propyl 2-oxypropionates (for example, methyl 2-methoxypropionate, ethyl 2-methoxypropionate, propyl 2-methoxypropionate, methyl 2-ethoxypropionate, ethyl 2-ethoxypropionate, methyl 2-oxy-2-methylpropionate, ethyl 2-oxy-2-methylpropionate, methyl 2-methoxy-2-methylpropionate, and ethyl 2-ethoxy-2-methylpropionate), methyl pyruvate, ethyl pyruvate, propyl pyruvate, methyl acetoacetate, ethyl acetoacetate, methyl 2-oxobutanoate, and ethyl 2-oxobutanoate;

ethers such as diethylene glycol dimethyl ether, tetrahydrofuran, ethylene glycol monomethyl ether, ethylene glycol monoethyl ether, methyl cellosolve acetate, ethyl cellosolve acetate, diethylene glycol monomethyl ether, diethylene glycol monoethyl ether, diethylene glycol monobutyl ether, propylene glycol monomethyl ether, propylene glycol methyl ether acetate, propylene glycol ethyl ether acetate, and propylene glycol propyl ether acetate;

ketones such as methyl ethyl ketone, cyclohexanone, 2-heptanone, and 3-heptanone; and

aromatic hydrocarbons such as toluene and xylene.

Among these, methyl 3-ethoxypropionate, ethyl 3-ethoxypropionate, ethyl cellosolve acetate, ethyl lactate, diethylene glycol dimethyl ether, butyl acetate, methyl 3-methoxypropionate, 2-heptanone, cyclohexanone, ethyl carbitol acetate, butyl carbitol acetate, propylene glycol methyl ether acetate, and the like are suitable.

The solvents may be used alone or in combination of two or more thereof.

<Sensitizer>

The composition according to the present disclosure may contain a sensitizer for the purpose of improving the radical generation efficiency of the radical initiator and widening the photosensitive wavelength. The sensitizer that can be used in the present disclosure is preferably a sensitizer that sensitizes the above-mentioned photopolymerization initiator by an electron transfer mechanism or an energy transfer mechanism.

The sensitizer that can be used in the present disclosure includes those belonging to the compounds listed below and having an absorption wavelength in a wavelength range of 300 nm to 450 nm.

Preferred examples of the sensitizer include those belonging to the following compounds and having an absorption wavelength in a wavelength range of 330 nm to 450 nm.

Examples of the sensitizer include polynuclear aromatics (for example, phenanthrene, anthracene, pyrene, perylene, triphenylene, and 9,10-dialkoxyanthracene), xanthenes (for example, fluorescein, eosin, erythrosine, rhodamine B, and rose bengal), thioxanthones (isopropyl thioxanthone, diethyl thioxanthone, and chlorothioxanthone), cyanines (for example, thiacarbocyanine and oxacarbocyanine), merocyanines (for example, merocyanine and carbomerocyanine), phthalocyanines, thiazines (for example, thionine, methylene blue, and toluidine blue), acridines (for example, acridine orange, chloroflavin, and acriflavine), anthraquinones (for example, anthraquinone), squaliums (for example, squalium), acridine orange, coumarins (for example, 7-diethylamino-4-methylcoumarin), ketocoumarins, phenothiazines, phenazines, styrylbenzenes, azo compounds, diphenylmethane, triphenylmethane, distyrylbenzenes, carbazoles, porphyrins, spiro compounds, quinacridones, indigo, styryl, pyrylium compounds, pyrromethene compounds, pyrazolotriazole compounds, benzothiazole compounds, barbituric acid derivatives, thiobarbituric acid derivatives, aromatic ketone compounds such as acetophenone, benzophenone, thioxanthone, and Michler's ketone, and heterocyclic compounds such as N-aryloxazolidinone. Further, other examples of the sensitizer include the compounds described in EP568993B, U.S. Pat. Nos. 4,508,811A, 5,227,227A, JP2001-125255A, JP1999-271969A (JP-H-11-271969A), and the like.

The sensitizers may be used alone or in combination of two or more thereof.

From the viewpoint of light absorption efficiency in a deep portion and initiation decomposition efficiency, the content of the sensitizer in the composition according to the present disclosure is preferably 0.1% by mass to 20% by mass and more preferably 0.5% by mass to 15% by mass with respect to the total solid content of the composition.

<Co-Sensitizer>

The composition according to the present disclosure may contain a co-sensitizer. The co-sensitizer has a function such as further improving the sensitivity of a sensitizing dye and an initiator to actinic radiation, or preventing the inhibition of polymerization of a polymerizable compound due to oxygen.

In addition, examples of the co-sensitizer include the compounds described in paragraphs [0233] to [0241] of JP2007-277514A.

From the viewpoint of improving the curing rate by balancing polymerization growth rate and chain transfer, the content of the co-sensitizer is preferably in a range of 0.1% by mass to 30% by mass, more preferably in a range of 1% by mass to 25% by mass, and still more preferably in a range of 0.5% by mass to 20% by mass with respect to the mass of the total solid content of the composition.

<Other Components>

The composition according to the present disclosure may contain, as necessary, various additives such as a fluorine-based organic compound, a thermal polymerization inhibitor, a photopolymerization initiator, other fillers, a polymer compound other than an alkali-soluble resin and a dispersant, a surfactant, an adhesion promoter, an antioxidant, an ultraviolet absorber, and an aggregation inhibitor.

Examples of other components include the compounds described in paragraphs [0238] to [0249] of JP2007-277514A.

<Preparation of Composition>

The method for preparing the composition according to the present disclosure is not particularly limited, and the composition can be obtained by mixing individual components contained in the composition by a known method.

In addition, in order to improve the dispersibility of the specific compound and the chromatic colorant, the composition according to the present disclosure may be prepared in such a manner that the specific compound and the dispersant are mixed to prepare a dispersion liquid of the specific compound, the chromatic colorant and the dispersant are mixed to prepare a dispersion liquid of the specific compound, and then these dispersion liquids and other components are further mixed.

In addition, filtration may be carried out through a filter in order to remove a foreign material or reduce defects. Any filter can be used without particular limitation as long as it has been conventionally used for filtration or the like.

(Cured Product)

The cured product according to the present disclosure is a cured product obtained by curing the composition according to the present disclosure.

The curing method is not particularly limited, and examples thereof include curing by exposure to actinic rays such as ultraviolet light and curing by heating.

The cured product according to the present disclosure is preferably in the form of a thin film, for example.

The cured product according to the present disclosure is suitably used as a color filter, an infrared absorption filter, a black matrix provided between pixels of the color filter, a refractive index adjusting film, or the like, and is particularly suitably used as the color filter.

(Color Filter and Production Method Thereof)

The color filter according to the present disclosure comprises the cured product according to the present disclosure.

The color filter according to the present disclosure preferably comprises the cured product according to the present disclosure on a support.

In the color filter, the cured product according to the present disclosure is preferably a pixel of the color filter and more preferably a green pixel of the color filter.

In addition, the cured product according to the present disclosure and another colored film (for example, a colored film containing the above-mentioned yellow colorant) may be overlapped to form one color filter pixel.

Hereinafter, the color filter according to the present disclosure will be described in detail through the production method thereof.

(First Aspect of Method for Producing Color Filter)

A first aspect of the method for producing a color filter according to the present disclosure includes a step of applying the composition according to the present disclosure onto a support to form a composition film (composition film forming step), a step of exposing the formed composition film to light in a pattern-wise manner (hereinafter, abbreviated as “exposing step” where appropriate), and a step of developing the composition film after exposure to form a colored pattern (hereinafter, abbreviated as “developing step” where appropriate).

Hereinafter, individual steps will be described.

<Composition Film Forming Step>

In the composition film forming step, the composition according to the present disclosure is applied onto a support to form a composition film.

Examples of the support which can be used in the present step include a soda glass, a Pyrex (registered trademark) glass, a quartz glass, and those glasses with a transparent conductive film attached thereto which are used in a liquid crystal display element or the like, a photoelectric conversion element substrate used in an imaging element or the like, for example, a silicon substrate, and a complementary metal oxide film semiconductor (CMOS). On these substrates, a black stripe, which isolates individual pixels, is formed in some cases.

In addition, on these substrates, as necessary, an undercoat layer (another layer) may be provided for improving adhesion with an upper layer, preventing diffusion of a substance, or flattening a substrate surface.

As the method for applying the composition according to the present disclosure onto the support, various application methods such as slit coating, ink jet method, spin coating, cast coating, roll coating, and screen printing can be applied.

The coating film thickness of the composition is preferably 0.1 μm to 10 μm, more preferably 0.2 μm to 5 μm, and still more preferably 0.2 μm to 3 μm.

The composition film applied onto the support may be dried (pre-baked) at a temperature of 50° C. to 140° C. for 10 seconds to 300 seconds using a hot plate, an oven, or the like.

<Exposing Step>

In the exposing step, the composition film formed in the composition film forming step is exposed in a pattern-wise manner. The method of exposing the composition film to light in a pattern-wise manner may be, for example, a method of exposing the composition film to light through a mask having a predetermined mask pattern.

In the present step, in a case where the composition according to the present disclosure is a negative composition, a light-irradiated portion can be cured. In a case where the composition according to the present disclosure is a positive composition, the solubility of the light-irradiated portion in a developer increases.

As the actinic radiation that can be used in the exposure, ultraviolet rays such as g-line and i-line are particularly preferably used. The exposure amount is preferably 5 mJ/cm² to 1500 mJ/cm², more preferably 10 mJ/cm² to 1000 mJ/cm², and most preferably 10 mJ/cm² to 500 mJ/cm².

In a case where the color filter according to the present disclosure is for a liquid crystal display element, the exposure amount is preferably 5 mJ/cm² to 200 mJ/cm², more preferably 10 mJ/cm² to 150 mJ/cm², and most preferably 10 mJ/cm² to 100 mJ/cm², in the above range. In addition, in a case where the color filter according to the present disclosure is for a solid-state imaging element, the exposure amount is preferably 30 mJ/cm² to 1500 mJ/cm², more preferably 50 mJ/cm² to 1000 mJ/cm², and most preferably 80 mJ/cm² to 500 mJ/cm², in the above range.

<Developing Step>

Next, by carrying out a development treatment, an unexposed portion in the exposing step is eluted in a developer, and therefore a photocured portion is obtained as a colored pattern. The developer is not particularly limited as long as it can remove the composition in an uncured portion, and a known developer can be used. Specifically, a combination of various organic solvents or an alkaline aqueous solution can be used as the developer.

The development temperature is preferably 20° C. to 30° C., and the development time is preferably 20 seconds to 90 seconds.

Examples of the organic solvent include the above-mentioned solvents that can be used in a case of preparing the pigment dispersion composition or composition according to the present disclosure.

As to the alkaline aqueous solution, an alkaline aqueous solution obtained by diluting an alkaline compound, such as sodium hydroxide, potassium hydroxide, sodium carbonate, sodium hydrogen carbonate, sodium silicate, sodium metasilicate, ammonia water, ethylamine, diethylamine, dimethylethanolamine, tetramethylammonium hydroxide, tetraethylammonium hydroxide, choline, pyrrole, piperidine, or 1,8-diazabicyclo-[5.4.0]-7-undecene, with pure water so as to have a concentration of 0.001% by mass to 10% by mass and preferably 0.01% by mass to 1% by mass is preferably used as the developer.

In addition, in a case where the developer consisting of such an alkaline aqueous solution is used, an aspect of washing (rinsing) with pure water after development is also preferred.

After the developing step, an excess developer may be washed away and drying may be carried out, followed by a heat treatment (post-baking).

The post-baking is a heat treatment after development, and preferably a heat curing treatment at 100° C. to 240° C. is carried out. In a case where the substrate is a glass substrate or a silicon substrate, 200° C. to 240° C. is preferable in the above temperature range.

The post-baking treatment can be carried out continuously or batchwise using a heating unit such as a hot plate, a convection oven (hot air circulation dryer), or a high-frequency heater such that the coating film after development is in the above condition.

A color filter having desired hues is produced by repeating the above-mentioned steps of the composition film forming step, the exposing step, and the developing step (further, the heat treatment if necessary) only a number of times corresponding to the number of desired hues.

In a case where a film is formed by applying the composition according to the present disclosure onto a substrate, the dry thickness of the film is preferably 0.3 μm to 5.0 μm, more preferably 0.5 μm to 3.5 μm, and still more preferably 1.0 μm to 2.5 μm.

Examples of the substrate include a non-alkali glass, a soda glass, a Pyrex (registered trademark) glass, a quartz glass, and those glasses with a transparent conductive film attached thereto which are used in a liquid crystal display element or the like, a photoelectric conversion element substrate used in a solid-state imaging element or the like, for example, a silicon substrate, and a plastic substrate. A black stripe for isolating individual pixels is preferably formed on these substrates.

The plastic substrate preferably has a gas barrier layer and/or a solvent resistant layer on the surface thereof.

The above production method is a method for producing a pixel of a color filter, but according to the composition according to the present disclosure, for example, a black matrix provided between the pixels of the color filter is also produced. The black matrix can be formed, for example, by carrying out pattern-wise exposure, alkali development, and then post-baking to accelerate the curing of the film in the same manner as in the above-mentioned pixel production method, except that a black colorant such as carbon black or titanium black is added as the colorant to the composition according to the present disclosure.

(Second Aspect of Method for Producing Color Filter)

A second aspect of the method for producing a color filter according to the present disclosure includes a step of applying the composition according to the present disclosure onto a support and curing the applied composition to form a cured product (cured product forming step); a step of forming a photoresist layer on the cured product (photoresist layer forming step); a step of exposing the photoresist layer to light in a pattern-wise manner and developing the exposed photoresist layer to form a resist pattern (resist pattern forming step); and a step of etching the cured product through the resist pattern (etching step). Hereinafter, individual steps will be described.

<Cured Product Forming Step>

In the cured product forming step, the composition according to the present disclosure is applied onto a support and cured to form a cured product.

The support in the composition film forming step described above is preferably used as the support.

In addition, the application method in the composition film forming step described above is preferably used as the method for applying the composition.

The method for curing the applied composition is not particularly limited, and it is preferable to cure the applied composition by light or heat.

In a case where the composition is cured by light, the light may be appropriately selected according to the initiator included in the composition, but for example, ultraviolet rays such as g-line and i-line are preferably used. The exposure amount is preferably 5 mJ/cm² to 1500 mJ/cm², more preferably 10 mJ/cm² to 1000 mJ/cm², and most preferably 10 mJ/cm² to 500 mJ/cm².

In a case where the composition is cured by heat, the heating temperature is preferably 120° C. to 250° C. and more preferably 160° C. to 230° C. The heating time varies depending on the heating unit, but is preferably about 3 to 30 minutes in a case of being heated on a hot plate and preferably about 30 to 90 minutes in a case of being heated in an oven.

<Photoresist Layer Forming Step>

In the photoresist layer forming step, a photoresist layer is formed on the cured product.

In the formation of the photoresist layer, for example, a known negative or positive photosensitive composition is used, and a positive photosensitive composition is preferable.

The photoresist layer is obtained by applying the photosensitive composition onto the cured product and drying the applied photosensitive composition as necessary.

The method for forming the photoresist layer is not particularly limited, and may be carried out by a known method.

The thickness of the photoresist layer is preferably 0.1 μm to 3 μm, more preferably 0.2 μm to 2.5 μm, and still more preferably 0.3 μm to 2 μm.

<Resist Pattern Forming Step>

In the resist pattern forming step, the photoresist layer is exposed in a pattern-wise manner and developed to form a resist pattern.

The exposure and development are not particularly limited and are carried out by a known method.

<Etching Step>

In the etching step, the cured product is etched through the resist pattern.

The etching method is not particularly limited, and may be carried out by a known method, for example, a dry etching method.

<Step of Peeling Resist Pattern>

The second aspect of the method for producing a color filter according to the present disclosure may further include a step of peeling the resist pattern after the etching step.

The method of peeling the resist pattern is not particularly limited, and a known method is used.

(Image Display Device)

The image display device according to the present disclosure (for example, a liquid crystal display device, an organic electroluminescence (EL) display device, or an electronic paper) includes the color filter according to the present disclosure.

Specifically, for example, an alignment film is formed on an inner surface side of the color filter, the alignment film is opposed to an electrode substrate, and a gap portion therebetween is filled with liquid crystal and then sealed, whereby a liquid crystal panel that is the image display device according to the present disclosure is obtained.

The definition of the liquid crystal display device or details of the respective display devices are described in, for example, “Electronic Display Device (Akio Sasaki, Kogyo Chosakai Publishing Co., Ltd., published in 1990)”, “Display Device (Sumiaki Ibuki, Sangyo Tosho Co., Ltd., published in 1989)”, and the like. In addition, the liquid crystal display device is described in, for example, “Next-Generation Liquid Crystal Display Technology (edited by Tatsuo Uchida, Kogyo Chosakai Publishing Co., Ltd., published in 1994)”. The liquid crystal display device to which the present disclosure can be applied is not particularly limited, and for example, the present disclosure can be applied to various types of liquid crystal display devices described in the “Next-Generation Liquid Crystal Display Technology”.

(Solid-State Imaging Element)

The solid-state imaging element according to the present disclosure (for example, an image sensor such as a charge coupled device (CCD) or a complementary metal oxide semiconductor (CMOS)) includes the color filter according to the present disclosure.

For example, the solid-state imaging element according to the present disclosure can be obtained by forming a color filter on a light-receiving element.

Specifically, the solid-state imaging element according to the present disclosure has a configuration which has a plurality of photodiodes constituting a light-receiving area of a solid-state imaging element (a CCD image sensor, a CMOS image sensor, or the like) and transfer electrodes consisting of polysilicon or the like, on a substrate; a light shielding film consisting of tungsten or the like onto the photodiodes and the transfer electrodes, which has openings only over the light-receiving portion of the photodiode; a device protective film consisting of silicon nitride or the like, which is formed so as to cover the entire surface of the light shielding film and the light-receiving portion of the photodiodes, on the light shielding film; and a color filter for a solid-state imaging element according to the present disclosure on the device protective film.

Further, the solid-state imaging element according to the present disclosure may have, for example, a configuration having a light collecting unit (for example, a microlens; the same applies hereinafter) on the device protective film and below the color filter (on the side close to the support), or a configuration having the light collecting unit on the color filter.

(Compound)

The compound according to the present disclosure is a compound represented by Formula 4.

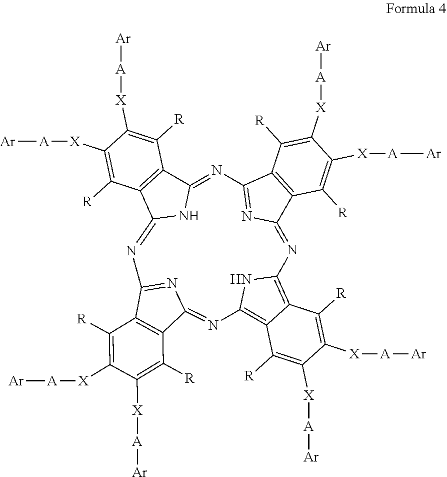

In Formula 4, X's each independently represent —O—, —S—, or —NR³—, A's each independently represent an alkylene group having 1 to 4 carbon atoms, which may have a substituent, and may contain —O—, —S—, or —NR³— in a site other than a bonding site to X, Ar's each independently represent an aryl group or a heteroaryl group, R³'s each independently represent a hydrogen atom, an alkyl group which may have a substituent, or an aryl group which may have a substituent, and R's each independently represent a hydrogen atom or a halogen atom.

In Formula 4, X has the same meaning as X in Formula 1 or Formula 3, except that X's each independently represent —O—, —S—, or —NR³—, and a preferred aspect thereof is also the same.

In Formula 4, R³ has the same meaning as R³ in Formula 1 or Formula 3, and a preferred aspect thereof is also the same.

In Formula 4, A has the same meaning as A in Formula 1 or Formula 3, except that A represents an alkylene group which may contain —O—S—, or —NR³— in a site other than a bonding site to X, and a preferred aspect thereof is also the same.

In Formula 4, Ar has the same meaning as R³ in Formula 1 or Formula 3, and a preferred aspect thereof is also the same.

In addition, preferred aspects of the maximum absorption wavelength, the absorbance at a wavelength of 570 nm, the average particle size, and the like of the compound represented by Formula 4 are also the same as the preferred aspects of the maximum absorption wavelength, the absorbance at a wavelength of 570 nm, the average particle size, and the like of the compound represented by Formula 1.

### EXAMPLES

Hereinafter, the present disclosure will be described in more detail with reference to Examples, but the present disclosure is not limited thereto.

In the Examples, “%” and “part(s)” refer to “% by mass” and “part(s) by mass”, respectively, unless otherwise specified. In addition, unless otherwise specified, in the polymer compound, the molecular weight is a weight-average molecular weight (Mw), and the ratio of the structural repeating units is a mole percentage.

The weight-average molecular weight (Mw) is a value measured in terms of polystyrene by gel permeation chromatography (GPC).

In addition, in the present examples, compound Pc-1 to compound Pc-121 which are the specific compounds are the same as the compound Pc-1 to compound Pc-121 in the above-mentioned specific examples.

<Synthesis of Specific Compound>

[Synthesis of Pc-6]

—Production of Intermediate A—

20.0 parts of dichlorophthalonitrile (manufactured by Tokyo Chemical Industry Co., Ltd.), 23.0 parts of phenethyl alcohol (manufactured by Tokyo Chemical Industry Co., Ltd.), and 250 parts of N,N-dimethylacetamide (DMAc, manufactured by Wako Pure Chemical Industries, Ltd.) were added to a three-neck flask, and stirred and dissolved at 40° C. Subsequently, 42.0 parts of potassium carbonate (manufactured by Nippon Soda Co., Ltd.) were added to the mixture which was then heated and stirred at 80° C. for 16 hours. After cooling to room temperature, 500 parts of distilled water were added dropwise thereto, followed by further stirring at the same temperature for 1 hour. The resulting solid was filtered, and the solid was washed with 500 parts of distilled water, further washed with a mixed liquid of 250 parts of methanol and 250 parts of distilled water, and dried. The obtained solid was subjected to silica gel column chromatography (ethyl acetate/hexane=20/80 vol %) to obtain 10.4 parts of an intermediate A.

The structure of the obtained intermediate A was identified by H-nuclear magnetic resonance (NMR). The identification results are shown below.

(¹H-NMR 300 MHz deuterated chloroform): 3.11 (t, 4H), 4.27 (t, 4H), 7.12 to 7.30 (m, 10H), 7.90 (s, 2H).

—Production of Pc-6—

2.0 parts of the intermediate A, 0.74 parts of diazabicycloundecene (DBU, manufactured by Wako Pure Chemical Industries, Ltd.), and 8.0 parts of normal pentanol (manufactured by Wako Pure Chemical Industries, Ltd.) were added to a three-neck flask and stirred at 160° C. for 4 hours. After cooling to 25° C., 10 parts of methanol were added thereto, followed by stirring at the same temperature for 1 hour. The resulting solid was filtered, and the solid was washed with 20 parts of methanol and dried. The solid and 20 parts of tetrahydrofuran were placed in a three-neck flask and stirred at 60° C. for 1 hour. After cooling to 25° C., the solid was recovered by filtration, washed twice with 20 parts of tetrahydrofuran, washed with 10 parts of methanol, and then dried to obtain 1.12 g of Pc-6.

The obtained Pc-6 was subjected to UV spectrum measurement using N-methylpiperidone, and as a result, it was confirmed that the compound had a maximum absorption wavelength of 683 nm.

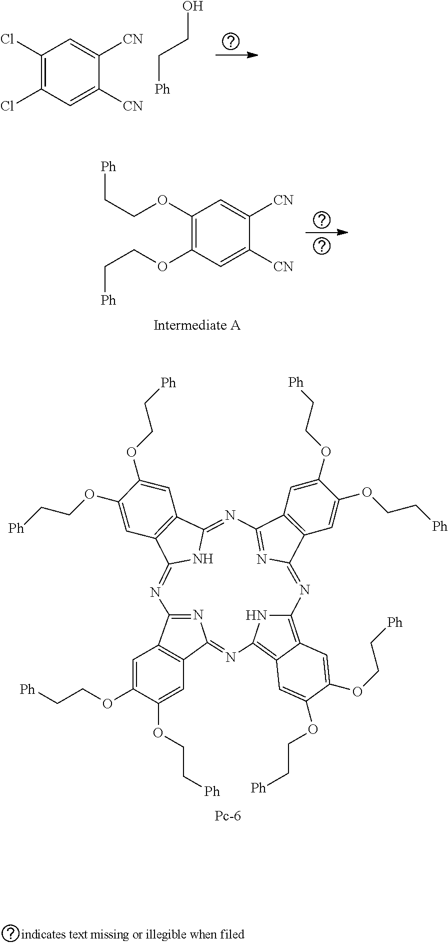

[Synthesis of Pc-10]

—Production of Intermediate B—

5.00 parts of the intermediate A and 40 parts of N,N-dimethylformamide (DMF, manufactured by Wako Pure Chemical Industries, Ltd.) were added to a three-neck flask, and cooled to 0° C. or lower. Subsequently, a solution of 3.99 parts of N-chlorosuccinimide (NCS, manufactured by Tokyo Chemical Industry Co., Ltd.) in N,N-dimethylformamide (20 parts) was added dropwise thereto. After the completion of the dropwise addition, the temperature was raised to 25° C., and 100 parts of distilled water were added dropwise thereto, followed by further stirring at the same temperature for 1 hour. The resulting solid was filtered, and the solid was washed with 100 parts of distilled water, further washed with a mixed liquid of 50 parts of methanol and 50 parts of distilled water, and dried to obtain 3.30 parts of an intermediate B.

The structure of the obtained intermediate B was identified by ¹H-NMR (nuclear magnetic resonance). The identification results are shown below.

(¹H-NMR 300 MHz deuterated chloroform): 3.10 (t, 4H), 4.33 (t, 4H), 7.11 to 7.30 (m, 10H)

—Production of Pc-10—

Pc-10 was obtained in the same manner as for Pc-6, except that, in the production of Pc-6, the intermediate B was used in place of the intermediate A and the amount of the compound used was appropriately changed.

The obtained Pc-10 was subjected to UV spectrum measurement using N-methylpiperidone, and as a result, it was confirmed that the compound had a maximum absorption wavelength of 701 nm.

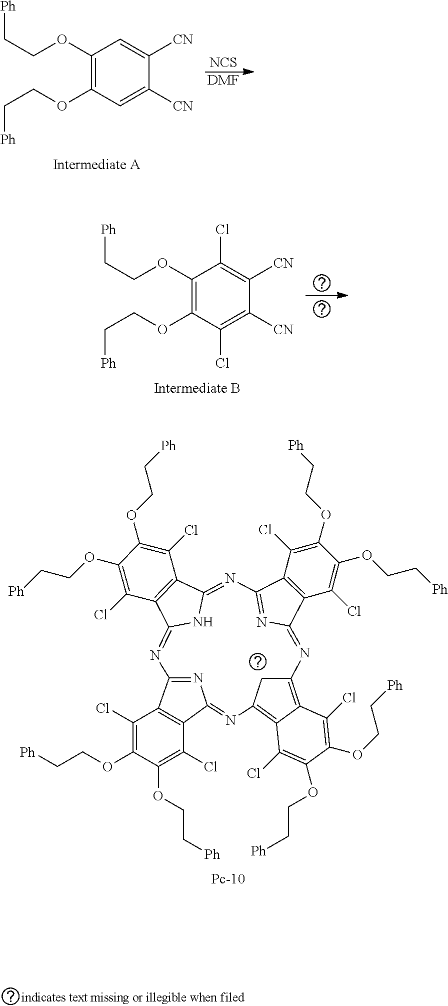

[Synthesis of Pc-33]

—Production of Intermediate C—

20.0 parts of dichlorophthalonitrile (manufactured by Tokyo Chemical Industry Co., Ltd.), 25.8 parts of phenethylamine (manufactured by Tokyo Chemical Industry Co., Ltd.), and 250 parts of N,N-dimethylacetamide (DMAc, manufactured by Wako Pure Chemical Industries, Ltd.) were added to a three-neck flask, and stirred and dissolved at 40° C. Subsequently, 42.0 parts of potassium carbonate (manufactured by Nippon Soda Co., Ltd.) were added to the mixture which was then heated and stirred at 60° C. for 4 hours. After cooling to room temperature, 500 parts of distilled water were added dropwise thereto, followed by further stirring at the same temperature for 1 hour. The resulting solid was filtered, and the solid was washed with 500 parts of distilled water, further washed with a mixed liquid of 250 parts of methanol and 250 parts of distilled water, and dried to obtain 31.7 parts of an intermediate C.

The structure of the obtained intermediate C was identified by H-NMR (nuclear magnetic resonance). The identification results are shown below.

(¹H-NMR 300 MHz deuterated chloroform): 2.93 (t, 4H), 3.42 (t, 4H), 7.02 (s, 2H), 7.18 to 7.26 (m, 10H).

—Production of Pc-33—

Pc-33 was obtained in the same manner as for Pc-6, except that, in the production of Pc-6, the intermediate C was used in place of the intermediate A and the amount of the compound used was appropriately changed.

The obtained Pc-33 was subjected to UV spectrum measurement using N-methylpiperidone, and as a result, it was confirmed that the compound had a maximum absorption wavelength of 712 nm.

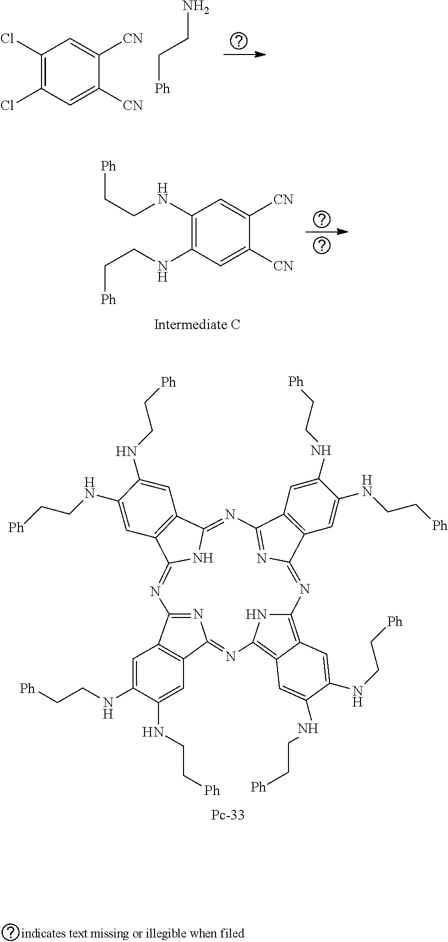

[Synthesis of Pc-37]

—Production of Intermediate D—

5.00 parts of the intermediate C and 40 parts of N,N-dimethylformamide (manufactured by Wako Pure Chemical Industries, Ltd., Fujifilm Wako Pure Chemical Industries, Ltd.) were added to a three-neck flask, and cooled to 0° C. or lower. Subsequently, a solution of 4.01 parts of N-chlorosuccinimide (manufactured by Tokyo Chemical Industry Co., Ltd.) in N,N-dimethylformamide (20 parts) was added dropwise thereto. After the completion of the dropwise addition, the temperature was raised to 25° C., and 100 parts of distilled water were added dropwise thereto, followed by further stirring at the same temperature for 1 hour. The resulting solid was filtered, and the solid was washed with 100 parts of distilled water, further washed with a mixed liquid of 100 parts of methanol and 100 parts of distilled water, and dried to obtain 2.78 parts of an intermediate D.

The structure of the obtained intermediate D was identified by ¹H-NMR (nuclear magnetic resonance). The identification results are shown below.

(¹H-NMR 300 MHz deuterated chloroform): 2.91 (t, 4H), 3.54 (t, 4H), 7.18 to 7.27 (m, 10H).

—Production of Pc-37—

Pc-37 was obtained in the same manner as for Pc-6, except that, in the production of Pc-6, the intermediate D was used in place of the intermediate A and the amount of the compound used was appropriately changed.

The obtained Pc-37 was subjected to UV spectrum measurement using N-methylpiperidone, and as a result, it was confirmed that the compound had a maximum absorption wavelength of 722 nm.

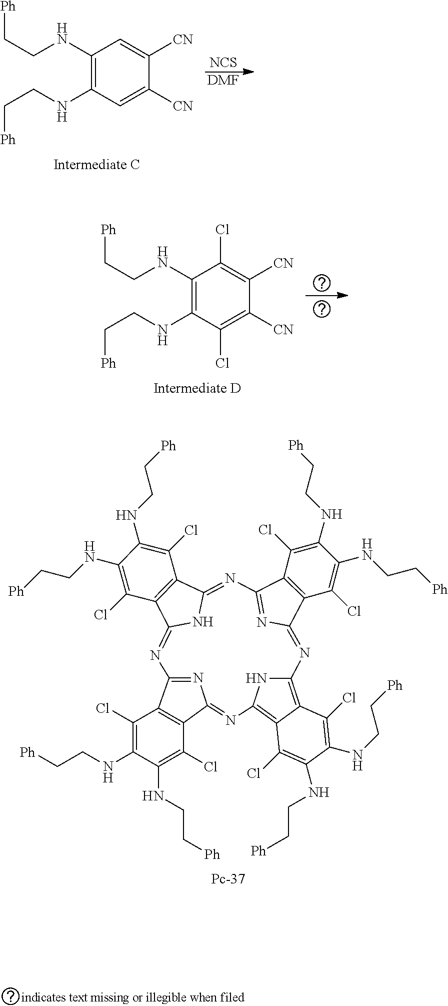

[Synthesis of Pc-71]

—Production of Intermediate E—

25.0 parts of dichlorophthalonitrile (manufactured by Tokyo Chemical Industry Co., Ltd.), 36.8 parts of 2-phenylethanethiol (manufactured by Tokyo Chemical Industry Co., Ltd.), and 500 parts of N,N-dimethylacetamide (DMAc, manufactured by Wako Pure Chemical Industries, Ltd.) were added to a three-neck flask, and stirred and dissolved at 40° C. Subsequently, 52.6 parts of potassium carbonate (manufactured by Nippon Soda Co., Ltd.) were added to the mixture which was then heated and stirred at 60° C. for 4 hours. After cooling to room temperature, 500 parts of distilled water were added dropwise thereto, followed by further stirring at the same temperature for 1 hour. The resulting solid was filtered, and the solid was washed with 500 parts of distilled water, further washed with a mixed liquid of 250 parts of methanol and 250 parts of distilled water, and dried to obtain 52.2 parts of an intermediate E.

The structure of the obtained intermediate E was identified by ¹H-NMR (nuclear magnetic resonance). The identification results are shown below.

(¹H-NMR 300 MHz deuterated chloroform): 3.02 (t, 4H), 3.26 (t, 4H), 7.18 to 7.37 (m, 12H).

—Production of Pc-71—

Pc-71 was obtained in the same manner as for Pc-6, except that, in the production of Pc-6, the intermediate E was used in place of the intermediate A and the amount of the compound used was appropriately changed.

The obtained Pc-71 was subjected to UV spectrum measurement using N-methylpiperidone, and as a result, it was confirmed that the compound had a maximum absorption wavelength of 703 nm.

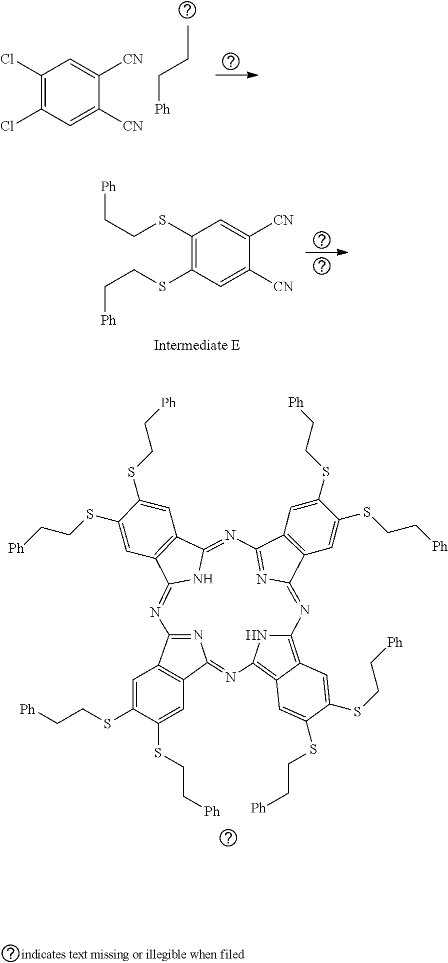

In addition, compounds other than Pc-6, Pc-10, Pc-33, Pc-37, and Pc-71 included in Pc-1 to Pc-121 were synthesized with reference to the synthesis methods of Pc-6, Pc-10, Pc-33, Pc-37, and Pc-71.

<Preparation of Dispersion Liquid>

A pigment (G pigment (specific compound): 8.29 parts by mass, Y pigment (yellow pigment): 2.07 parts by mass), a derivative (1.03 parts by mass), a dispersant, and a solvent (71.92 parts by mass) shown in the tables which will be given later were mixed, 230 parts by mass of zirconia beads having a diameter of 0.3 mm were added thereto, a dispersion treatment was carried out for 5 hours using a paint shaker, and the beads were separated by filtration to produce a dispersion liquid. The numerical values in the tables which will be given later are parts by mass.

In the tables which will be given later, the description of “T” indicates that a corresponding compound or an amount thereof used is the same as the compound or the amount thereof used in the column immediately above.

TABLE 71

| | Pigment | | | Dispersant | | |
|---|---|---|---|---|---|---|
| | G | Y | | | Parts by | Solvent |
| | pigment | pigment | Derivative | Type | mass | Type |
| Dispersion | Pc-1 | PY-185 | Derivative-1 | P-1 | 15.12 | PGMEA |
| liquid 1 | | | | | | |
| Dispersion | Pc-2 | ↑ | ↑ | ↑ | ↑ | ↑ |
| liquid 2 | | | | | | |
| Dispersion | Pc-3 | ↑ | ↑ | ↑ | ↑ | ↑ |
| liquid 3 | | | | | | |
| Dispersion | Pc-4 | ↑ | ↑ | ↑ | ↑ | ↑ |
| liquid 4 | | | | | | |
| Dispersion | Pc-5 | ↑ | ↑ | ↑ | ↑ | ↑ |
| liquid 5 | | | | | | |
| Dispersion | Pc-6 | ↑ | ↑ | ↑ | ↑ | ↑ |
| liquid 6 | | | | | | |
| Dispersion | Pc-7 | ↑ | ↑ | ↑ | ↑ | ↑ |
| liquid 7 | | | | | | |
| Dispersion | Pc-8 | ↑ | ↑ | ↑ | ↑ | ↑ |
| liquid 8 | | | | | | |
| Dispersion | Pc-9 | ↑ | ↑ | ↑ | ↑ | ↑ |
| liquid 9 | | | | | | |
| Dispersion | ↑ | PY-139 | ↑ | ↑ | ↑ | ↑ |
| liquid 10 | | | | | | |
| Dispersion | ↑ | PY-150 | ↑ | ↑ | ↑ | ↑ |
| liquid 11 | | | | | | |
| Dispersion | ↑ | PY-185 | ↑ | ↑ | 11.00 | ↑ |
| liquid 12 | | | | | | |
| Dispersion | ↑ | ↑ | ↑ | P-2 | 15.12 | ↑ |
| liquid 13 | | | | | | |
| Dispersion | ↑ | ↑ | ↑ | P-3 | ↑ | ↑ |
| liquid 14 | | | | | | |
| Dispersion | ↑ | ↑ | Derivative-2 | P-4 | ↑ | ↑ |
| liquid 15 | | | | | | |
| Dispersion | ↑ | ↑ | Derivative-3 | P-1 | ↑ | ↑ |
| liquid 16 | | | | | | |
| Dispersion | ↑ | ↑ | Derivative-4 | ↑ | ↑ | ↑ |
| liquid 17 | | | | | | |
| Dispersion | ↑ | ↑ | Derivative-1 | ↑ | ↑ | PGME |
| liquid 18 | | | | | | |
| Dispersion | Pc-10 | ↑ | ↑ | ↑ | ↑ | PGMEA |
| liquid 19 | | | | | | |
| Dispersion | ↑ | PY-139 | ↑ | ↑ | ↑ | ↑ |
| liquid 20 | | | | | | |
| Dispersion | ↑ | PY-150 | ↑ | ↑ | ↑ | ↑ |
| liquid 21 | | | | | | |
| Dispersion | ↑ | PY-185 | ↑ | ↑ | 11.00 | ↑ |
| liquid 22 | | | | | | |
| Dispersion | ↑ | ↑ | ↑ | P-2 | 15.12 | ↑ |
| liquid 23 | | | | | | |
| Dispersion | ↑ | ↑ | ↑ | P-3 | ↑ | ↑ |
| liquid 24 | | | | | | |
| Dispersion | ↑ | ↑ | Derivative-2 | P-4 | ↑ | ↑ |
| liquid 25 | | | | | | |
| Dispersion | ↑ | ↑ | Derivative-3 | P-1 | ↑ | ↑ |
| liquid 26 | | | | | | |
| Dispersion | ↑ | ↑ | Derivative-4 | ↑ | ↑ | ↑ |
| liquid 27 | | | | | | |
| Dispersion | ↑ | ↑ | Derivative-1 | ↑ | ↑ | PGME |
| liquid 28 | | | | | | |
| Dispersion | Pc-11 | ↑ | ↑ | ↑ | ↑ | PGMEA |
| liquid 29 | | | | | | |
| Dispersion | Pc-12 | ↑ | ↑ | ↑ | ↑ | ↑ |
| liquid 30 | | | | | | |
| Dispersion | Pc-13 | ↑ | ↑ | ↑ | ↑ | ↑ |
| liquid 31 | | | | | | |
| Dispersion | Pc-14 | ↑ | ↑ | ↑ | ↑ | ↑ |
| liquid 32 | | | | | | |
| Dispersion | Pc-15 | ↑ | ↑ | ↑ | ↑ | ↑ |
| liquid 33 | | | | | | |
| Dispersion | Pc-16 | ↑ | ↑ | ↑ | ↑ | ↑ |
| liquid 34 | | | | | | |
| Dispersion | Pc-17 | ↑ | ↑ | ↑ | ↑ | ↑ |
| liquid 35 | | | | | | |
| Dispersion | Pc-18 | ↑ | ↑ | ↑ | ↑ | ↑ |
| liquid 36 | | | | | | |
| Dispersion | Pc-19 | ↑ | ↑ | ↑ | ↑ | ↑ |
| liquid 37 | | | | | | |
| Dispersion | Pc-20 | ↑ | ↑ | ↑ | ↑ | ↑ |
| liquid 38 | | | | | | |
| Dispersion | Pc-21 | ↑ | ↑ | ↑ | ↑ | ↑ |
| liquid 39 | | | | | | |
| Dispersion | Pc-22 | ↑ | ↑ | ↑ | ↑ | ↑ |
| liquid 40 | | | | | | |
| Dispersion | Pc-23 | ↑ | ↑ | ↑ | ↑ | ↑ |
| liquid 41 | | | | | | |
| Dispersion | Pc-24 | ↑ | ↑ | ↑ | ↑ | ↑ |
| liquid 42 | | | | | | |
| Dispersion | Pc-25 | ↑ | ↑ | ↑ | ↑ | ↑ |
| liquid 43 | | | | | | |
| Dispersion | Pc-26 | ↑ | ↑ | ↑ | ↑ | ↑ |
| liquid 44 | | | | | | |
| Dispersion | Pc-27 | ↑ | ↑ | ↑ | ↑ | ↑ |
| liquid 45 | | | | | | |
| Dispersion | Pc-28 | PY-185 | Derivative-1 | P-1 | 15.12 | PGMEA |
| liquid 46 | | | | | | |
| Dispersion | Pc-29 | ↑ | ↑ | ↑ | ↑ | ↑ |
| liquid 47 | | | | | | |
| Dispersion | ↑ | PY-139 | ↑ | ↑ | ↑ | ↑ |
| liquid 48 | | | | | | |
| Dispersion | ↑ | PY-150 | ↑ | ↑ | ↑ | ↑ |
| liquid 49 | | | | | | |
| Dispersion | ↑ | PY-185 | ↑ | ↑ | 11.00 | ↑ |
| liquid 50 | | | | | | |
| Dispersion | ↑ | ↑ | ↑ | P-2 | 15.12 | ↑ |
| liquid 51 | | | | | | |
| Dispersion | ↑ | ↑ | ↑ | P-3 | ↑ | ↑ |
| liquid 52 | | | | | | |
| Dispersion | ↑ | ↑ | Derivative-2 | P-4 | ↑ | ↑ |
| liquid 53 | | | | | | |
| Dispersion | ↑ | ↑ | Derivative-3 | P-1 | ↑ | ↑ |
| liquid 54 | | | | | | |
| Dispersion | ↑ | ↑ | Derivative-4 | ↑ | ↑ | ↑ |
| liquid 55 | | | | | | |
| Dispersion | ↑ | ↑ | Derivative-1 | ↑ | ↑ | PGME |
| liquid 56 | | | | | | |
| Dispersion | Pc-30 | PY-185 | Derivative-1 | P-1 | 15.12 | PGMEA |
| liquid 57 | | | | | | |
| Dispersion | Pc-31 | ↑ | ↑ | ↑ | ↑ | ↑ |
| liquid 58 | | | | | | |
| Dispersion | Pc-32 | ↑ | ↑ | ↑ | ↑ | ↑ |
| liquid 59 | | | | | | |
| Dispersion | Pc-33 | ↑ | ↑ | ↑ | ↑ | ↑ |
| liquid 60 | | | | | | |
| Dispersion | Pc-34 | ↑ | ↑ | ↑ | ↑ | ↑ |
| liquid 61 | | | | | | |
| Dispersion | Pc-35 | ↑ | ↑ | ↑ | ↑ | ↑ |
| liquid 62 | | | | | | |
| Dispersion | Pc-36 | ↑ | ↑ | ↑ | ↑ | ↑ |
| liquid 63 | | | | | | |
| Dispersion | ↑ | PY-139 | ↑ | ↑ | ↑ | ↑ |
| liquid 64 | | | | | | |
| Dispersion | ↑ | PY-150 | ↑ | ↑ | ↑ | ↑ |
| liquid 65 | | | | | | |
| Dispersion | ↑ | PY-185 | ↑ | ↑ | 11.00 | ↑ |
| liquid 66 | | | | | | |
| Dispersion | ↑ | ↑ | ↑ | P-2 | 15.12 | ↑ |
| liquid 67 | | | | | | |
| Dispersion | ↑ | ↑ | ↑ | P-3 | ↑ | ↑ |
| liquid 68 | | | | | | |
| Dispersion | ↑ | ↑ | Derivative-2 | P-4 | ↑ | ↑ |
| liquid 69 | | | | | | |
| Dispersion | ↑ | ↑ | Derivative-3 | P-1 | ↑ | ↑ |
| liquid 70 | | | | | | |
| Dispersion | ↑ | ↑ | Derivative-4 | ↑ | ↑ | ↑ |
| liquid 71 | | | | | | |
| Dispersion | ↑ | ↑ | Derivative-1 | ↑ | ↑ | PGME |
| liquid 72 | | | | | | |
| Dispersion | Pc-37 | ↑ | ↑ | ↑ | ↑ | PGMEA |
| liquid 73 | | | | | | |
| Dispersion | ↑ | PY-139 | ↑ | ↑ | ↑ | ↑ |
| liquid 74 | | | | | | |
| Dispersion | ↑ | PY-150 | ↑ | ↑ | ↑ | ↑ |
| liquid 75 | | | | | | |
| Dispersion | ↑ | PY-185 | ↑ | ↑ | 11.00 | ↑ |
| liquid 76 | | | | | | |
| Dispersion | ↑ | ↑ | ↑ | P-2 | 15.12 | ↑ |
| liquid 77 | | | | | | |
| Dispersion | ↑ | ↑ | ↑ | P-3 | ↑ | ↑ |
| liquid 78 | | | | | | |
| Dispersion | ↑ | ↑ | Derivative-2 | P-4 | ↑ | ↑ |
| liquid 79 | | | | | | |
| Dispersion | ↑ | ↑ | Derivative-3 | P-1 | ↑ | ↑ |
| liquid 80 | | | | | | |
| Dispersion | ↑ | ↑ | Derivative-4 | ↑ | ↑ | ↑ |
| liquid 81 | | | | | | |
| Dispersion | ↑ | ↑ | Derivative-1 | ↑ | ↑ | PGME |
| liquid 82 | | | | | | |
| Dispersion | Pc-38 | ↑ | ↑ | ↑ | ↑ | PGMEA |
| liquid 83 | | | | | | |
| Dispersion | Pc-39 | ↑ | ↑ | ↑ | ↑ | ↑ |
| liquid 84 | | | | | | |
| Dispersion | Pc-40 | ↑ | ↑ | ↑ | ↑ | ↑ |
| liquid 85 | | | | | | |
| Dispersion | Pc-41 | ↑ | ↑ | ↑ | ↑ | ↑ |
| liquid 86 | | | | | | |
| Dispersion | Pc-42 | ↑ | ↑ | ↑ | ↑ | ↑ |
| liquid 87 | | | | | | |
| Dispersion | Pc-43 | ↑ | ↑ | ↑ | ↑ | ↑ |
| liquid 88 | | | | | | |
| Dispersion | Pc-44 | ↑ | ↑ | ↑ | ↑ | ↑ |
| liquid 89 | | | | | | |
| Dispersion | Pc-45 | ↑ | ↑ | ↑ | ↑ | ↑ |
| liquid 90 | | | | | | |

TABLE 8

| | Pigment | | | Dispersant | | |
|---|---|---|---|---|---|---|
| | G | Y | | | Parts by | Solvent |
| | pigment | pigment | Derivative | Type | mass | Type |
| Dispersion | Pc-46 | PY-185 | Derivative-1 | P-1 | 15.12 | PGMEA |
| liquid 91 | | | | | | |
| Dispersion | Pc-47 | ↑ | ↑ | ↑ | ↑ | ↑ |
| liquid 92 | | | | | | |
| Dispersion | Pc-48 | ↑ | ↑ | ↑ | ↑ | ↑ |
| liquid 93 | | | | | | |
| Dispersion | Pc-49 | ↑ | ↑ | ↑ | ↑ | ↑ |
| liquid 94 | | | | | | |
| Dispersion | Pc-50 | ↑ | ↑ | ↑ | ↑ | ↑ |
| liquid 95 | | | | | | |
| Dispersion | Pc-51 | ↑ | ↑ | ↑ | ↑ | ↑ |
| liquid 96 | | | | | | |
| Dispersion | Pc-52 | ↑ | ↑ | ↑ | ↑ | ↑ |
| liquid 97 | | | | | | |
| Dispersion | Pc-53 | ↑ | ↑ | ↑ | ↑ | ↑ |
| liquid 98 | | | | | | |
| Dispersion | Pc-54 | ↑ | ↑ | ↑ | ↑ | ↑ |
| liquid 99 | | | | | | |
| Dispersion | Pc-55 | ↑ | ↑ | ↑ | ↑ | ↑ |
| liquid 100 | | | | | | |
| Dispersion | Pc-56 | ↑ | ↑ | ↑ | ↑ | ↑ |
| liquid 101 | | | | | | |
| Dispersion | ↑ | PY-139 | ↑ | ↑ | ↑ | ↑ |
| liquid 102 | | | | | | |
| Dispersion | ↑ | PY-150 | ↑ | ↑ | ↑ | ↑ |
| liquid 103 | | | | | | |
| Dispersion | ↑ | PY-185 | ↑ | ↑ | 11.00 | ↑ |
| liquid 104 | | | | | | |
| Dispersion | ↑ | ↑ | ↑ | P-2 | 15.12 | ↑ |
| liquid 105 | | | | | | |
| Dispersion | ↑ | ↑ | ↑ | P-3 | ↑ | ↑ |
| liquid 106 | | | | | | |
| Dispersion | ↑ | ↑ | Derivative-2 | P-4 | ↑ | ↑ |
| liquid 107 | | | | | | |
| Dispersion | ↑ | ↑ | Derivative-3 | P-1 | ↑ | ↑ |
| liquid 108 | | | | | | |
| Dispersion | ↑ | ↑ | Derivative-4 | ↑ | ↑ | ↑ |
| liquid 109 | | | | | | |
| Dispersion | ↑ | ↑ | Derivative-1 | ↑ | ↑ | PGME |
| liquid 110 | | | | | | |
| Dispersion | Pc-57 | PY-185 | Derivative-1 | P-1 | 15.12 | PGMEA |
| liquid 111 | | | | | | |
| Dispersion | ↑ | PY-139 | ↑ | ↑ | ↑ | ↑ |
| liquid 112 | | | | | | |
| Dispersion | ↑ | PY-150 | ↑ | ↑ | ↑ | ↑ |
| liquid 113 | | | | | | |
| Dispersion | ↑ | PY-185 | ↑ | ↑ | 11.00 | ↑ |
| liquid 114 | | | | | | |
| Dispersion | ↑ | ↑ | ↑ | P-2 | 15.12 | ↑ |
| liquid 115 | | | | | | |
| Dispersion | ↑ | ↑ | ↑ | P-3 | ↑ | ↑ |
| liquid 116 | | | | | | |
| Dispersion | ↑ | ↑ | Derivative-2 | P-4 | ↑ | ↑ |
| liquid 117 | | | | | | |
| Dispersion | ↑ | ↑ | Derivative-3 | P-1 | ↑ | ↑ |
| liquid 118 | | | | | | |
| Dispersion | ↑ | ↑ | Derivative-4 | ↑ | ↑ | ↑ |
| liquid 119 | | | | | | |
| Dispersion | ↑ | ↑ | Derivative-1 | ↑ | ↑ | PGME |
| liquid 120 | | | | | | |
| Dispersion | Pc-58 | ↑ | ↑ | ↑ | ↑ | PGMEA |
| liquid 121 | | | | | | |
| Dispersion | Pc-59 | ↑ | ↑ | ↑ | ↑ | ↑ |
| liquid 122 | | | | | | |
| Dispersion | Pc-60 | ↑ | ↑ | ↑ | ↑ | ↑ |
| liquid 123 | | | | | | |
| Dispersion | Pc-61 | ↑ | ↑ | ↑ | ↑ | ↑ |
| liquid 124 | | | | | | |
| Dispersion | Pc-62 | ↑ | ↑ | ↑ | ↑ | ↑ |
| liquid 125 | | | | | | |
| Dispersion | Pc-63 | ↑ | ↑ | ↑ | ↑ | ↑ |
| liquid 126 | | | | | | |
| Dispersion | ↑ | PY-139 | ↑ | ↑ | ↑ | ↑ |
| liquid 127 | | | | | | |
| Dispersion | ↑ | PY-150 | ↑ | ↑ | ↑ | ↑ |
| liquid 128 | | | | | | |
| Dispersion | ↑ | PY-185 | ↑ | ↑ | 11.00 | ↑ |
| liquid 129 | | | | | | |
| Dispersion | ↑ | ↑ | ↑ | P-2 | 15.12 | ↑ |
| liquid 130 | | | | | | |
| Dispersion | ↑ | ↑ | ↑ | P-3 | ↑ | ↑ |
| liquid 131 | | | | | | |
| Dispersion | ↑ | ↑ | Derivative-2 | P-4 | ↑ | ↑ |
| liquid 132 | | | | | | |
| Dispersion | ↑ | ↑ | Derivative-3 | P-1 | ↑ | ↑ |
| liquid 133 | | | | | | |
| Dispersion | ↑ | ↑ | Derivative-4 | ↑ | ↑ | ↑ |
| liquid 134 | | | | | | |
| Dispersion | ↑ | ↑ | Derivative-1 | ↑ | ↑ | PGME |
| liquid 135 | | | | | | |
| Dispersion | Pc-64 | PY-185 | Derivative-1 | P-1 | 15.12 | PGMEA |
| liquid 136 | | | | | | |
| Dispersion | ↑ | PY-139 | ↑ | ↑ | ↑ | ↑ |
| liquid 137 | | | | | | |
| Dispersion | ↑ | PY-150 | ↑ | ↑ | ↑ | ↑ |
| liquid 138 | | | | | | |
| Dispersion | ↑ | PY-185 | ↑ | ↑ | 11.00 | ↑ |
| liquid 139 | | | | | | |
| Dispersion | ↑ | ↑ | ↑ | P-2 | 15.12 | ↑ |
| liquid 140 | | | | | | |
| Dispersion | ↑ | ↑ | ↑ | P-3 | ↑ | ↑ |
| liquid 141 | | | | | | |
| Dispersion | ↑ | ↑ | Derivative-2 | P-4 | ↑ | ↑ |
| liquid 142 | | | | | | |
| Dispersion | ↑ | ↑ | Derivative-3 | P-1 | ↑ | ↑ |
| liquid 143 | | | | | | |
| Dispersion | ↑ | ↑ | Derivative-4 | ↑ | ↑ | ↑ |
| liquid 144 | | | | | | |
| Dispersion | ↑ | ↑ | Derivative-1 | ↑ | ↑ | PGME |
| liquid 145 | | | | | | |
| Dispersion | Pc-65 | ↑ | ↑ | ↑ | ↑ | PGMEA |
| liquid 146 | | | | | | |
| Dispersion | Pc-66 | ↑ | ↑ | ↑ | ↑ | ↑ |
| liquid 147 | | | | | | |
| Dispersion | Pc-67 | ↑ | ↑ | ↑ | ↑ | ↑ |
| liquid 148 | | | | | | |
| Dispersion | ↑ | PY-139 | ↑ | ↑ | ↑ | ↑ |
| liquid 149 | | | | | | |
| Dispersion | ↑ | PY-150 | ↑ | ↑ | ↑ | ↑ |
| liquid 150 | | | | | | |
| Dispersion | ↑ | PY-185 | ↑ | ↑ | 11.00 | ↑ |
| liquid 151 | | | | | | |
| Dispersion | ↑ | ↑ | ↑ | P-2 | 15.12 | ↑ |
| liquid 152 | | | | | | |
| Dispersion | ↑ | ↑ | ↑ | P-3 | ↑ | ↑ |
| liquid 153 | | | | | | |
| Dispersion | ↑ | ↑ | Derivative-2 | P-4 | ↑ | ↑ |
| liquid 154 | | | | | | |
| Dispersion | ↑ | ↑ | Derivative-3 | P-1 | ↑ | ↑ |
| liquid 155 | | | | | | |
| Dispersion | ↑ | ↑ | Derivative-4 | ↑ | ↑ | ↑ |
| liquid 156 | | | | | | |
| Dispersion | ↑ | ↑ | Derivative-1 | ↑ | ↑ | PGME |
| liquid 157 | | | | | | |
| Dispersion | Pc-68 | ↑ | ↑ | ↑ | ↑ | PGMEA |
| liquid 158 | | | | | | |
| Dispersion | Pc-69 | ↑ | ↑ | ↑ | ↑ | ↑ |
| liquid 159 | | | | | | |
| Dispersion | Pc-70 | ↑ | ↑ | ↑ | ↑ | ↑ |
| liquid 160 | | | | | | |
| Dispersion | Pc-71 | ↑ | ↑ | ↑ | ↑ | ↑ |
| liquid 161 | | | | | | |
| Dispersion | Pc-72 | ↑ | ↑ | ↑ | ↑ | ↑ |
| liquid 162 | | | | | | |
| Dispersion | Pc-73 | ↑ | ↑ | ↑ | ↑ | ↑ |
| liquid 163 | | | | | | |
| Dispersion | Pc-74 | PY-185 | Derivative-1 | P-1 | 15.12 | PGMEA |
| liquid 164 | | | | | | |
| Dispersion | ↑ | PY-139 | ↑ | ↑ | ↑ | ↑ |
| liquid 165 | | | | | | |
| Dispersion | ↑ | PY-150 | ↑ | ↑ | ↑ | ↑ |
| liquid 166 | | | | | | |
| Dispersion | ↑ | PY-185 | ↑ | ↑ | 11.00 | ↑ |
| liquid 167 | | | | | | |
| Dispersion | ↑ | ↑ | ↑ | P-2 | 15.12 | ↑ |
| liquid 168 | | | | | | |
| Dispersion | ↑ | ↑ | ↑ | P-3 | ↑ | ↑ |
| liquid 169 | | | | | | |
| Dispersion | ↑ | ↑ | Derivative-2 | P-4 | ↑ | ↑ |
| liquid 170 | | | | | | |
| Dispersion | ↑ | ↑ | Derivative-3 | P-1 | ↑ | ↑ |
| liquid 171 | | | | | | |
| Dispersion | ↑ | ↑ | Derivative-4 | ↑ | ↑ | ↑ |
| liquid 172 | | | | | | |
| Dispersion | ↑ | ↑ | Derivative-1 | ↑ | ↑ | PGME |
| liquid 173 | | | | | | |
| Dispersion | Pc-75 | ↑ | ↑ | ↑ | ↑ | PGMEA |
| liquid 174 | | | | | | |
| Dispersion | ↑ | PY-139 | ↑ | ↑ | ↑ | ↑ |
| liquid 175 | | | | | | |
| Dispersion | ↑ | PY-150 | ↑ | ↑ | ↑ | ↑ |
| liquid 176 | | | | | | |
| Dispersion | ↑ | PY-185 | ↑ | ↑ | 11.00 | ↑ |
| liquid 177 | | | | | | |
| Dispersion | ↑ | ↑ | ↑ | P-2 | 15.12 | ↑ |
| liquid 178 | | | | | | |
| Dispersion | ↑ | ↑ | ↑ | P-3 | ↑ | ↑ |
| liquid 179 | | | | | | |
| Dispersion | ↑ | ↑ | Derivative-2 | P-4 | ↑ | ↑ |
| liquid 180 | | | | | | |

TABLE 9

| | Pigment | | | Dispersant | | |
|---|---|---|---|---|---|---|
| | G | Y | | | Parts by | Solvent |
| | pigment | pigment | Dispersant | Type | mass | Type |
| Dispersion | ↑ | ↑ | Derivative-3 | P-1 | ↑ | ↑ |
| liquid 181 | | | | | | |
| Dispersion | ↑ | ↑ | Derivative-4 | ↑ | ↑ | ↑ |
| liquid 182 | | | | | | |
| Dispersion | ↑ | ↑ | Derivative-1 | ↑ | ↑ | PGME |
| liquid 183 | | | | | | |
| Dispersion | Pc-76 | ↑ | ↑ | ↑ | ↑ | PGMEA |
| liquid 184 | | | | | | |
| Dispersion | Pc-77 | ↑ | ↑ | ↑ | ↑ | ↑ |
| liquid 185 | | | | | | |
| Dispersion | ↑ | PY-139 | ↑ | ↑ | ↑ | ↑ |
| liquid 186 | | | | | | |
| Dispersion | ↑ | PY-150 | ↑ | ↑ | ↑ | ↑ |
| liquid 187 | | | | | | |
| Dispersion | ↑ | PY-185 | ↑ | ↑ | 11.00 | ↑ |
| liquid 188 | | | | | | |
| Dispersion | ↑ | ↑ | ↑ | P-2 | 15.12 | ↑ |
| liquid 189 | | | | | | |
| Dispersion | ↑ | ↑ | ↑ | P-3 | ↑ | ↑ |
| liquid 190 | | | | | | |
| Dispersion | ↑ | ↑ | Derivative-2 | P-4 | ↑ | ↑ |
| liquid 191 | | | | | | |
| Dispersion | ↑ | ↑ | Derivative-3 | P-1 | ↑ | ↑ |
| liquid 192 | | | | | | |
| Dispersion | ↑ | ↑ | Derivative-4 | ↑ | ↑ | ↑ |
| liquid 193 | | | | | | |
| Dispersion | ↑ | ↑ | Derivative-1 | ↑ | ↑ | PGME |
| liquid 194 | | | | | | |
| Dispersion | Pc-78 | ↑ | ↑ | ↑ | ↑ | PGMEA |
| liquid 195 | | | | | | |
| Dispersion | Pc-79 | ↑ | ↑ | ↑ | ↑ | ↑ |
| liquid 196 | | | | | | |
| Dispersion | Pc-80 | ↑ | ↑ | ↑ | ↑ | ↑ |
| liquid 197 | | | | | | |
| Dispersion | Pc-81 | ↑ | ↑ | ↑ | ↑ | ↑ |
| liquid 198 | | | | | | |
| Dispersion | Pc-82 | ↑ | ↑ | ↑ | ↑ | ↑ |
| liquid 199 | | | | | | |
| Dispersion | Pc-83 | ↑ | ↑ | ↑ | ↑ | ↑ |
| liquid 200 | | | | | | |
| Dispersion | Pc-84 | ↑ | ↑ | ↑ | ↑ | ↑ |
| liquid 201 | | | | | | |
| Dispersion | Pc-85 | ↑ | ↑ | ↑ | ↑ | ↑ |
| liquid 202 | | | | | | |
| Dispersion | Pc-86 | ↑ | ↑ | ↑ | ↑ | ↑ |
| liquid 203 | | | | | | |
| Dispersion | Pc-87 | ↑ | ↑ | ↑ | ↑ | ↑ |
| liquid 204 | | | | | | |
| Dispersion | Pc-88 | ↑ | ↑ | ↑ | ↑ | ↑ |
| liquid 205 | | | | | | |
| Dispersion | Pc-89 | ↑ | ↑ | ↑ | ↑ | ↑ |
| liquid 206 | | | | | | |
| Dispersion | Pc-90 | ↑ | ↑ | ↑ | ↑ | ↑ |
| liquid 207 | | | | | | |
| Dispersion | Pc-91 | ↑ | ↑ | ↑ | ↑ | ↑ |
| liquid 208 | | | | | | |
| Dispersion | Pc-92 | ↑ | ↑ | ↑ | ↑ | ↑ |
| liquid 209 | | | | | | |
| Dispersion | Pc-93 | ↑ | ↑ | ↑ | ↑ | ↑ |
| liquid 210 | | | | | | |
| Dispersion | Pc-94 | ↑ | ↑ | ↑ | ↑ | ↑ |
| liquid 211 | | | | | | |
| Dispersion | Pc-95 | ↑ | ↑ | ↑ | ↑ | ↑ |
| liquid 212 | | | | | | |
| Dispersion | Pc-96 | ↑ | ↑ | ↑ | ↑ | ↑ |
| liquid 213 | | | | | | |
| Dispersion | Pc-97 | ↑ | ↑ | ↑ | ↑ | ↑ |
| liquid 214 | | | | | | |
| Dispersion | Pc-98 | ↑ | ↑ | ↑ | ↑ | ↑ |
| liquid 215 | | | | | | |
| Dispersion | Pc-99 | ↑ | ↑ | ↑ | ↑ | ↑ |
| liquid 216 | | | | | | |
| Dispersion | Pc-100 | PY-185 | Derivative-1 | P-1 | 15.12 | PGMEA |
| liquid 217 | | | | | | |
| Dispersion | Pc-101 | ↑ | ↑ | ↑ | ↑ | ↑ |
| liquid 218 | | | | | | |
| Dispersion | Pc-102 | ↑ | ↑ | ↑ | ↑ | ↑ |
| liquid 219 | | | | | | |
| Dispersion | Pc-103 | ↑ | ↑ | ↑ | ↑ | ↑ |
| liquid 220 | | | | | | |
| Dispersion | Pc-104 | ↑ | ↑ | ↑ | ↑ | ↑ |
| liquid 221 | | | | | | |
| Dispersion | Pc-105 | ↑ | ↑ | ↑ | ↑ | ↑ |
| liquid 222 | | | | | | |
| Dispersion | Pc-106 | ↑ | ↑ | ↑ | ↑ | ↑ |
| liquid 223 | | | | | | |
| Dispersion | Pc-107 | ↑ | ↑ | ↑ | ↑ | ↑ |
| liquid 224 | | | | | | |
| Dispersion | Pc-108 | ↑ | ↑ | ↑ | ↑ | ↑ |
| liquid 225 | | | | | | |
| Dispersion | Pc-109 | PY-185 | Derivative-1 | P-1 | 15.12 | PGMEA |
| liquid 226 | | | | | | |
| Dispersion | Pc-110 | ↑ | ↑ | ↑ | ↑ | ↑ |
| liquid 227 | | | | | | |
| Dispersion | Pc-111 | ↑ | ↑ | ↑ | ↑ | ↑ |
| liquid 228 | | | | | | |
| Dispersion | Pc-112 | ↑ | ↑ | ↑ | ↑ | ↑ |
| liquid 229 | | | | | | |
| Dispersion | Pc-113 | ↑ | ↑ | ↑ | ↑ | ↑ |
| liquid 230 | | | | | | |
| Dispersion | Pc-114 | ↑ | ↑ | ↑ | ↑ | ↑ |
| liquid 231 | | | | | | |
| Dispersion | Pc-115 | ↑ | ↑ | ↑ | ↑ | ↑ |
| liquid 232 | | | | | | |
| Dispersion | Pc-116 | ↑ | ↑ | ↑ | ↑ | ↑ |
| liquid 233 | | | | | | |
| Dispersion | Pc-117 | ↑ | ↑ | ↑ | ↑ | ↑ |
| liquid 234 | | | | | | |
| Dispersion | Pc-118 | ↑ | ↑ | ↑ | ↑ | ↑ |
| liquid 235 | | | | | | |
| Dispersion | Pc-119 | ↑ | ↑ | ↑ | ↑ | ↑ |
| liquid 236 | | | | | | |
| Dispersion | Pc-120 | ↑ | ↑ | ↑ | ↑ | ↑ |
| liquid 237 | | | | | | |
| Dispersion | Pc-121 | ↑ | ↑ | ↑ | ↑ | ↑ |
| liquid 238 | | | | | | |
| Dispersion | Compar- | ↑ | ↑ | ↑ | ↑ | ↑ |
| liquid 239 | ative | | | | | |
| | Pc-1 | | | | | |
| Dispersion | Compar- | ↑ | ↑ | ↑ | ↑ | ↑ |
| liquid 240 | ative | | | | | |
| | Pc-2 | | | | | |
| Dispersion | Compar- | ↑ | ↑ | ↑ | ↑ | ↑ |
| liquid 241 | ative | | | | | |
| | Pc-3 | | | | | |
| Dispersion | Compar- | ↑ | ↑ | ↑ | ↑ | ↑ |
| liquid 242 | ative | | | | | |
| | Pc-4 | | | | | |
| Dispersion | Compar- | ↑ | ↑ | ↑ | ↑ | ↑ |
| liquid 243 | ative | | | | | |
| | Pc-5 | | | | | |
| Dispersion | PG-36 | ↑ | ↑ | ↑ | ↑ | ↑ |
| liquid 244 | | | | | | |
| Dispersion | PG-58 | ↑ | ↑ | ↑ | ↑ | ↑ |
| liquid 245 | | | | | | |

The details of the abbreviations in the tables which was given above are as follows.

[G Pigment]

Comparative Pc-1 to Comparative Pc-5 are compounds having the structures shown below. In addition, PG-36 represents C.I. Pigment Green 36, and PG-58 represents C.I. Pigment Green 58.

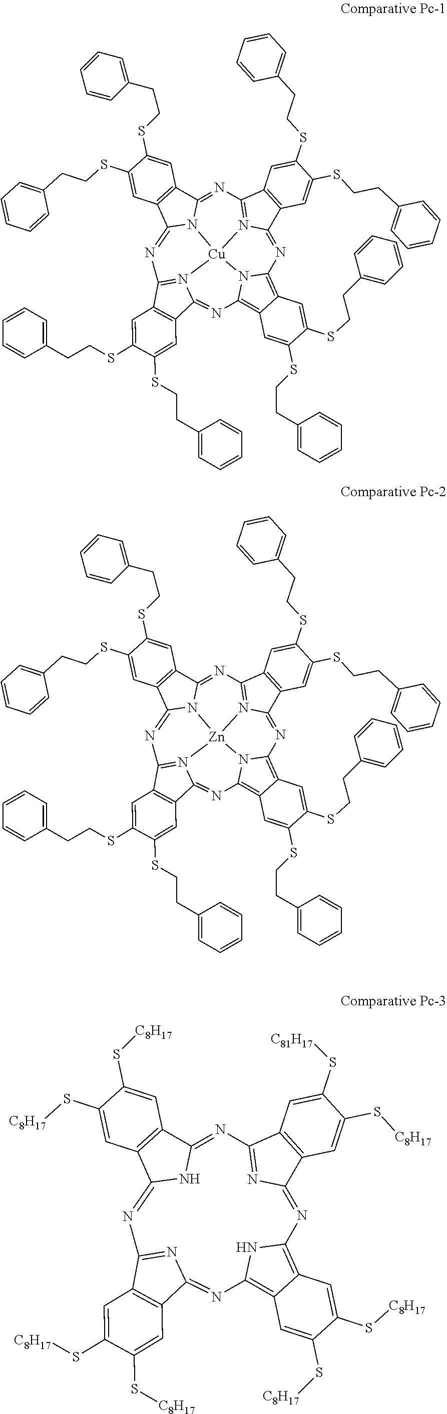

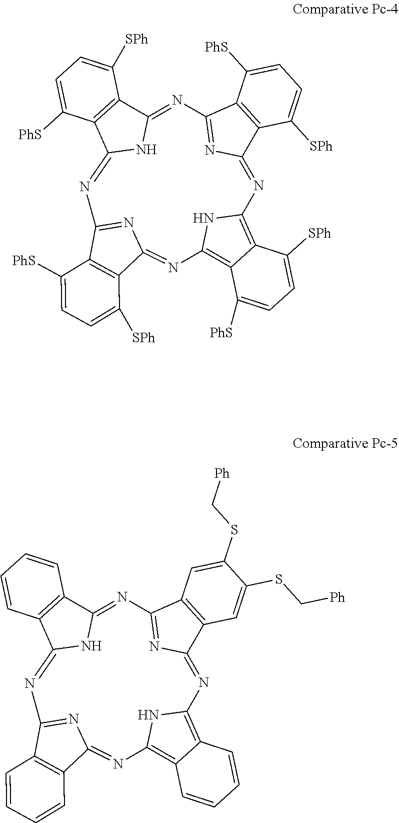

[Derivative (Pigment Derivative)]

Derivative-1 to Derivative-4 described in the column of “Derivative” (pigment derivative) are compounds having the structures shown below.

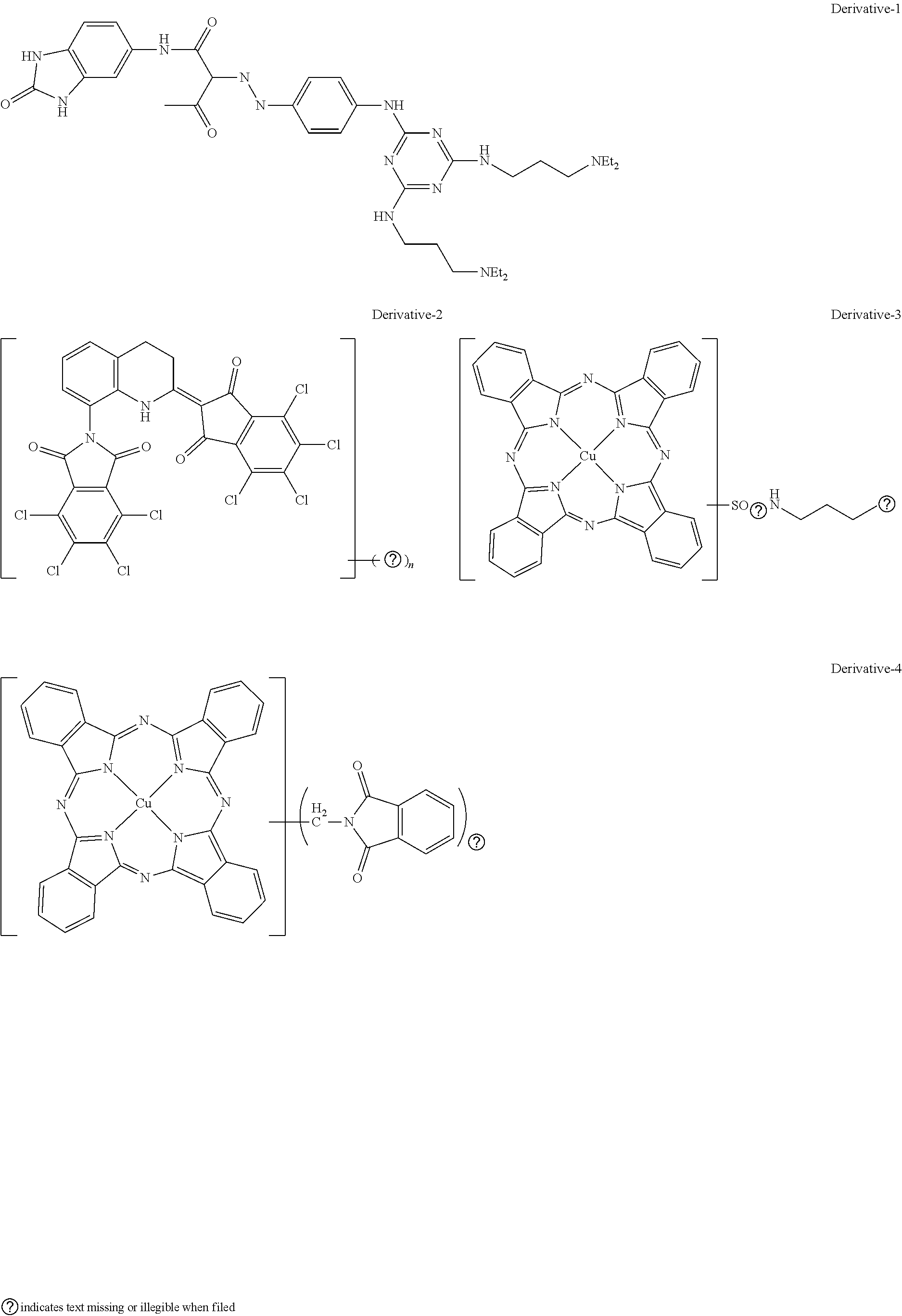

[Dispersant]

P-1: a 30% by mass propylene glycol monomethyl ether acetate (PGMEA) solution of a resin having the structure shown below. The numerical value attached to the main chain is a molar ratio, and the numerical value attached to the side chain is the number of repeating units. Mw=20,000.

P-2: a 30% by mass PGMEA solution of a resin having the structure shown below. The numerical value attached to the main chain is a molar ratio, and the numerical value attached to the side chain is the number of repeating units. Mw=18,000.

P-3: a 30% by mass PGMEA solution of a resin having the structure shown below. The numerical value attached to the main chain is a molar ratio, and the numerical value attached to the side chain is the number of repeating units. Mw=22,000.

P-4: a 20% by mass PGMEA solution of a resin having the structure shown below. The numerical value attached to the main chain is a molar ratio, and the numerical value attached to the side chain is the number of repeating units. Mw=22,900.

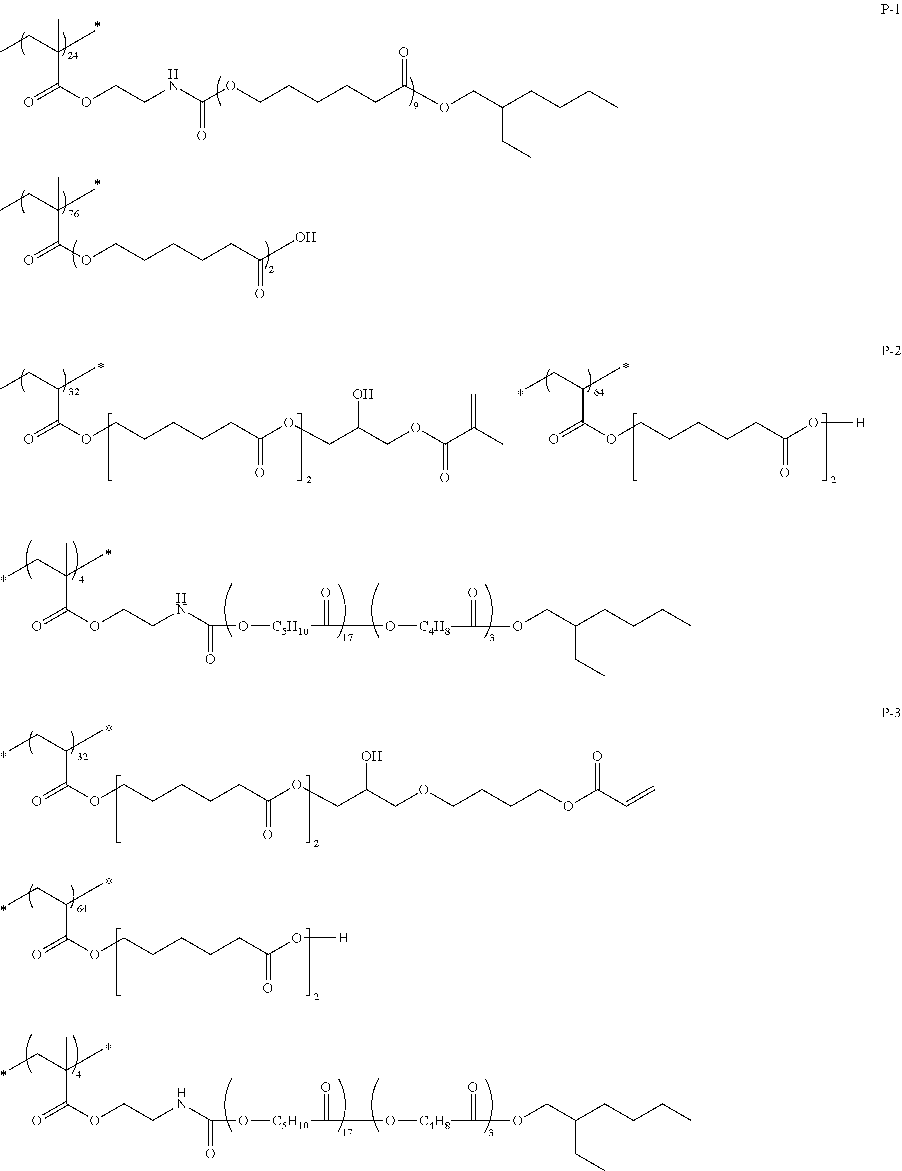

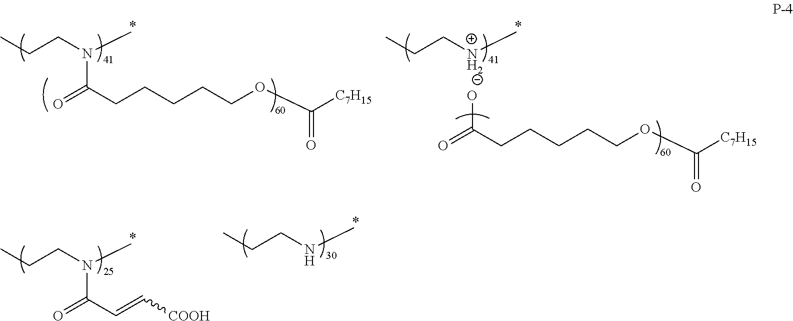

[Solvent]

PGMEA: propylene glycol monomethyl ether acetate

PGME: propylene glycol monomethyl ether

### Example 1 to Example 238, and Comparative Example 1 to Comparative Example 7

<Preparation 1 of Composition>

A composition was prepared by mixing raw materials having the compositions shown in Table 10 below.

TABLE 10

| | Parts by mass |
|---|---|
| Dispersion liquid | 39.4 |
| (dispersion liquid listed in Table 11 to Table 13) | |
| Resin D1 | 0.58 |
| Polymerizable compound E1 | 0.54 |
| Photopolymerization initiator F3 | 0.33 |
| Surfactant H1 | 4.17 |
| p-Methoxyphenol | 0.0006 |
| PGMEA | 7.66 |

The details of the abbreviations in the tables which was given above are as follows.

[Resin (Alkali-Soluble Resin)]

Resin D1 is a compound having the structure shown below. The numerical value attached to the main chain is a molar ratio. Mw=11,000.

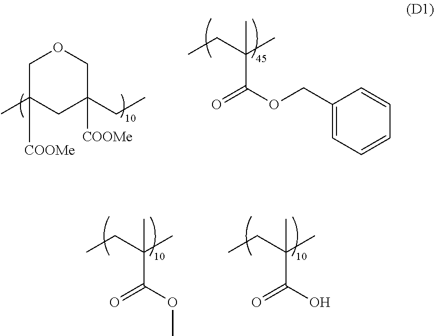

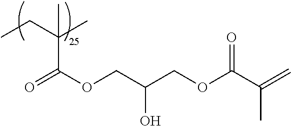

[Polymerizable Compound]
Polymerizable compound E1: KAYARAD DPHA (manufactured by Nippon Kayaku Co., Ltd.), a compound having the structure shown below.

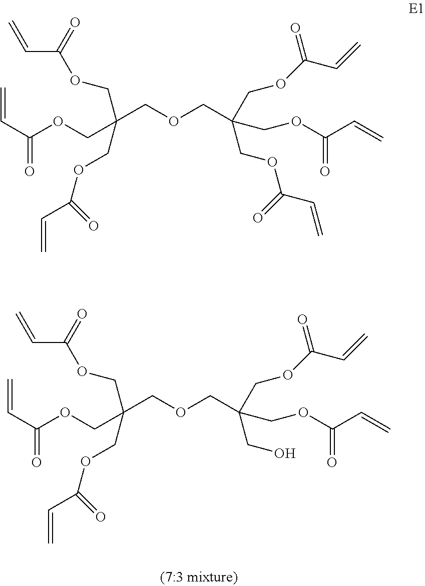 [SMILES: C=CC(=O)OCC(COCC(COC(=O)C=C)(COC(=O)C=C)COC(=O)C=C)(COC(=O)C=C)COC(=O)C=C ; C=CC(=O)OCC(CO)(COCC(COC(=O)C=C)(COC(=O)C=C)COC(=O)C=C)COC(=O)C=C]

[Polymerization Initiator]
Photopolymerization initiator F3: a compound having the structure shown below.

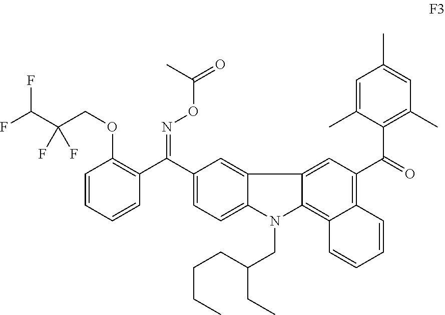 [SMILES: CCCCC(CC)Cn1c2ccc(/C(=N\OC(C)=O)c3ccccc3OCC(F)(F)C(F)F)cc2c2cc(C(=O)c3c(C)cc(C)cc3C)c3ccccc3c21]

[Surfactant]
Surfactant H1: a 1% by mass PGMEA solution of the following mixture (Mw=14000). In the following formula, % indicating the percentage of repeating units is mol %.

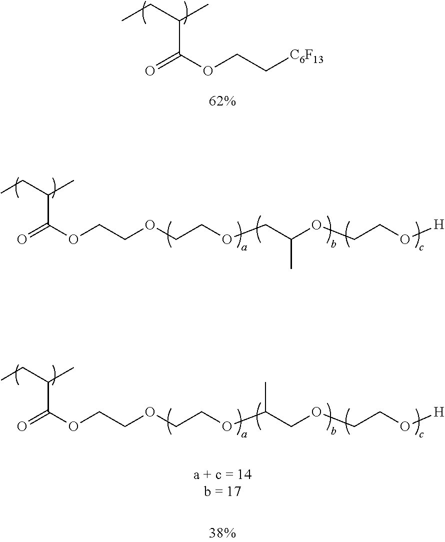

<Evaluation of Storage Stability>

After measuring the viscosity of the composition obtained above with a “RE-85L” (manufactured by Toki Sangyo Co., Ltd.), the dispersion liquid thereof was allowed to stand at 45° C. for 3 days and then the viscosity was measured again. The stability was evaluated from the viscosity difference (ΔVis) before and after allowing to stand, according to the following evaluation standards. It can be said that the smaller the numerical value of the viscosity difference (ΔVis), the better the dispersion stability. The viscosity of the dispersion liquid was measured with the temperature adjusted to 25° C. The evaluation standards are as follows, and the evaluation results are shown in the tables which will be given later.

[Evaluation Standards]

A: ΔVis is 0.5 Pa·s or less

B: ΔVis is greater than 0.5 Pa·s and 1.0 Pa·s or less

C: ΔVis is greater than 1.0 Pa·s and 2.0 Pa·s or less

D: ΔVis is greater than 2.0 Pa s

<Evaluation of Spectral Characteristics>

Each composition was spin-coated on a glass substrate such that the film thickness after post-baking was 0.6 μm, dried on a hot plate at 100° C. for 120 seconds, and then a heat treatment (post-baking) was further carried out for 300 seconds using a hot plate at 200° C. to form a cured film. Using a UV-visible-near infrared spectrophotometer U-4100 (manufactured by Hitachi High-Technologies Corporation) (reference: glass substrate), the glass substrate on which the cured film was formed was measured for the transmittance of light in a wavelength range of 300 nm to 1000 nm. The spectral evaluation was carried out from the obtained transmittance ratio between the transmittance at a wavelength of 570 nm and the transmittance at a wavelength of 650 nm (T=(transmittance at wavelength of 570 nm)/(transmittance at wavelength of 650 nm)×100). In a case where the edge sharpness of the absorption spectrum is satisfactory, since the transmittance at a wavelength of 650 nm is low and the transmittance at a wavelength of 570 nm is high, the larger the transmittance ratio between the transmittance at a wavelength of 570 nm and the transmittance at a wavelength of 650 nm, the better the spectral characteristics. The evaluation standards are as follows, and the evaluation results are shown in the tables which will be given later.

[Evaluation Standards]

A: 16≤T

B: 14≤T<16

C: 12≤T<14

D: 10≤T<12

E: T<10

<Light Resistance>

The cured film obtained in the evaluation of spectral characteristics was irradiated with 20,000 lux light for 20 hours through an ultraviolet cut filter with a Xe lamp to carry out a light resistance test, and the ΔEab value of the color difference before and after the light resistance test was measured with a colorimeter MCPD-1000 (manufactured by Otsuka Electronics Co., Ltd.). The evaluation standards are as follows, and the evaluation results are shown in the tables which will be given later.

[Evaluation Standards]

A: ΔEab value<2.5

B: 2.5≤ΔEab value<5

C: 5≤ΔEab value<10

D: 10≤ΔEab value

<Solubility>

In all Examples, the solubility of the specific compound in the composition, measured by the method described above, was 0.1% by mass or less.

Table 11

| | Dispersion | Storage | Spectral | Light |
|---|---|---|---|---|
| Examples | liquid | stability | characteristics | resistance |
| 1 | 1 | A | B | A |
| 2 | 2 | A | A | A |
| 3 | 3 | A | B | B |
| 4 | 4 | A | B | B |
| 5 | 5 | A | B | B |
| 6 | 6 | A | B | A |
| 7 | 7 | A | B | B |
| 8 | 8 | A | B | B |
| 9 | 9 | A | A | A |
| 10 | 10 | B | A | A |
| 11 | 11 | B | A | A |
| 12 | 12 | B | A | A |
| 13 | 13 | B | A | A |
| 14 | 14 | B | A | A |
| 15 | 15 | A | A | A |
| 16 | 16 | A | A | A |
| 17 | 17 | A | A | A |
| 18 | 18 | B | A | A |
| 19 | 19 | A | A | A |
| 20 | 20 | B | A | A |
| 21 | 21 | B | A | A |
| 22 | 22 | B | A | A |
| 23 | 23 | B | A | A |
| 24 | 24 | B | A | A |
| 25 | 25 | B | A | A |
| 26 | 26 | A | A | A |
| 27 | 27 | A | A | A |
| 28 | 28 | A | A | A |
| 29 | 29 | B | A | A |
| 30 | 30 | A | B | A |
| 31 | 31 | A | A | A |
| 32 | 32 | A | A | A |
| 33 | 33 | A | A | A |
| 34 | 34 | A | A | A |
| 35 | 35 | A | B | B |
| 36 | 36 | A | A | A |
| 37 | 37 | A | B | B |
| 38 | 38 | A | B | A |
| 39 | 39 | A | B | A |
| 40 | 40 | A | B | B |
| 41 | 41 | A | B | B |
| 42 | 42 | A | B | B |
| 43 | 43 | A | B | B |
| 44 | 44 | A | B | B |
| 45 | 45 | A | B | B |
| 46 | 46 | A | B | A |
| 47 | 47 | A | A | A |
| 48 | 48 | B | A | A |
| 49 | 49 | B | A | A |
| 50 | 50 | B | A | A |
| 51 | 51 | B | A | A |
| 52 | 52 | B | A | A |
| 53 | 53 | A | A | A |
| 54 | 54 | A | A | A |
| 55 | 55 | A | A | A |
| 56 | 56 | B | A | A |
| 57 | 57 | A | B | B |
| 58 | 58 | A | B | B |
| 59 | 59 | A | B | B |
| 60 | 60 | A | B | A |
| 61 | 61 | A | B | B |
| 62 | 62 | A | B | B |
| 63 | 63 | A | A | A |
| 64 | 64 | B | A | A |
| 65 | 65 | B | A | A |
| 66 | 66 | B | A | A |
| 67 | 67 | B | A | A |
| 68 | 68 | B | A | A |
| 69 | 69 | A | A | A |
| 70 | 70 | A | A | A |
| 71 | 71 | A | A | A |
| 72 | 72 | B | A | A |
| 73 | 73 | A | A | A |
| 74 | 74 | B | A | A |
| 75 | 75 | B | A | A |
| 76 | 76 | B | A | A |
| 77 | 77 | B | A | A |
| 78 | 78 | B | A | A |
| 79 | 79 | A | A | A |
| 80 | 80 | A | A | A |
| 81 | 81 | A | A | A |
| 82 | 82 | B | A | A |
| 83 | 83 | A | A | A |
| 84 | 84 | A | B | A |
| 85 | 85 | A | A | A |
| 86 | 86 | A | A | A |
| 87 | 87 | A | A | A |
| 88 | 88 | A | A | A |
| 89 | 89 | A | B | B |
| 90 | 90 | A | A | A |
| 91 | 91 | A | B | B |
| 92 | 92 | A | B | A |
| 93 | 93 | A | B | A |
| 94 | 94 | A | B | B |
| 95 | 95 | A | B | B |
| 96 | 96 | A | B | B |

TABLE 12

| | Dispersion | Storage | Spectral | Light |
|---|---|---|---|---|
| Examples | liquid | stability | characteristics | resistance |
| 97 | 97 | A | B | B |
| 98 | 98 | A | B | B |
| 99 | 99 | A | B | B |
| 100 | 100 | A | B | B |
| 101 | 101 | A | B | A |
| 102 | 102 | B | A | A |
| 103 | 103 | B | A | A |
| 104 | 104 | B | A | A |
| 105 | 105 | B | A | A |
| 106 | 106 | B | A | A |
| 107 | 107 | A | A | A |
| 108 | 108 | A | A | A |
| 109 | 109 | A | A | A |
| 110 | 110 | B | A | A |
| 111 | 111 | A | A | A |
| 112 | 112 | B | A | A |
| 113 | 113 | B | A | A |
| 114 | 114 | B | A | A |
| 115 | 115 | B | A | A |
| 116 | 116 | B | A | A |
| 117 | 117 | A | A | A |
| 118 | 118 | A | A | A |
| 119 | 119 | A | A | A |
| 120 | 120 | B | A | A |
| 121 | 121 | A | A | A |
| 122 | 122 | A | A | A |
| 123 | 123 | A | A | A |
| 124 | 124 | A | A | A |
| 125 | 125 | A | B | A |
| 126 | 126 | A | A | A |
| 127 | 127 | A | A | A |
| 128 | 128 | A | A | A |
| 129 | 129 | B | A | A |
| 130 | 130 | B | A | A |
| 131 | 131 | A | A | A |
| 132 | 132 | A | A | A |
| 133 | 133 | A | A | A |
| 134 | 134 | A | A | A |
| 135 | 135 | B | A | A |
| 136 | 136 | A | A | A |
| 137 | 137 | B | A | A |
| 138 | 138 | B | A | A |
| 139 | 139 | B | A | A |
| 140 | 140 | B | A | A |
| 141 | 141 | B | A | A |
| 142 | 142 | A | A | A |
| 143 | 143 | A | A | A |
| 144 | 144 | A | A | A |
| 145 | 145 | B | A | A |
| 146 | 146 | A | A | A |
| 147 | 147 | A | B | A |
| 148 | 148 | A | A | B |
| 149 | 149 | B | A | B |
| 150 | 150 | B | A | B |
| 151 | 151 | B | A | B |
| 152 | 152 | B | A | B |
| 153 | 153 | B | A | B |
| 154 | 154 | A | A | B |
| 155 | 155 | A | A | B |
| 156 | 156 | A | A | B |
| 157 | 157 | B | A | B |
| 158 | 158 | A | B | B |
| 159 | 159 | A | B | B |
| 160 | 160 | A | B | B |
| 161 | 161 | A | B | A |
| 162 | 162 | A | B | A |
| 163 | 163 | A | B | A |
| 164 | 164 | A | A | B |
| 165 | 165 | A | A | B |
| 166 | 166 | A | A | B |
| 167 | 167 | B | A | B |
| 168 | 168 | B | A | B |
| 169 | 169 | B | A | B |
| 170 | 170 | A | A | B |
| 171 | 171 | A | A | B |
| 172 | 172 | A | A | B |
| 173 | 173 | B | A | B |
| 174 | 174 | A | A | B |
| 175 | 175 | B | A | B |
| 176 | 176 | B | A | B |
| 177 | 177 | B | A | B |
| 178 | 178 | B | A | B |
| 179 | 179 | B | A | B |
| 180 | 180 | A | A | B |
| 181 | 181 | A | A | B |
| 182 | 182 | A | A | B |
| 183 | 183 | B | A | B |
| 184 | 184 | A | A | B |
| 185 | 185 | A | A | A |
| 186 | 186 | B | A | B |
| 187 | 187 | B | A | B |
| 188 | 188 | B | A | A |
| 189 | 189 | B | A | B |
| 190 | 190 | B | A | B |
| 191 | 191 | A | A | B |
| 192 | 192 | A | A | B |

TABLE 13

| | Dispersion | Storage | Spectral | Light |
|---|---|---|---|---|
| | liquid | stability | characteristics | resistance |
| Examples | | | | |
| 193 | 193 | A | A | B |
| 194 | 194 | A | A | B |
| 195 | 195 | B | B | B |
| 196 | 196 | A | B | B |
| 197 | 197 | A | A | B |
| 198 | 198 | A | B | B |
| 199 | 199 | A | A | B |
| 200 | 200 | A | A | B |
| 201 | 201 | A | B | B |
| 202 | 202 | A | B | B |
| 203 | 203 | A | B | B |
| 204 | 204 | A | B | B |
| 205 | 205 | A | B | B |
| 206 | 206 | A | B | B |
| 207 | 207 | A | C | B |
| 208 | 208 | A | C | B |
| 209 | 209 | A | C | B |
| 210 | 210 | A | C | B |
| 211 | 211 | A | C | B |
| 212 | 212 | A | C | B |
| 213 | 213 | A | C | B |
| 214 | 214 | A | C | B |
| 215 | 215 | A | C | B |
| 216 | 216 | A | C | B |
| 217 | 217 | A | C | B |
| 218 | 218 | A | C | B |
| 219 | 219 | A | C | B |
| 220 | 220 | A | C | B |
| 221 | 221 | A | C | B |
| 222 | 222 | A | C | B |
| 223 | 223 | A | C | B |
| 224 | 224 | A | C | B |
| 225 | 225 | A | C | B |
| 226 | 226 | A | C | B |
| 227 | 227 | A | C | B |
| 228 | 228 | A | C | B |
| 229 | 229 | A | C | B |
| 230 | 230 | A | C | B |
| 231 | 231 | B | C | C |
| 232 | 232 | A | C | C |
| 233 | 233 | A | C | C |
| 234 | 234 | A | C | C |
| 235 | 235 | A | C | B |
| 236 | 236 | A | C | B |
| 237 | 237 | B | C | C |
| 238 | 238 | B | C | B |
| Comparative | | | | |
| Examples | | | | |
| 1 | 239 | C | D | C |
| 2 | 240 | B | D | D |
| 3 | 241 | B | E | D |
| 4 | 242 | B | E | C |
| 5 | 243 | C | E | C |
| 6 | 244 | C | E | C |
| 7 | 245 | C | D | D |

### Example 239 to Example 254

<Preparation of Composition>

A composition was prepared by mixing the raw materials having the compositions shown in Table 14 below and evaluated in the same manner as in Example 1. As a result, the same results as in Example 9 (composition using the dispersant 9) were obtained.

In Table 15 below, the description of “T” indicates that a corresponding compound or an amount thereof used is the same as the compound or the amount thereof used in the column immediately above.

TABLE 14

| | Parts by mass |
|---|---|
| Dispersion liquid (dispersion liquid | Addition amount listed in Table 15 |
| listed in Table 15) | |
| Resin listed in Table 15 | Addition amount listed in Table 15 |
| Polymerizable compound listed in | Addition amount listed in Table 15 |
| Table 15 | |
| Photopolymerization initiator listed in | Addition amount listed in Table 15 |
| Table 15 | |
| Surfactant H1 | 4.17 |
| p-Methoxyphenol | 0.0006 |
| Organic solvent listed in Table 15 | Addition amount listed in Table 15 |

TABLE 15

| | | | | | Polymerizable | | Photopolymerization | | | |
|---|---|---|---|---|---|---|---|---|---|---|
| | Dispersion liquid | | Resin | | compound | | initiator | | Organic solvent | |
| | | Parts by | | Parts by | | Parts by | | Parts by | | Parts by |
| Examples | Type | mass | Type | mass | Type | mass | Type | mass | Type | mass |
| 239 | 9 | 19.7 | D1 | 0.58 | E1 | 0.54 | F3 | 0.33 | PGMEA | 7.66 |
| | 101 | 19.7 | | | | | | | | |
| 240 | 9 | 29.4 | ↑ | ↑ | ↑ | ↑ | ↑ | ↑ | ↑ | ↑ |
| | 243 | 10.0 | | | | | | | | |
| 241 | 9 | 39.4 | ↑ | 0.85 | ↑ | 0.27 | ↑ | ↑ | ↑ | ↑ |
| 242 | ↑ | ↑ | D2 | 0.58 | ↑ | 0.54 | ↑ | ↑ | ↑ | ↑ |
| 243 | ↑ | ↑ | D1 | 0.29 | ↑ | ↑ | ↑ | ↑ | ↑ | ↑ |
| | | | D2 | 0.29 | | | | | | |
| 244 | ↑ | ↑ | D1 | 0.58 | E2 | ↑ | ↑ | ↑ | ↑ | ↑ |
| 245 | ↑ | ↑ | ↑ | ↑ | E3 | ↑ | ↑ | ↑ | ↑ | ↑ |
| 246 | ↑ | ↑ | ↑ | ↑ | E4 | ↑ | ↑ | ↑ | ↑ | ↑ |
| 247 | ↑ | ↑ | ↑ | ↑ | E5 | ↑ | ↑ | ↑ | ↑ | ↑ |
| 248 | ↑ | ↑ | ↑ | ↑ | E1 | 0.27 | ↑ | ↑ | ↑ | ↑ |
| | | | | | E2 | 0.27 | | | | |
| 249 | ↑ | ↑ | ↑ | ↑ | E1 | 0.54 | F1 | ↑ | ↑ | ↑ |
| 250 | ↑ | ↑ | ↑ | ↑ | ↑ | ↑ | F2 | ↑ | ↑ | ↑ |
| 251 | ↑ | ↑ | ↑ | ↑ | ↑ | ↑ | F4 | ↑ | ↑ | ↑ |
| 252 | ↑ | ↑ | ↑ | ↑ | ↑ | ↑ | F5 | ↑ | ↑ | ↑ |
| 253 | ↑ | ↑ | ↑ | ↑ | ↑ | ↑ | F3 | 0.22 | ↑ | ↑ |
| | | | | | | | F4 | 0.11 | | |
| 254 | ↑ | ↑ | ↑ | ↑ | ↑ | ↑ | ↑ | ↑ | PGMEA | 3.83 |
| | | | | | | | | | Cyclohexanone | 3.83 |

Details of the compounds described by the abbreviations in Table 15 above other than those described above are as follows.

[Resin (Alkali-Soluble Resin)]

Resin D2 is a compound having the structure shown below. The numerical value attached to the main chain is a molar ratio. Mw=14000.

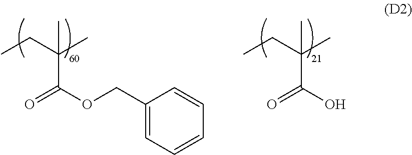

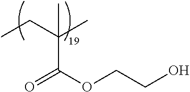

[Polymerizable Compound]
E2: ARONIX M-305 (manufactured by Toagosei Co., Ltd.), a compound having the structure shown below.
E3: NK ESTER A-TMMT (manufactured by Shin-Nakamura Chemical Co., Ltd.), a compound having the structure shown below.
E4: KAYARAD RP-1040 (manufactured by Nippon Kayaku Co., Ltd.), a compound having the structure shown below.
E5: ARONIX TO-2349 (manufactured by Toagosei Co., Ltd.)

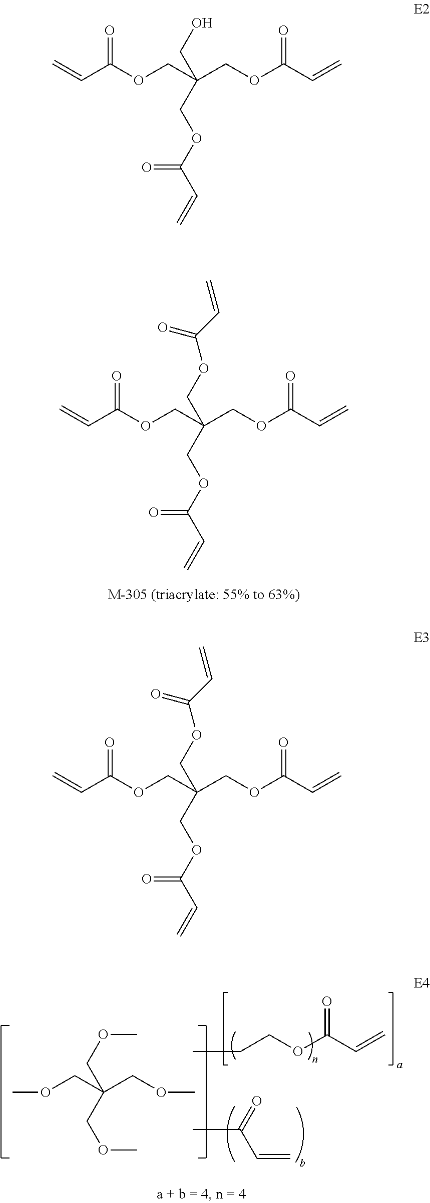

[Polymerization Initiator]
Photopolymerization initiator F1: IRGACURE-OXE01 (manufactured by BASF SE), a compound having the structure shown below.
Photopolymerization initiator F2: IRGACURE-OXE02 (manufactured by BASF SE), a compound having the structure shown below.
Photopolymerization initiator F4: IRGACURE 369 (manufactured by BASF SE), a compound having the structure shown below.
Photopolymerization initiator F5: a compound having the structure shown below.

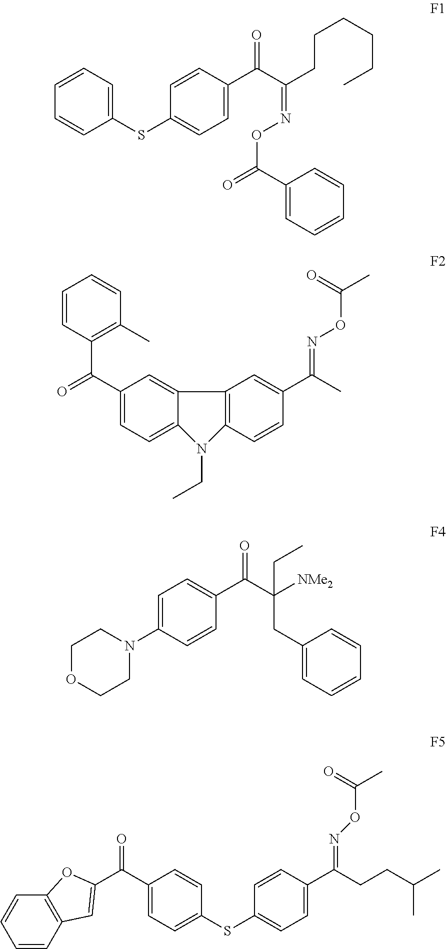

### Example 255

Evaluation was carried out in the same manner as in Example 19, except that the following dispersion liquid 246 was used. The same results as in Example 19 were obtained except that the evaluation result of storage stability was B.

<Dispersion Liquid 246>

Specific compound Pc-10 (10.36 parts by mass), Derivative-1 (1.03 parts by mass), Dispersant P-1, and a solvent (PGMEA, 71.92 parts by mass) were mixed, 230 parts by mass of zirconia beads having a diameter of 0.3 mm were added thereto, a dispersion treatment was carried out for 5 hours using a paint shaker, and the beads were separated by filtration to produce a dispersion liquid.

### Example 256

Evaluation was carried out in the same manner as in Example 19, except that the following dispersion liquid 247 was used. The same results as in Example 19 were obtained except that the storage stability was rated as B.

<Dispersion Liquid 247>

Specific compound Pc-10 (8.29 parts by mass, Y pigment (yellow pigment) PY-185 (2.07 parts by mass), Dispersant P-1, and a solvent (PGMEA, 71.92 parts by mass) were mixed, 230 parts by mass of zirconia beads having a diameter of 0.3 mm were added thereto, a dispersion treatment was carried out for 5 hours using a paint shaker, and the beads were separated by filtration to produce a dispersion liquid. The numerical values in the table which will be given later are parts by mass.

From the above Examples, it can be seen that the cured product of the composition according to the present disclosure has excellent spectral characteristics. Therefore, the composition according to the present disclosure is considered to be suitable as a composition used for producing a color filter.

In addition, it can also be seen that the composition according to the present example is excellent in storage stability and light resistance.

### Example 301 to Example 556

Green composition was applied onto a silicon wafer by spin coating such that the film thickness after film formation was 1.0 μm. This was followed by heating at 100° C. for 2 minutes using a hot plate. Then, the exposure was carried out at 1,000 mJ/cm² through a mask having a dot pattern of 2 μm square using an i-line stepper exposure apparatus FPA-3000i5+(manufactured by Canon Inc.). Next, the puddle development was carried out at 23° C. for 60 seconds using a 0.3% by mass aqueous solution of tetramethylammonium hydroxide (TMAH). This was followed by rinsing with a spin shower and then further washing with pure water. Next, the Red composition was patterned by heating at 200° C. for 5 minutes using a hot plate. Similarly, the Red composition and the Blue composition were sequentially patterned to form red, green, and blue colored patterns (Bayer patterns).

The compositions prepared in Example 1 to Example 256 were used as the Green composition. Examples in which the solid-state imaging element was formed using the composition prepared in each of Example 1 to Example 256 as the Green composition correspond to Example 301 to Example 556, respectively.

The Red composition and the Blue composition will be described later.

The Bayer pattern is a pattern in which a 2×2 array of color filter elements each having one red (Red) element, two green (Green) elements, and one blue (Blue) element is repeated, as disclosed in U.S. Pat. No. 3,971,065A.

The obtained color filter was incorporated into a solid-state imaging element according to a known method. It was confirmed that the solid-state imaging element had excellent spectral characteristics, high resolution, and excellent color separation even in a case where any of the compositions obtained in Example 1 to Example 256 was used.

That is, a solid-state imaging element having a suitable image recognition ability was obtained by using the composition according to the present disclosure as the Green composition.

The Red composition and the Blue composition used in Example 301 to Example 556 are as follows.

—Red Composition—

The following components were mixed, stirred, and then filtered through a nylon filter (manufactured by Pall Corporation) having a pore size of 0.45 μm to prepare a Red

composition.

Red pigment dispersion liquid: 51.7 parts by mass

Resin 4 (40% by mass PGMEA solution): 0.6 parts by mass

Polymerizable compound 4: 0.6 parts by mass

Photopolymerization initiator 1: 0.3 parts by mass

Surfactant 1: 4.2 parts by mass

PGMEA: 42.6 parts by mass

—Blue Composition—

The following components were mixed, stirred, and then filtered through a nylon filter (manufactured by Pall Corporation) having a pore size of 0.45 μm to prepare a Blue composition.

Blue pigment dispersion liquid: 44.9 parts by mass

Resin 4 (40% by mass PGMEA solution): 2.1 parts by mass

Polymerizable compound 1: 1.5 parts by mass

Polymerizable compound 4: 0.7 parts by mass

Photopolymerization initiator 1: 0.8 parts by mass

Surfactant 1: 4.2 parts by mass

PGMEA: 45.8 parts by mass

The raw materials used for the Red composition, the Green composition, and the Blue composition are as follows.

Red Pigment Dispersion Liquid

A mixed liquid consisting of 9.6 parts by mass of C.I. Pigment Red 254, 4.3 parts by mass of C.I. Pigment Yellow 139, 6.8 parts by mass of a dispersant (Disperbyk-161, manufactured by BYK-Chemie GmbH), and 79.3 parts by mass of PGMEA was mixed and dispersed for 3 hours by a beads mill (zirconia beads having a diameter of 0.3 mm) to prepare a pigment dispersion liquid. Thereafter, a dispersion treatment was further carried out at a flow rate of 500 g/min under a pressure of 2,000 kg/cm², using a high-pressure disperser NANO-3000-10 (manufactured by Nippon BEE Chemical Co., Ltd.) equipped with a pressure reducing mechanism. This dispersion treatment was repeated 10 times to obtain a Red pigment dispersion liquid.

Blue Pigment Dispersion Liquid

A mixed liquid consisting of 9.7 parts by mass of C.I. Pigment Blue 15:6, 2.4 parts by mass of C.I. Pigment Violet 23, 5.5 parts by mass of a dispersant (Disperbyk-161, manufactured by BYK-Chemie GmbH), and 82.4 parts by mass of PGMEA was mixed and dispersed for 3 hours by a beads mill (zirconia beads having a diameter of 0.3 mm) to prepare a pigment dispersion liquid. Thereafter, a dispersion treatment was further carried out at a flow rate of 500 g/min under a pressure of 2,000 kg/cm², using a high-pressure disperser NANO-3000-10 (manufactured by Nippon BEE Chemical Co., Ltd.) equipped with a pressure reducing mechanism. This dispersion treatment was repeated 10 times to obtain a Blue pigment dispersion liquid.
Polymerizable compound 1: KAYARAD DPHA (mixture of dipentaerythritol hexaacrylate and dipentaerythritol pentaacrylate, manufactured by Nippon Kayaku Co., Ltd.)
Polymerizable compound 4: a structure shown below

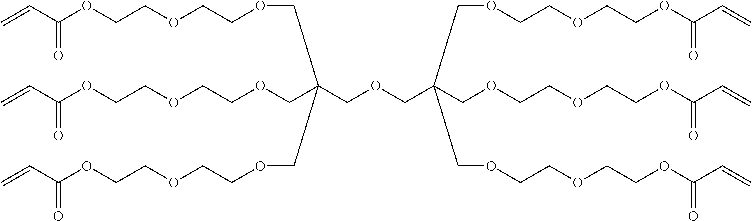 [SMILES: C=CC(=O)OCCOCCOCC(COCCOCCOC(=O)C=C)(COCCOCCOC(=O)C=C)COCC(COCCOCCOC(=O)C=C)(COCCOCCOC(=O)C=C)COCCOCCOC(=O)C=C]

Resin 4: a structure shown below (acid value: 70 mgKOH/g, Mw=11,000, the ratio in each structural unit is a molar ratio)

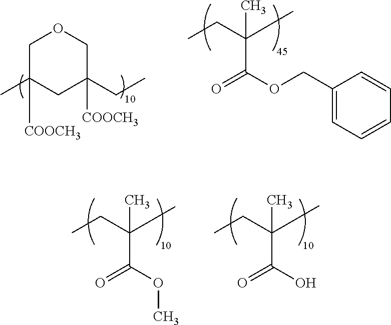

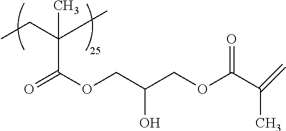

Photopolymerization initiator 1: IRGACURE-OXE01 (1-[4-(phenylthio)]-1,2-octanedione-2-(O-benzoyloxime), manufactured by BASF SE)
Surfactant 1: a 1% by mass PGMEA solution of the following mixture (Mw=14,000). In the following formula, the unit of % (62% and 38%) indicating the percentage of the structural units is % by mass.

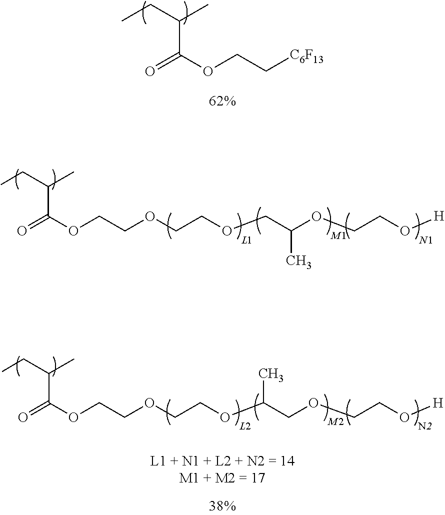

### Example 601

<Formation of Cured Product>

A coloring composition A having the following composition was applied onto an 8-inch silicon wafer substrate by a spin coater so as to form a coating film having a thickness of 0.4 μm, followed by heating at 200° C. for 5 minutes using a hot plate, and then the coating film was cured to form a colored layer (cured product).

TABLE 16

| Coloring composition A | Parts by mass |
|---|---|
| Dispersion liquid 19 | 39.4 |
| Epoxy compound | 1.5 |
| Surfactant | 0.3 |

[Epoxy Compound]

1,2-epoxy-4-(2-oxiranyl)cyclohexane adduct of 2,2-bis(hydroxymethyl)-1-butanol (EHPE3150, Mw: 23000, manufactured by Daicel Corporation)

[Surfactant]

0.2% solution of F-781 (manufactured by DIC Corporation) in cyclohexanone

<Formation of Resist Pattern>

Next, a positive photoresist “FHi622BC” (manufactured by FUJIFILM Electronics Materials Co., Ltd.) was applied onto the colored layer and pre-baked to form a photoresist layer having a film thickness of 0.8 μm.

Next, using an i-line stepper exposure apparatus FPA-3000i5+(manufactured by Canon Inc.), the exposure was carried out at a wavelength of 365 nm through a Bayer pattern mask of 2.0 μm square by adjusting the exposure amount such that the pattern size was 2.0 μm square.

Next, a heat treatment was carried out for 1 minute at a temperature at which the temperature of the photoresist layer or an ambient temperature was 90° C. Thereafter, a development treatment was carried out for 1 minute with a developer “FHD-5” (manufactured by FUJIFILM Electronics Materials Co., Ltd.), and further a post-baking treatment was carried out at 110° C. for 1 minute.

<Dry Etching>

Next, dry etching was carried out in the following procedure.

A first stage etching treatment for 80 seconds was carried out in a dry etching apparatus (U-621, manufactured by Hitachi High-Technologies Corporation) with an RF power: 800 W, an antenna bias: 400 W, a wafer bias: 200 W, a chamber internal pressure: 4.0 Pa, a substrate temperature: 50° C., and a gas type and a flow rate of a mixed gas set to CF₄: 80 mL/min., O₂: 40 mL/min., and Ar: 800 mL/min.

Then, a second stage etching treatment, over-etching treatment for 28 seconds was carried out in the same etching chamber with an RF power: 600 W, an antenna bias: 100 W, a wafer bias: 250 W, a chamber internal pressure: 2.0 Pa, a substrate temperature: 50° C., and a gas type and a flow rate of a mixed gas set to N₂: 500 mL/min., O₂: 50 mL/min., and Ar: 500 mL/min (N₂/O₂/Ar=10/1/10).

After carrying out the dry etching under the above-mentioned conditions, the resist was removed by carrying out a peeling treatment using a photoresist peeling solution “MS230C” (manufactured by FUJIFILM Electronics Materials Co., Ltd.) for 120 seconds, further followed by washing with pure water and spin drying. Thereafter, a dehydration baking treatment was carried out at 100° C. for 2 minutes. Thus, a colored layer was obtained.

The same results as in Example 19 were obtained in a case where the spectral characteristics and the light resistance were evaluated in the same manner as in Example 19.

The disclosure of JP2018-035196 filed on Feb. 28, 2018 is incorporated herein by reference in its entirety.

All publications, patent applications, and technical standards mentioned in the present specification are herein incorporated by reference to the same extent as if each individual publication, patent application, and technical standard were specifically and individually indicated to be incorporated by reference.

What is claimed is:

1. A composition comprising:
a compound represented by Formula 1 and having a maximum absorption wavelength in a range of 600 nm or more and less than 750 nm; and
a polymerizable compound: 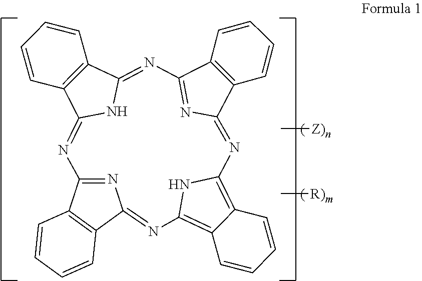
in Formula 1, Z's each independently represent a group represented by Formula 2, n represents an integer of 4 to 16, and R's each independently represent a hydrogen atom or a monovalent substituent which is different from Z, m represents an integer of 0 to 12, and m+n is 16, and 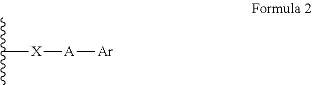
in Formula 2, X is —O—, —S—, —NR³—, —(C═O)—, or a group represented by a combination of at least two thereof, R³'s each independently represent a hydrogen atom, an alkyl group which may have a substituent, or an aryl group which may have a substituent, A represents a divalent linking group, and Ar represents an aryl group or a heteroaryl group.

2. The composition according to claim 1,
wherein at least one of Z's is bonded to a β-position of the compound represented by Formula 1.

3. The composition according to claim 1,
wherein the compound represented by Formula 1 is a compound represented by Formula 3: 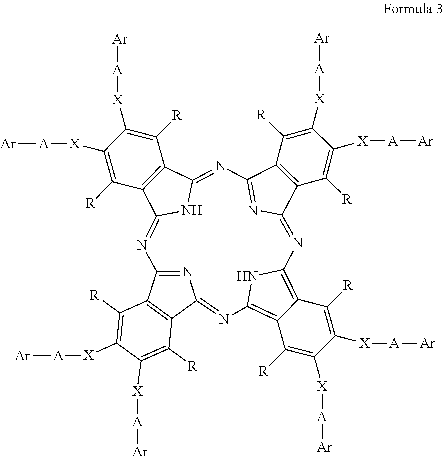
in Formula 3, R's each independently represent a hydrogen atom or a monovalent substituent which is different from Z, X's each independently represent —O—, —S—, —NR³—, —(C═O)—, or a group represented by a combination of at least two thereof, R³'s each independently represent a hydrogen atom, an alkyl group which may have a substituent, or an aryl group which may have a substituent, A's each independently represent a divalent linking group, and Ar's each independently represent an aryl group or a heteroaryl group.

4. The composition according to claim 1,
wherein X's are each independently —O—, —S—, or —NR³—, A's are each independently an alkylene group having 1 to 4 carbon atoms, which may have a substituent, and may contain —O—, —S—, or —NR³— in a site other than a bonding site to X, R³'s each independently represent a hydrogen atom, an alkyl group which may have a substituent, or an aryl group which may have a substituent, and R's are each independently a hydrogen atom or a halogen atom.

5. The composition according to claim 1,
wherein a content of the compound represented by Formula 1 is 40% by mass or more with respect to a total solid content of the composition.

6. The composition according to claim 1,
wherein the compound represented by Formula 1 has a solubility of 0.1% by mass or less in the composition.

7. The composition according to claim 1, further comprising:
a yellow pigment.

8. The composition according to claim 1, further comprising:
a polymerization initiator,
wherein the polymerizable compound is an ethylenically unsaturated compound.

9. A cured product obtained by curing the composition according to claim 1.

10. A color filter comprising:
the cured product according to claim 9.

11. A method for producing a color filter, comprising:
a step of applying the composition according to claim 1 onto a support to form a composition film;
a step of exposing the formed composition film to light in a pattern-wise manner; and
a step of developing the composition film after exposure to form a colored pattern.

12. A method for producing a color filter, comprising:
a step of applying the composition according to claim 1 onto a support and curing the applied composition to form a cured product;
a step of forming a photoresist layer on the cured product;
a step of exposing the photoresist layer to light in a pattern-wise manner and developing the exposed photoresist layer to form a resist pattern; and
a step of etching the cured product through the resist pattern.

13. A solid-state imaging element comprising:
the color filter according to claim 10.

14. An image display device comprising:
the color filter according to claim 10.

15. A compound represented by Formula 4: 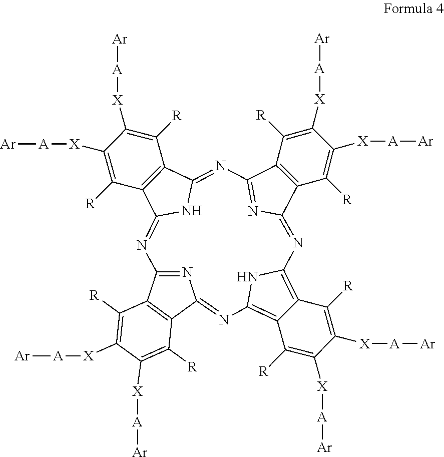
in Formula 4, X's each independently represent —O—, —S—, or —NR³—, A's each independently represent an alkylene group having 1 to 4 carbon atoms, which may have a substituent, and may contain —O—, —S—, or —NR³— in a site other than a bonding site to X, Ar's each independently represent an aryl group or a heteroaryl group, R³'s each independently represent a hydrogen atom, an alkyl group which may have a substituent, or an aryl group which may have a substituent, and R's each independently represent a hydrogen atom or a halogen atom.
